(19) United States
(12) Patent Application Publication
(10) Pub. No.: US 2024/0231756 A9
(43) Pub. Date: Jul. 11, 2024

(54) SEMICONDUCTOR DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Yoshiyuki KUROKAWA, Sagamihara, Kanagawa (JP); Hiromichi GODO, Isehara, Kanagawa (JP); Kazuki TSUDA, Atsugi, Kanagawa (JP); Satoru OHSHITA, Hadano, Kanagawa (JP); Hidefumi RIKIMARU, Tama, Tokyo (JP)

(21) Appl. No.: 18/278,451

(22) PCT Filed: Feb. 24, 2022
(86) PCT No.: PCT/IB2022/051619

§ 371 Date: Aug. 23, 2023

(30) Foreign Application Priority Data
Mar. 5, 2021 (JP) 2021-034961
Mar. 18, 2021 (JP) 2021-044615

(51) Int. Cl. G06F 7/523; G06F 7/50; G09G 3/3208; G11C 11/405; H10B 12/00; H10K 59/121

(52) U.S. Cl. CPC G06F 7/523; G06F 7/50; G09G 3/3208; G11C 11/405; H10B 12/00; H10K 59/1213; H10K 59/1216

(57) ABSTRACT

A semiconductor device with a novel structure is provided. The semiconductor device includes a cell array performing a product-sum operation of a first layer and a product-sum operation of a second layer in an artificial neural network, a first circuit from which first data is input to the cell array, and a second circuit to which second data is output from the cell array. The cell array includes a plurality of cells. The cell array includes a first region and a second region. In a first period, the first region is supplied with the t-th (t is a natural number greater than or equal to 2) first data from the first circuit and outputs the t-th second data according to the product-sum operation of the first layer to the second circuit. In the first period, the second region is supplied with the (t+1)-th first data from the first circuit and outputs the (t+1)-th second data according to the product-sum operation of the second layer to the first circuit.

### TECHNICAL FIELD

In this specification, a semiconductor device and the like will be described.

Note that one embodiment of the present invention is not limited to the above technical field. Examples of the technical field of one embodiment of the present invention disclosed in this specification and the like include a semiconductor device, an image capturing device, a display device, a light-emitting device, a power storage device, a storage device, a display system, an electronic appliance, a lighting device, an input device, an input/output device, a driving method thereof, and a manufacturing method thereof.

### BACKGROUND ART

Integrated circuits that imitate the mechanism of the human brain are currently under active development. The integrated circuits incorporate electronic circuits as the brain mechanism and include circuits corresponding to “neurons” and “synapses” of the human brain. Such integrated circuits may therefore be called “neuromorphic”, “brain-morphic”, or “brain-inspired” circuits. The integrated circuits have a non-von Neumann architecture and are expected to be able to perform parallel processing with extremely low power consumption as compared with a von Neumann architecture, in which power consumption increases with increasing processing speed.

An information processing model that imitates a biological neural network including “neurons” and “synapses” is called an artificial neural network (ANN). By using an artificial neural network, inference with an accuracy as high as or higher than that of a human can be carried out. In an artificial neural network, the main arithmetic operation is the weighted sum operation of outputs from neurons, i.e., the product-sum operation.

Non-Patent Document 1 proposes a product-sum operation circuit including a nonvolatile memory element. Each memory element of the product-sum operation circuit outputs a current corresponding to a product of data corresponding to a multiplier retained in each memory element and input data corresponding to a multiplicand by using operation in a subthreshold region of a transistor containing silicon in its channel formation region. With the sum of currents output from the memory elements in each column, the product-sum operation circuit acquires data corresponding to a product-sum operation. The product-sum operation circuit includes memory elements therein, and thus does not need to read and write data from and to an external memory when carrying out multiplication and addition. This can decrease the number of times of data transfer for reading, writing, and the like; thus, the power consumption should be reduced.

### REFERENCE

### Non-Patent Document

[Non-Patent Document 1] X. Guo et al., “Fast, Energy-Efficient, Robust, and Reproducible Mixed-Signal Neuromorphic Classifier Based on Embedded NOR Flash Memory Technology” IEDM2017, pp. 151-154.

### SUMMARY OF THE INVENTION

### Problems to be Solved by the Invention

In the case of performing a product-sum operation by a product-sum operation circuit, an increase in a shoot-through current due to miniaturization of transistors, for example, might increase power consumption. It is important that not only arithmetic processing speed but also arithmetic processing performance per unit electric power be improved in repetitive arithmetic processing such as a product-sum operation.

By applying a display system provided with a product-sum operation circuit to a glasses-type AR (augmented reality) device or the like, a higher-level user experience combining a sensor function and an AI processing function in addition to a display function can be provided. However, since batteries are assumed to be used for driving the device, power consumption is strictly restricted. For this reason, an arithmetic device for achieving the function needs to be a low-power consumption device.

An object of one embodiment of the present invention is to provide a semiconductor device or the like with high arithmetic processing performance per unit electric power. An object of one embodiment of the present invention is to provide a semiconductor device or the like excellent in reducing power consumption. An object of one embodiment of the present invention is to provide a semiconductor device or the like that has a novel structure and is capable of performing a product-sum operation.

One embodiment of the present invention does not necessarily achieve all the above objects and only needs to achieve at least one of the objects. The description of the above objects does not preclude the existence of other objects. Objects other than these objects will be apparent from the description of the specification, the claims, the drawings, and the like, and objects other than these objects can be derived from the description of the specification, the claims, the drawings, and the like.

### Means for Solving the Problems

One embodiment of the present invention is a semiconductor device including a cell array performing a product-sum operation of a first layer and a product-sum operation of a second layer in an artificial neural network, a first circuit from which first data is input to the cell array, and a second circuit to which second data is output from the cell array; the cell array includes a plurality of cells; the cell array includes a first region and a second region; and in a first period, the first region is supplied with the t-th (t is a natural number greater than or equal to 2) first data from the first circuit and outputs the t-th second data according to the product-sum operation of the first layer to the second circuit, and the second region is supplied with the (t+1)-th first data from the first circuit and outputs the (t+1)-th second data according to the product-sum operation of the second layer to the second circuit.

One embodiment of the present invention is a semiconductor device including a cell array performing a product-sum operation of a first layer and a product-sum operation of a second layer in an artificial neural network, a first circuit from which first data is input to the cell array, and a second circuit to which second data is output from the cell array; the cell array includes a plurality of cells; the cell array includes a first region and a second region; in a first period, the first region is supplied with the t-th (t is a natural number greater than or equal to 2) first data from the first circuit and outputs the t-th second data according to the product-sum operation of the first layer to the second circuit, and the second region is supplied with the (t+1)-th first data from the first circuit and outputs the (t+1)-th second data according to the product-sum operation of the second layer to the second circuit; and in a second period, the first region is supplied with the (t+1)-th first data from the first circuit and outputs the (t+1)-th second data according to the product-sum operation of the first layer to the second circuit, and the second region is supplied with the t-th first data from the first circuit and outputs the t-th second data according to the product-sum operation of the second layer to the second circuit.

In the semiconductor device of one embodiment of the present invention, the first data input to the second region is preferably data obtained by performing a nonlinear operation on the second data output from the first region.

In the semiconductor device of one embodiment of the present invention, a third circuit to which the second data is output from the cell array is preferably included, and the third circuit preferably has a function of performing an arithmetic operation based on a nonlinear function on the second data.

In the semiconductor device of one embodiment of the present invention, the cell preferably includes a first transistor, a second transistor, and a capacitor; the first transistor preferably has a function of retaining a first potential corresponding to weight data supplied to a gate of the second transistor through the first transistor in an off state; the capacitor preferably has a function of changing the first potential retained in the gate of the second transistor into a second potential in accordance with a change in a potential corresponding to the first data supplied to one electrode of the capacitor; and the second transistor preferably has a function of outputting the second data based on the first data, as an analog current, to the other of a source or a drain of the second transistor.

In the semiconductor device of one embodiment of the present invention, the analog current preferably flows when the second transistor operates in a subthreshold region.

In the semiconductor device of one embodiment of the present invention, the first transistor preferably includes a semiconductor layer containing a metal oxide in a channel formation region.

In the semiconductor device of one embodiment of the present invention, the metal oxide preferably contains In, Ga, and Zn.

In the semiconductor device of one embodiment of the present invention, each of the second transistor preferably includes a semiconductor layer containing silicon in a channel formation region.

One embodiment of the present invention is an electronic device including the semiconductor device, a driver circuit, a pixel circuit, a light-emitting element, and a light-receiving element; the pixel circuit has a function of controlling light emission of the light-emitting element; the driver circuit has a function of controlling the pixel circuit; the semiconductor device includes a transistor included in a layer provided with the pixel circuit and a transistor included in a layer provided with the driver circuit; and the semiconductor device has a function of performing arithmetic processing using a current output from the light-receiving element as the first data.

In the electronic device of one embodiment of the present invention, the light-receiving element includes an organic photodiode and the light-emitting element is an organic EL element.

In the electronic device of one embodiment of the present invention, the light-emitting element and the light-receiving element are separated by a photolithography method.

Note that other embodiments of the present invention will be shown in the description of the following embodiments and the drawings.

### Effect of the Invention

One embodiment of the present invention can provide a semiconductor device or the like with high arithmetic processing performance per unit electric power. One embodiment of the present invention can provide a semiconductor device or the like excellent in reducing power consumption. One embodiment of the present invention can provide a semiconductor device or the like that has a novel structure and is capable of performing a product-sum operation.

The description of a plurality of effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1 is a diagram illustrating a structure example of a semiconductor device.

FIG. 2A and FIG. 2B are diagrams each illustrating a structure example of a semiconductor device.

FIG. 3A and FIG. 3B are diagrams each illustrating a structure example of a semiconductor device.

FIG. 4A and FIG. 4B are diagrams each illustrating a structure example of a semiconductor device.

FIG. 5 is a diagram illustrating a structure example of a semiconductor device.

FIG. 6 is a diagram illustrating a structure example of a semiconductor device.

FIG. 7 is a diagram illustrating a structure example of a semiconductor device.

FIG. 8 is a diagram illustrating a structure example of a semiconductor device.

FIG. 9 is a diagram illustrating a structure example of a semiconductor device.

FIG. 10 is a diagram illustrating a structure example of a semiconductor device.

FIG. 11A and FIG. 11B are diagrams each illustrating a structure example of a semiconductor device.

FIG. 12 is a diagram illustrating a structure example of a semiconductor device.

FIG. 13A, FIG. 13B, and FIG. 13C are diagrams each illustrating a structure example of a semiconductor device.

FIG. 14A, FIG. 14B, FIG. 14C, and FIG. 14D are diagrams each illustrating a structure example of a semiconductor device.

FIG. 15A, FIG. 15B, and FIG. 15C are diagrams each illustrating a structure example of a semiconductor device.

FIG. 16 is a diagram illustrating a structure example of a semiconductor device.

FIG. 17 is a diagram illustrating a structure example of a semiconductor device.

FIG. 18A and FIG. 18B are diagrams illustrating a structure example of a display device.

FIG. 19A and FIG. 19B are diagrams each illustrating a structure example of a display device.

FIG. 20 is a diagram illustrating a structure example of a display device.

FIG. 21A and FIG. 21B are diagrams each illustrating a structure example of a display device.

FIG. 22A and FIG. 22B are diagrams each illustrating a structure example of a display device.

FIG. 23A, FIG. 23B, FIG. 23C, and FIG. 23D are diagrams each illustrating a structure example of a display device.

FIG. 24A and FIG. 24B are diagrams each illustrating a structure example of a display device.

FIG. 25A, FIG. 25B, FIG. 25C, and FIG. 25D are diagrams each illustrating a structure example of a display device.

FIG. 26A and FIG. 26B are diagrams each illustrating a structure example of a display device.

FIG. 27A to FIG. 27G are diagrams each illustrating a structure example of a display device.

FIG. 28 is a diagram illustrating a structure example of a display device.

FIG. 29A and FIG. 29B are diagrams illustrating a structure example of an electronic device.

FIG. 30A and FIG. 30B are diagrams each illustrating a structure example of an electronic device.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the terms do not limit the number of components. Furthermore, the terms do not limit the order of components. For example, a “first” component in one embodiment in this specification and the like can be referred to as a “second” component in other embodiments or the scope of claims. For another example, a “first” component in one embodiment in this specification and the like can be omitted in other embodiments or the scope of claims.

The same components, components having similar functions, components made of the same material, components formed at the same time, and the like in the drawings are denoted by the same reference numerals, and repeated description thereof is omitted in some cases.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and, particularly when they need to be distinguished from each other, an identification sign such as “_1”, “_2”, “_n”, or “m,n” is sometimes added to the reference numerals. For example, a second wiring GL is referred to as a wiring GL_2.

### Embodiment 1

A semiconductor device of one embodiment of the present invention will be described. The semiconductor device of one embodiment of the present invention can be used for arithmetic processing of an artificial neural network. As the artificial neural network, a hierarchical neural network can be used, for example.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

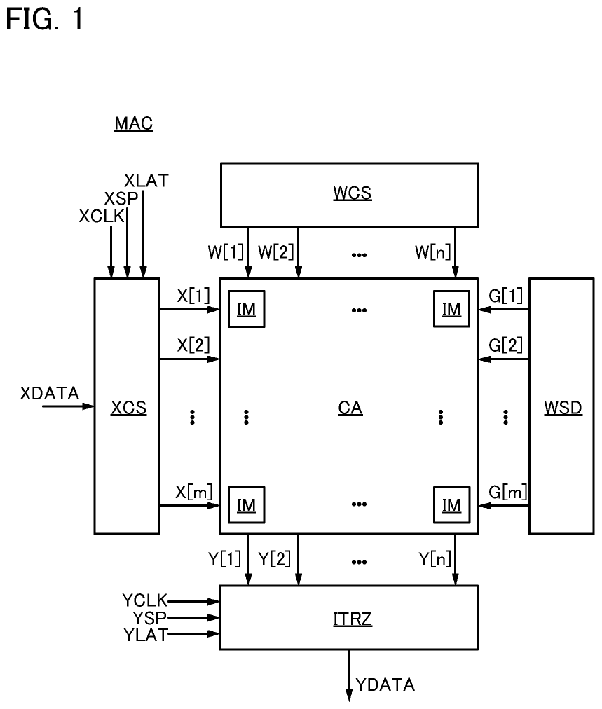

FIG. 1 is a block diagram of a semiconductor device including a cell array and its peripheral circuits which can perform a product-sum operation performed in arithmetic processing of an artificial neural network (hereinafter, referred to as a neural network in some cases). Note that the semiconductor device including the cell array and its peripheral circuits described in this embodiment is a circuit that can perform a product-sum operation and referred to as an arithmetic circuit in some cases.

A semiconductor device MAC includes a circuit XCS, a circuit WCS, a circuit WSD, a cell array CA, and a circuit ITRZ. The cell array CA includes cells IM (also referred to as memory cells) arranged in a matrix of m rows and n columns (m and n are each a natural number greater than or equal to 2).

The circuit XCS includes a digital-to-analog (D/A) converter circuit corresponding to each row of the cell array CA. The circuit XCS can supply an analog signal corresponding to input data through signal lines X[1] to X[m] to the cells IM of each row of the cell array CA. The circuit XCS is referred to as an X driver in some cases. The signal lines X[1] to X[m] may be referred to as wirings XCL[1] to XCL[m].

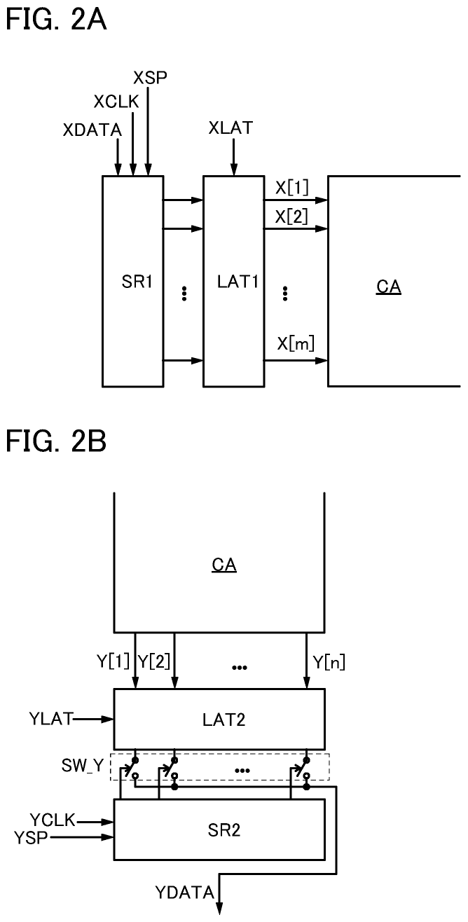

Input data XDATA supplied to each row of the cell array CA is supplied to the circuit XCS. The input data XDATA is supplied to the signal lines X[1] to X[m] at a predetermined timing by a clock signal XCLK, a start pulse XSP, and a latch signal XLAT. For example, the circuit XCS includes a shift register SR1 and a latch circuit LAT1 as illustrated in FIG. 2A. The input data XDATA is assigned to each row by the clock signal XCLK and the start pulse XSP, which are input to the shift register SR1, and then is retained in the latch circuit LAT1. Then, the input data XDATA is output to the signal lines X[1] to X[m] at a timing of the latch signal XLAT.

The circuit WCS includes a D/A converter circuit corresponding to each column of the cell array CA and can supply an analog signal corresponding to weight data from signal lines W[1] to W[n] to the cells IM of each column of the cell array CA. The circuit WCS is referred to as a W driver. The signal lines W[1] to W[n] may be referred to as wirings WCL[1] to WCL[n].

The circuit WSD can supply a signal for selecting a write target row of the cell array CA through signal lines G[1] to G[m]. The circuit WSD is referred to as a G driver. The signal lines G[1] to G[m] may be referred to as wirings WSL[1] to WSL[m].

The circuit ITRZ includes an analog-to-digital (A/D) converter circuit corresponding to each column of the cell array CA, and can obtain a digital signal corresponding to an analog signal output from the cells IM of each column of the cell array CA to signal lines Y[1] to Y[n]. The circuit ITRZ is referred to as a Y driver in some cases. The signal lines Y[1] to Y[n] correspond to wirings connected to the above-described signal lines W[1] to W[n], that is, the wirings WCL[1] to WCL[n].

The circuit ITRZ outputs output data YDATA obtained from each row of the cell array CA. As the output data YDATA, the analog signal is obtained from the signal lines Y[1] to Y[n] at a predetermined timing by a clock signal YCLK, a start pulse YSP, and a latch signal YLAT, and output as the output data YDATA of the digital signal. For example, the circuit ITRZ includes a shift register SR2, a latch circuit LAT2, and a switch SW_Y as illustrated in FIG. 2B. Data of the signal lines Y[1] to Y[n] are retained in the latch circuit LAT2. The data of the signal lines Y[1] to Y[n] retained in the latch circuit LAT2 is output as the output data YDATA at a timing when the switch SW_Y assigned to each column by the clock signal YCLK and the start pulse YSP, which are input to the shift register SR2, is turned on.

Note that description of specific examples and operation examples of the circuit XCS, the circuit WCS, the circuit WSD, the cell array CA, and the circuit ITRZ will be described in detail in Embodiment 3.

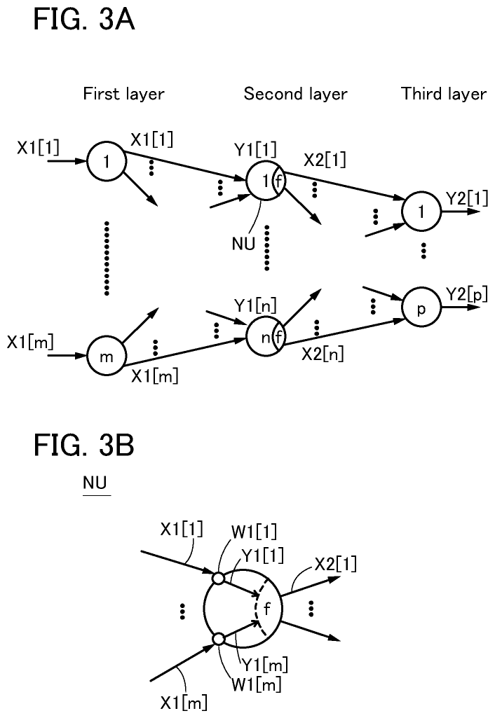

Here, a hierarchical neural network is described. A hierarchical neural network includes one input layer, one or a plurality of intermediate layers (hidden layers), and one output layer, for example. FIG. 3A illustrates a diagram of a network of three-layer perceptrons, which is an example of a hierarchical neural network. In FIG. 3A, a first layer corresponds to an input layer, a second layer corresponds to an intermediate layer, and a third layer corresponds to an output layer.

Each of the layers of the neural network includes one or a plurality of neurons NU. In FIG. 3A, the first layer illustrates m neurons, the second layer illustrates n neurons, and the third layer illustrates p neurons (n, m, and p are each a natural number greater than or equal to 2).

In FIG. 3A, in the first layer which is an input layer, data X1[1] to X1[m] are supplied to m neurons. The data X1[1] to X1[m] are output from the respective neurons in the first layer to the respective neurons in the second layer. In FIG. 3A, in the third layer which is an output layer, data X2[1] to X2[n] are supplied top neurons. The neurons of the output layer output data Y2[1] to Y2[p] obtained by fully connected processing of the data X2[1] to X2[n] and weight data W2[1] to W2[n] (not illustrated).

A signal input to and output from the neuron of the second layer, which is an intermediate layer, is described with reference to FIG. 3B. FIG. 3B illustrates the data X1[1] to X1[m] input from each neuron of the first layer and weight data W1[1] to W1[m] included in the neuron of the second layer. FIG. 3B illustrates data Y1[1] to Y1[m] obtained by product-sum operations of the input data X1[1] to X1[m] and the weight data W1[1] to W1[m]. The data Y1[1] to Y1[m] are output to neurons of the third layer as data X2[1], which is obtained by performing a nonlinear operation based on an activation function ƒ.

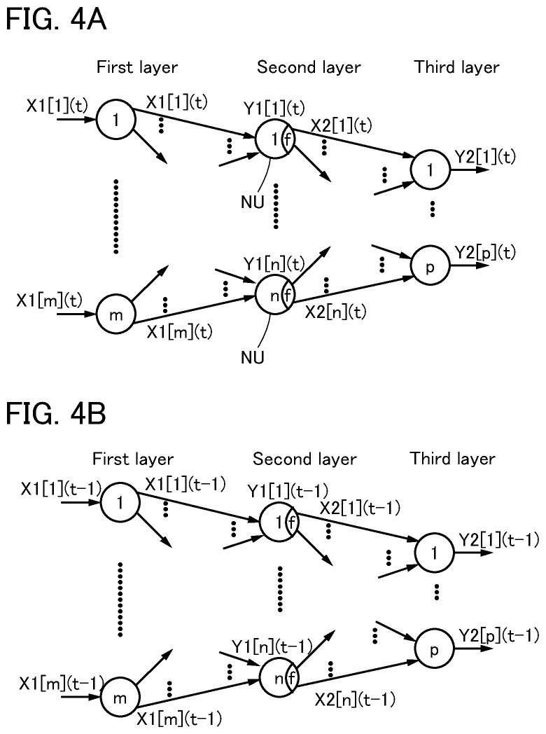

For example, the t-th data X1[1](t) to X1[m](t) (t is a natural number greater than or equal to 2) are input to and output from each layer of the neural network of FIG. 3A as illustrated in FIG. 4A. In addition, the (t+1)-th data X1[1](t+1) to X1[m](t+1) are input to and output from each layer of the neural network of FIG. 3A as illustrated in FIG. 4B.

In the neural network, product-sum operations Y1[j](t)=ΣW1[i,j]X1[i](t) and nonlinear operations X2[j](t)=ƒ(Y1[j](t)) are performed on the input t-th data X1[1](t) to X1[m](t) in the second layer which is an intermediate layer, and product-sum operations Y2[k](t)=ΣW2[j,k]X2[j](t) are performed in the third layer which is an output layer. In the same manner, product-sum operations Y1[j](t+1)=ΣW1[i,j]X1[i](t+1) and nonlinear operations X2[j](t+1)=ƒ(Y1[i](t+1)) are performed on the input (t+1)-th data X1[1](t+1) to X1[m](t+1) in the second layer which is an intermediate layer, and product-sum operations Y2[k](t)=ΣW2[j,k]X2[j](t+1) are performed in the third layer which is an output layer. Note that in some cases, a layer that performs a product-sum operation is referred to as “first layer” and “second layer”, and the second layer which is an intermediate layer is referred to as “first layer” and the third layer which is an output layer is referred to as “second layer”, for example. Note that i, j, and k in each formula are each a natural number. A nonlinear operation is an arithmetic operation by a nonlinear function ƒ(X) to X. Examples of a nonlinear function ƒ(X) include a sigmoid function, a ReLU function, and the like.

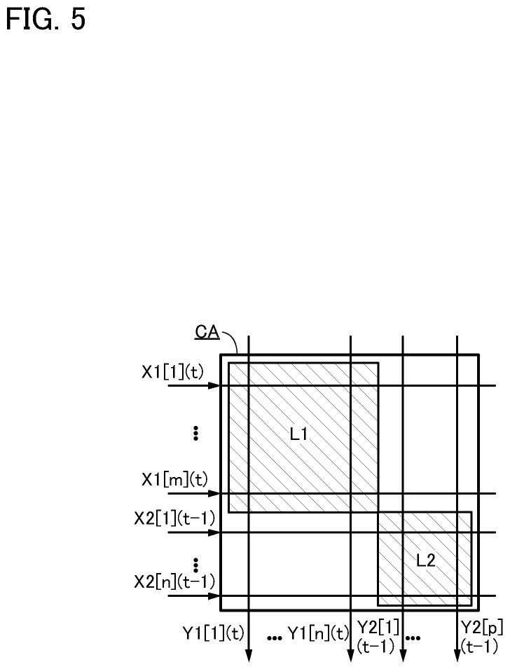

FIG. 5 is a diagram in which a region of the cell array CA illustrated in FIG. 1 is divided in accordance with the neural network illustrated in FIG. 4A and FIG. 4B. The product-sum operations Y1[j](t)=ΣW1[i,j]X1[i](t) of m rows and n columns on the t-th data X[1](t) to X1[m](t) in an intermediate layer are assigned to an area L1, and product-sum operations Y2[k](t+1)=ΣW2[j,k]X2[j](t+1) of n rows and p columns on the (t+1)-th data X1[1](t+1) to X1[m](t+1) in an output layer are assigned to an area L2.

With the structure in FIG. 5, a product-sum operation in a plurality of layers of the neural network can be performed in one cell array CA, and an arithmetic processing device with low power consumption that can perform arithmetic processing efficiently can be provided.

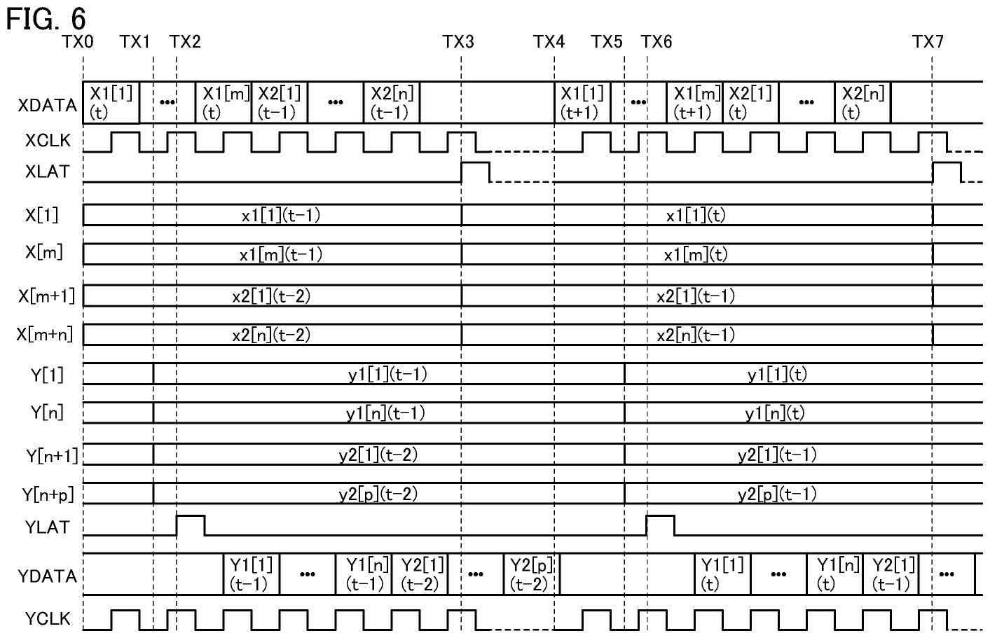

FIG. 6 is a timing chart in the case where the region of the cell array CA illustrated in FIG. 1 is divided and operated as illustrated in FIG. 5. Note that the following description is made assuming that weight data W1[i,j] is retained in the cell IM of the i-th row and the j-th column (i=1 to m, j=1 to n) of the cell array CA. Moreover, the description is made assuming that weight data W2[i,j] is retained in the cell IM of the (m+i)-th row and the (n+j)-th column (i=1 to n,j=1 top) of the cell array CA.

At time TX0, the t-th data X1[1](t) to X1[m](t) and nonlinear operation data X2[1](t+1) to X2[n](t+1) of an intermediate layer to the (t+1)-th data X1[1](t+1) to X1[m](t+1) are sequentially input to the circuit XCS. The t-th data X1[1](t) to X1[m](t) and the nonlinear operation data X2[1](t+1) to X2[n](t+1) of the intermediate layer to the (t+1)-th data X1[1](t+1) to X1[m](t+1) are sequentially input to the latch circuit of the circuit XCS in synchronization with the clock signal XCLK.

At time TX1, the t-th analog signals y1[1](t+1)=Σw1[i,1]x1[i](t+1) to y1[n](t+1)=Σw1[i,n]x1[i](t+1) and the (t+2)-th analog signals y2[1](t−2)=Σw2[j,1]x2[j](t+2) to y2[p](t+2)=Σw2[j,p]x1[j](t+2) in each column of the cell array CA are determined and supplied to the signal lines Y[1] to Y[n] and signal lines Y[n+1] to Y[n+p]. The A/D converter circuit corresponding to each column of the cell array CA generates the (t+1)-th output data Y1[1](t+1) to Y1[n](t+1) corresponding to the (t+1)-th analog signals y1[1](t+1) to y1[n](t+1) and the (t+2)-th output data Y2[1](t+2) to Y2[p](t−2) corresponding to the (t+2)-th analog signals y2[1](t+2) to y2[p](t−2).

At time TX2, by setting the latch signal YLAT to H level, the (t−1)-th data Y1[1](t+1) to Y1[n](t+1) and the (t−2)-th data Y2[1](t+2) to Y2[1](t+2) are taken into the latch circuit of the circuit ITRZ and sequentially output in synchronization with the clock signal YCLK.

At time TX3, by setting the latch signal XLAT to H level, the D/A converter circuit corresponding to each row of the cell array CA generates the t-th analog signals x1[1](t) to x1[m](t) corresponding to the t-th data X1[1](t) to X1[m](t) and the (t+1)-th analog signals x2[1](t+1) to x2[n](t+1) corresponding to the nonlinear operation data X2[1](t+1) to X2[n](t+1) of the intermediate layer to the (t+1)-th data X1[1](t+1) to X1[m](t+1), and the signals are supplied to the signal lines X[1] to X[m] and signal lines X[m+1] to X[m+n].

In a period from Time TX0 to Time TX3 (a first period), by inputting the (t+1)-th data X1[1](t+1) to X1[m](t+1) in the area L1 of FIG. 5 (a first region), the (t+1)-th data Y1[1](t+1) to Y1[n](t+1) corresponding to a product-sum operation of the area L1 can be output. In addition, in the period from Time TX0 to Time TX3 (the first period), by inputting the (t−2)-th data X2[1](t+2) to X2[m](t−2) in the area L2 of FIG. 5 (a second region), the (t+2)-th data Y2[1](t+2) to Y2[n](t−2) corresponding to a product-sum operation of the area L2 can be output.

At time TX4, the (t+1)-th data X1[1](t+1) to X1[m](t+1) and nonlinear operation data X2[1](t) to X2[n](t) of the intermediate layer to the t-th data X1[1](t) to X1[m](t) are sequentially input to the circuit XCS. The (t+1)-th data X[1](t+1) to X1[m](t+1) and the nonlinear operation data X2[1](t) to X2[n](t) of the intermediate layer to the t-th data X1[1](t) to X1[m](t) are sequentially input to the latch circuit of the circuit XCS in synchronization with the clock signal XCLK.

At time TX5, the t-th analog signals y1[1](t)=Σw1[i,1]x1[i](t) to y1[n](t)=Σw1[i,n]x1[i](t) and the (t+1)-th analog signals y2[1](t+1)=Σw2[j,1]x2[j](t+1) to y2[p](t+1)=Σw2[j,p]x1[j](t+1) in each column of the cell array CA are determined and supplied to the signal lines Y[1] to Y[n] and the signal lines Y[n+1] to Y[n+p]. The A/D converter circuit corresponding to each column of the cell array CA generates the t-th output data Y1[1](t) to Y1[n](t) corresponding to the t-th analog signals y1[1](t) to y1[n](t) and the (t+1)-th output data Y2[1](t+1) to Y2[p](t+1) corresponding to the (t−1)-th analog signals y2[1](t+1) to y2[p](t+1).

At time TX6, by setting the latch signal YLAT to H level, the t-th data Y1[1](t) to Y1[n](t) and the (t−1)-th data Y2[1](t+1) to Y2[1](t+1) are taken into the latch circuit of the circuit ITRZ and sequentially output in synchronization with the clock signal YCLK.

At time TX7, by setting the latch signal XLAT to H level, the D/A converter circuit corresponding to each row of the cell array CA generates the (t+1)-th analog signals x1[1](t+1) to x1[m](t+1) corresponding to the (t+1)-th data X1[1](t+1) to X1[m](t+1) and the t-th analog signals x2[1](t) to x2[n](t) corresponding to the nonlinear operation data X2[1](t) to X2[n](t) of the intermediate layer to the t-th data X1[1](t) to X1[m](t), and the signals are supplied to the signal lines X[1] to X[m] and the signal lines X[m+1] to X[m+n] (not illustrated).

In a period from Time TX4 to Time TX7 (a second period), by inputting the t-th data X1[1](t) to X1[m](t) in the area L1 of FIG. 5 (the first region), the t-th data Y1[1](t) to Y1[n](t) corresponding to the product-sum operation of the area L1 can be output. In addition, in the period from Time TX4 to Time TX7 (the second period), by inputting the (t−1)-th data X2[1](t+1) to X2[m](t+1) in the area L2 of FIG. 5 (the second region), the (t−1)-th data Y2[1](t+1) to Y2[n](t−1) corresponding to the product-sum operation of the area L2 can be output.

Here, a structure is preferably employed in which the t-th data Y1[1](i) to Y1[n](t) is output and the nonlinear operations X2[j](t)=ƒ(Y1[j](t)) in the intermediate layer corresponding to the t-th data are performed in accordance with the cycle of the clock signal YCLK, the nonlinear operation results are retained by a first-in-first-out (FIFO), and the nonlinear operation data X2[1](t) to X2[n](t) is read by the FIFO in accordance with the cycle of the clock signal XCLK. With such a structure, the operating speed of the D/A converter circuit and the A/D converter circuit can each be set at an appropriate value; thus, a reduction in power consumption or the like can be achieved.

In addition, a structure is preferably employed in which the clock signal YCLK and the clock signal XCLK have the same cycle, and outputting the t-th data Y1[1](i) to Y1[n](i) and performing the nonlinear operations X2[j](t)=ƒ(Y1[j](t)) in the intermediate layer corresponding to the t-th data are performed in synchronization with the clock signal XCLK so as to have the same timing as inputting X2[j](i). Such a structure does not require a mechanism such as the first-in-first-out (FIFO) for retaining the nonlinear operation result and reading out it in synchronization with the clock signal XCLK, whereby a structure of a semiconductor device can be simplified.

With the above-described structure, a product-sum operation corresponding to a plurality of layers of the neural network can be performed in one cell array, whereby a low-power-consumption arithmetic processing device that can perform arithmetic processing effectively can be provided.

### Embodiment 2

In this embodiment, a structure different from the structure of the semiconductor device described in the above embodiment will be described. The above description can be referred to for portions similar to Embodiment 1, and detailed description of the portions is omitted.

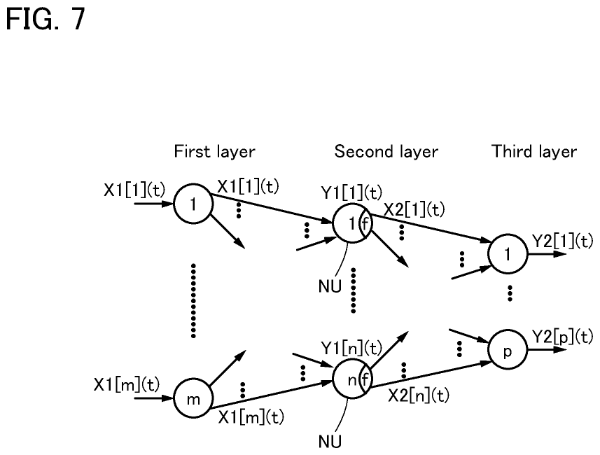

In this embodiment, the case of performing an arithmetic operation in an example of the hierarchical neural network illustrated in FIG. 3A in Embodiment 1 is described. FIG. 7 illustrates a state when the t-th data X1[1](t) to X1[m](t) (t is a natural number greater than or equal to 2) is input, data X1[1](t) to X1[m](t) is input and output between the first layer and the second layer of the neural network and data X2[1](t) to X2[n](t) is input and output between the second layer and the third layer of the neural network, for example.

In the neural network, the product-sum operations Y1[j](t)=ΣW1[i,j]X1[i](t) and the nonlinear operations X2[j]( )=ƒ(Y1[j](t)) are performed on the input t-th data X1[1](t) to X1[m](t) in the second layer which is an intermediate layer (also referred to as a first layer), and the product-sum operations Y2[k](t)=E W2[j,k]X2[j](t) are performed in the third layer which is an output layer (also referred to as a second layer). Note that i, j, and k in each formula are each a natural number. The nonlinear operation is an arithmetic operation by a nonlinear function ƒ(X) to X. Examples of a nonlinear function ƒ(X) include a sigmoid function, a ReLU function, and the like.

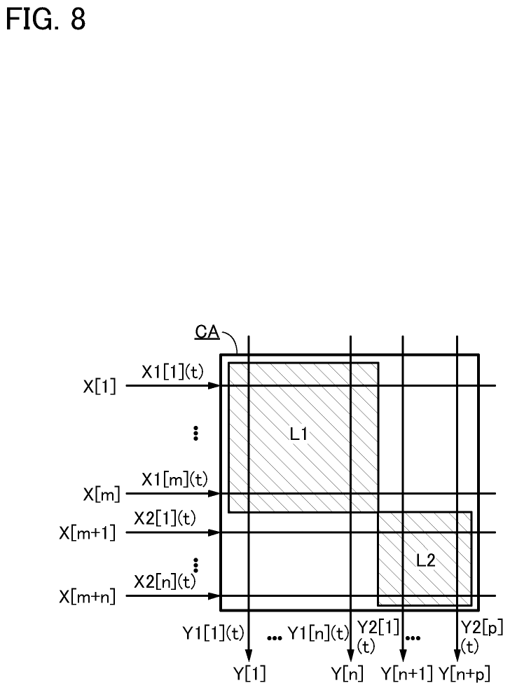

FIG. 8 is a diagram in which the region of the cell array CA is divided in accordance with the neural network illustrated in FIG. 7. The cell array CA illustrated in FIG. 8 includes the cells IM of (m+n) rows and (n+p) columns connected to the signal lines X[1] to X[m], the signal lines X[m+1] to X[m+n], the signal lines Y[1] to X[n], and signal lines X[n+1] to X[n+p]. In the cell array CA illustrated in FIG. 8, the t-th data X1[1](t) to X1[m](t) and the t-th data X2[1](t) to X2[n](t) are input to the signal lines X[1] to X[m+n]. In the cell array CA illustrated in FIG. 8, the t-th data Y1[1](t) to Y1[n](t) and the t-th data Y2[1](t) to Y2[p](t) are output to signal lines Y[1] to Y[n+p]. That is, the product-sum operations Y1[j](t)=ΣW1[i,j]X1[i](t) of m rows and n columns in the second layer, which is an intermediate layer, to the t-th data X[1](t) to X1[m](t) are assigned to the area L1, and the product-sum operations Y2[k]( )=ΣW2[j,k]X2[j](t) of n rows and p columns in the third layer, which is an output layer, to the t-th data X2[1](t) to X2[n](t) are assigned to the area L2.

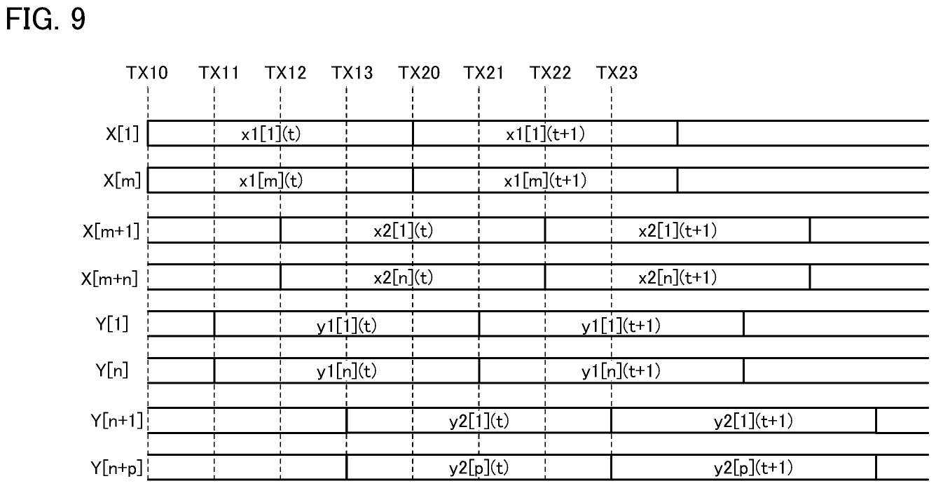

FIG. 9 is a driving timing chart of the semiconductor device where the cell array CA is divided by areas as illustrated in FIG. 8. Note that it is assumed that weight data w1[i,j] is retained in the cell IM of the i-th row and the j-th column (i=1 to m, j=1 to n) of the cell array CA. In addition, it is assumed that weight data w2[i,j] is retained in the cell IM of the (m+i)-th row and the (n+j)-th column (i=1 to n,j=1 top) of the cell array CA.

At time TX10, the analog signals x1[1](t) to x1[m](t) corresponding to the t-th data are supplied to the signal lines X[1] to X[m]. In the area L1 of the cell array CA, arithmetic operations corresponding to the product-sum operations ΣW1[i,j]X1[i](t) of m rows and n columns are performed.

At time TX11, the analog signals y1[1](t)=Σw1[i,1]x1[i](t) to y1[n](t)=Σw1[i,n]x1[i](t) of each column of the area L1 of the cell array CA are determined and supplied to the signal lines Y[i] to Y[n].

At time TX12, the analog signals x2[1](t) to x2[n](t) that are obtained by performing a nonlinear operation on analog signals y1[1](t) to y1[n](t) are supplied to the signal lines X[m+1] to X[m+n]. In the area L2 of the cell array CA, arithmetic operations corresponding to the product-sum operations Σw2[j,k]x2[j](t) of n rows and p columns are performed.

At time TX13, analog signals y2[1](t)=Σw2[j,1]x2[j](t) to y2[1](t)=Σw2[j,n]x2[j](t) of each column of the area L2 of the cell array CA are determined and supplied to the signal lines Y[n+1] to X[n+p]. Here, analog signals y2[1](t) to y2[p](t) correspond to the results of performing the arithmetic operation of the neural network of FIG. 7 on the t-th data.

At time TX20, the analog signals x1[1](t+1) to x1[m](t+1) corresponding to the (t+1)-th data are supplied to the signal lines X[1] to X[m]. In the area L1 of the cell array CA, arithmetic operations corresponding to product-sum operations Σw1[i,j]x1[i](t+1) of m rows and n columns are performed.

At time TX21, analog signals y1[1](t+1)=Σw1[i,1]x1[i](t+1) to y1[n](t+1)=Σw1[i,n]x1[i](t+1) of each column of the area L1 of the cell array CA are determined and supplied to the signal lines Y[1] to Y[n].

At time TX22, analog signals x2[1](t+1) to x2[n](t+1) that are obtained by performing a nonlinear operation on analog signals y1[1](t+1) to y1[n](t+1) are supplied to the signal lines X[m+1] to X[m+n]. In the area L2 of the cell array CA, arithmetic operations corresponding to product-sum operations Σw2[j,k]x2[j](t+1) of n rows and p columns are performed.

At time TX23, analog signals y2[1](t+1)=Σw2[j,1]x2[j](t+1) to y2[1](t+1)=Σw2[j,n]x2[j](t+1) of each column of the area L2 of the cell array CA are determined and supplied to the signal lines Y[n+1] to Y[n+p]. Here, analog signals y2[1](t+1) to y2[1](t+1) correspond to the results of performing the arithmetic processing of the neural network of FIG. 7 on the (t+1)-th data.

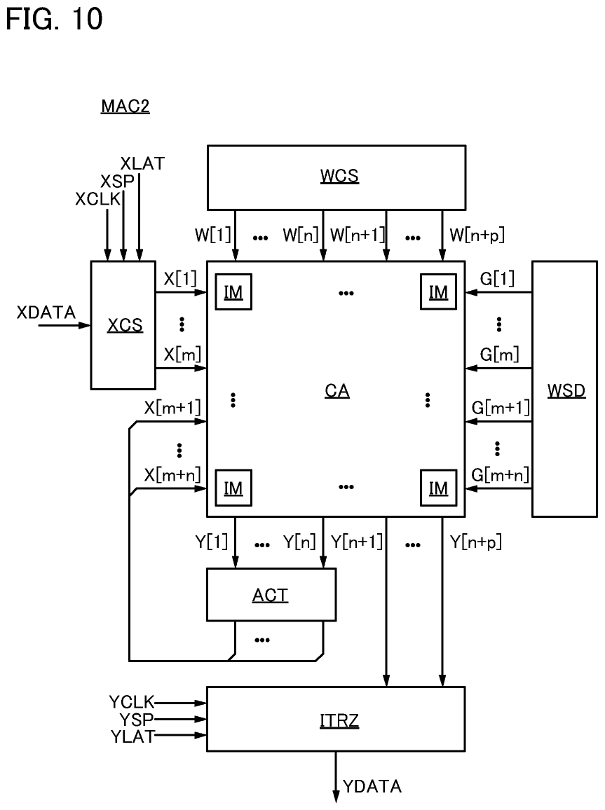

FIG. 10 illustrates an example of peripheral circuits of a semiconductor device MAC2 provided with the cell array CA enabling the arithmetic processing of this embodiment. The semiconductor device MAC2 includes the circuit XCS, the circuit WCS, the circuit WSD, the cell array CA, the circuit ITRZ, and a circuit ACT. The cell array CA includes the cells IM which are arranged in a matrix of (m+n) rows and (n+p) columns. Note that the semiconductor device MAC2 differs from the above-described semiconductor device MAC of Embodiment 1 in that the circuit ACT is provided between the signal lines Y[1] to Y[n] and the signal lines X[m+1] to X[m+n].

The circuit ACT includes a circuit that has a function of performing a nonlinear operation corresponding to each column of the cell array CA. The circuit ACT can obtain an analog signal that is obtained by performing a nonlinear operation on an analog signal output from each column of the cell array CA to the signal lines Y[1] to Y[n]. By outputting the analog signal to the signal lines X[m+1] to X[m+n], the analog signal can be supplied to the cells IM of each row of the cell array CA.

Note that a structure is preferably employed in which an analog signal supplied from the circuit ACT and an analog signal supplied from the circuit XCS can be selectively supplied to the signal lines X[m+1] to X[m+n]. In addition, the signal lines Y[1] to Y[n] are preferably configured to supply an analog signal to the circuit ITRZ in addition to the circuit ACT. With the structure, the number of rows and the number of columns of the area L1 and the area L2 can be flexibly changed corresponding to the structure of the neural network that is to be a target of the arithmetic processing. Note that analog signals from the circuit XCS or the circuit ACT can be selectively supplied to all or some of the signal lines X[1] to X[m+n]. In addition, analog signals can be selectively supplied to the circuit ITRZ or the circuit ACT from all or some of the signal lines Y[1] to Y[n+p]. Furthermore, the signal lines X[1] to X[m+n] and the signal lines Y[1] to Y[n+p] to which an analog signal is not supplied can be electrically disconnected as appropriate by an analog switch or the like.

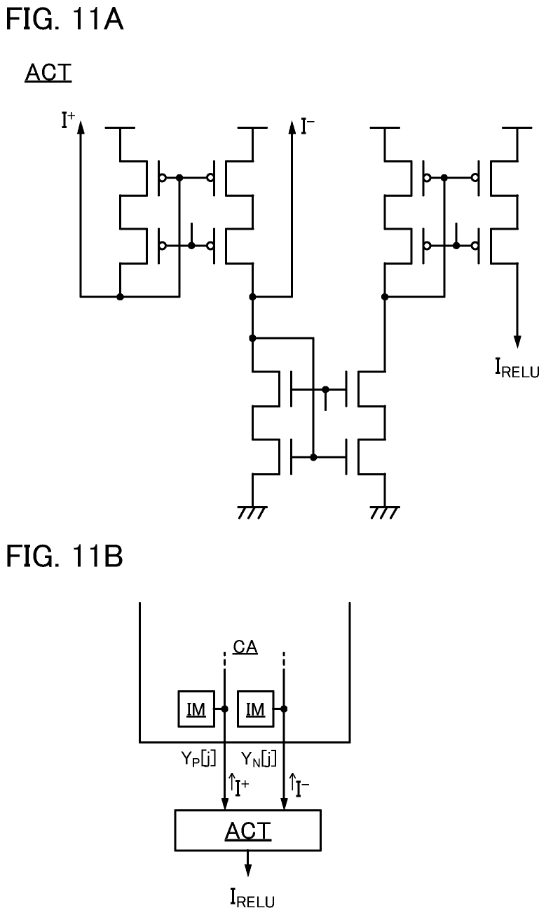

FIG. 11A illustrates a structure example of the circuit ACT that has a function of performing a nonlinear operation. In FIG. 11A, two columns of the cell array CA are used as a pair in the case where positive weight data and negative weight data are used.

FIG. 11A illustrates a structure in which a nonlinear operation corresponding to analog currents I⁺ and I⁻ flowing through a pair of signal lines Y_{P}[j] and Y_{N}[j] is performed in accordance with the positive weight data and the negative weight data that are retained in a pair of cells IM as illustrated in FIG. 11B.

The analog current P illustrated in FIG. 11A and FIG. 11B is a current that is output from a column corresponding to the positive weight data. The analog current I⁻ is a current that is output from a column corresponding to the negative weight data. In the structure illustrated in FIG. 11A, the circuit ACT can output an analog current I_{RELU} which corresponds to (I⁺−I⁻) when I⁺>I⁻, that is, when the net result of the product-sum operation is positive. On the other hand, in the structure illustrated in FIG. 11A, the circuit ACT can output the analog current I_{RELU} which corresponds to 0 when I⁺<I⁻, that is, when the net result of the product-sum operation is negative. That is, the obtained output corresponds to the result that is obtained by performing a nonlinear operation by the ReLU function on the result of the product-sum operation.

With the above-described structure, a semiconductor device with low power consumption which can effectively perform a product-sum operation corresponding to a plurality of layers of the neural network in one cell array without performing the analog-digital conversion or the digital-analog conversion during the product-sum operation can be provided.

### Embodiment 3

In this embodiment, a structure example of the cell array and its peripheral circuits described in the above embodiment will be described.

### Structure Example of Cell Array CA

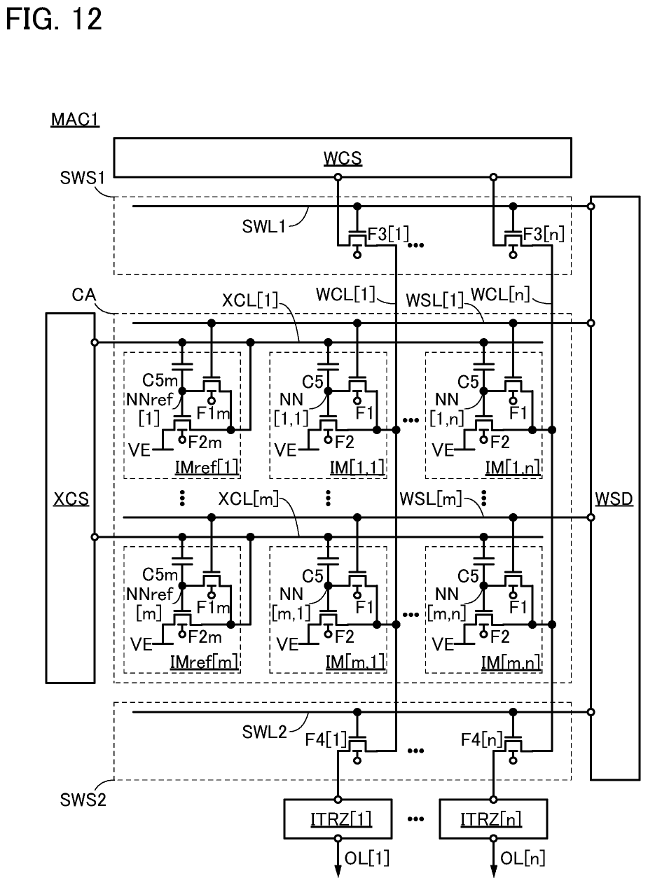

FIG. 12 illustrates a structure example of a semiconductor device that performs a product-sum operation of the weight data that is positive or “0” and the input data that is positive or “0”. A semiconductor device MACI illustrated in FIG. 12 is a circuit that performs a product-sum operation of the weight data corresponding to a potential retained in each cell and the input data that is input (first data) and performs an arithmetic operation of an activation function with the use of the intermediate data (second data) of the product-sum operation. Note that the weight data and the input data can be analog data or multilevel data (discrete data), for example.

The semiconductor device MAC1 includes the circuit WCS, the circuit XCS, the circuit WSD, a circuit SWS1, a circuit SWS2, the cell array CA, and a circuit ITRZ[1] to a circuit ITRZ[n].

The cell array CA includes a cell IM[1,1] to a cell IM[m,n] (here, m is an integer greater than or equal to 1 and n is an integer greater than or equal to 1) and a cell IMref[1] to a cell IMref[m]. The cell IM[1,1] to the cell IM[m,n] have a function of retaining a potential corresponding to the current amount according to the weight data, and the cell IMref[1] to the cell IMref[m] have a function of supplying a potential corresponding to the input data required for performing a product-sum operation with the retained weight data to a wiring XCL[1] to a wiring XCL[m].

Note that in the cell array CA in FIG. 12, cells are arranged in a matrix of n+1 rows and m columns; however, the cell array CA may have a structure in which cells are arranged in a matrix of two or more rows and two or more columns. In the case where the semiconductor device MAC and the semiconductor device MAC2 respectively described in Embodiment 1 and Embodiment 2 are employed, the cell IM corresponding to each region can be provided.

The cell IM[1,1] to the cell IM[m,n] each include a transistor F1, a transistor F2, and a capacitor C5, and the cell IMref[1] to the cell IMref[m] each include a transistor F1m, a transistor F2m, and a capacitor C5m, for example.

It is particularly preferable that the sizes of the transistors F1 (e.g., the channel lengths, the channel widths, and the transistor structures) included in the cell IM[1,1] to the cell IM[m,n] be equal to each other, and the sizes of the transistors F2 included in the cell IM[1,1] to the cell IM[m,n] be equal to each other. It is preferable that the sizes of the transistors F1m included in the cell IMref[1] to the cell IMref[m] be equal to each other, and the sizes of the transistors F2m included in the cell IMref[1] to the cell IMref[m] be equal to each other. It is also preferable that the sizes of the transistor F1 and the transistor F1m be equal to each other, and the sizes of the transistor F2 and the transistor F2m be equal to each other.

By making the transistors have the same size, the transistors can have substantially the same electrical characteristics. Thus, by making the transistors F1 included in the cell IM[1,1] to the cell IM[m,n] have the same size and the transistors F2 included in the cell IM[1,1] to the cell IM[m,n] have the same size, the cell IM[1,1] to the cell IM[m,n] can perform almost the same operation when being in the same conditions as each other. The same condition means, for example, input potentials to a source, a drain, and a gate of the transistor F1, input potentials to a source, a drain, and a gate of the transistor F2, and a voltage input to each of the cell IM[1,1] to the cell IM[m,n]. By making the transistors F1m included in the cell IMref[1] to the cell IMref[m] have the same size and the transistors F2m included in the cell IMref[1] to the cell IMref[m] have the same size, the cell IMref[1] to the cell IMref[m] can exhibit almost the same performance and yield almost the same results, for example. In the case of the same conditions, the cell IMref[1] to the cell IMref[m] can perform substantially the same operation. The same condition means, for example, input potentials to a source, a drain, and a gate of the transistor F1m, input potentials to a source, a drain, and a gate of the transistor F2m, and a voltage input to each of the cell IMref[1] to the cell IMref[m].

Unless otherwise specified, the transistor F1 and the transistor F1m in an on state may operate in a linear region in the end. In other words, the gate voltage, the source voltage, and the drain voltage of each of the above-described transistors may be within the range where the transistor operates in the linear region. However, one embodiment of the present invention is not limited thereto. For example, the transistor F1 and the transistor F1m in an on state may operate in a saturation region or may operate both in a linear region and in a saturation region.

Unless otherwise specified, the transistor F2 and the transistor F2m may operate in a subthreshold region (i.e., the gate-source voltage may be lower than the threshold voltage in the transistor F2 or the transistor F2m, further preferably, the drain current increases exponentially with respect to the gate-source voltage). In other words, the gate voltage, the source voltage, and the drain voltage of each of the above-described transistors may be within the range where the transistor operates in the subthreshold region. Thus, the transistor F2 and the transistor F2m may operate such that the off-state current flows between the source and the drain.

The transistor F1 and/or the transistor F1m are/is preferably a transistor including a metal oxide (also referred to as an oxide semiconductor) in a channel formation region (the transistor is also referred to as OS transistor), for example. In addition, it is further preferable that a channel formation region in the transistor F1 and/or the transistor F1m be an oxide containing at least one of indium, gallium, and zinc. Instead of the oxide, an oxide containing at least one of indium, an element M (as the element M, for example, one kind or a plurality of kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like can be given), and zinc may be used.

With the use of an OS transistor as the transistor F1 and/or the transistor F1m, the leakage current of the transistor F1 and/or the transistor F1m can be inhibited, so that the power consumption of the semiconductor device can be reduced. Specifically, in the case where the transistor F1 and/or the transistor F1m are/is in the non-conduction state, the amount of leakage current from a retention node to the wiring XCL or the wiring WCL can be extremely small and thus the frequency of refresh operation for the potential of the retention node can be reduced. The reduction in the frequency of refresh operations can reduce the power consumption of the semiconductor device. An extremely low leakage current from the retention node to the wiring WCL or the wiring XCL allows cells to retain the potential of the retention node for a long time, increasing the arithmetic accuracy of the semiconductor device.

The use of an OS transistor also as the transistor F2 and/or the transistor F2m enables operation with a wide range of current in the subthreshold region, leading to a reduction in the current consumption. With the use of an OS transistor also as the transistor F2 and/or the transistor F2m, the transistor F2 and/or the transistor F2m can be manufactured concurrently with the transistor F1 and the transistor F1m; thus, the manufacturing process of the semiconductor device can sometimes be shortened. The transistor F2 and/or the transistor F2m can be, other than an OS transistor, a transistor containing silicon in its channel formation region (hereinafter, referred to as a Si transistor). As the silicon, amorphous silicon (sometimes referred to as hydrogenated amorphous silicon), microcrystalline silicon, polycrystalline silicon, single crystal silicon, or the like can be used, for example.

When a semiconductor device or the like is highly integrated into a chip or the like, heat may be generated in the chip by circuit operation. This heat makes the temperature of a transistor rise to change the characteristics of the transistor, and the field-effect mobility thereof might change or the operation frequency thereof might decrease, for example. Since an OS transistor has a higher heat resistance than a Si transistor, a change in field-effect mobility and a decrease in operating frequency due to a temperature change do not easily occur. With the use of an OS transistor, arithmetic operation, processing, or the like can thus be easily performed even in a high temperature environment. To form a semiconductor device highly resistant to heat due to operation, an OS transistor is preferably used as its transistor.

In each of the cell IM[1,1] to the cell IM[m,n], a first terminal of the transistor F1 is electrically connected to the gate of the transistor F2. A first terminal of the transistor F2 is electrically connected to a wiring VE. A first terminal of the capacitor C5 is electrically connected to the gate of the transistor F2.

In each of the cell IMref[1] to the cell IMref[m], a first terminal of the transistor F1m is electrically connected to the gate of the transistor F2m. A first terminal of the transistor F2m is electrically connected to the wiring VE. A first terminal of the capacitor C5m is electrically connected to the gate of the transistor F2m.

In each of the transistor F1, the transistor F2, the transistor F1m, and the transistor F2m in FIG. 12, a back gate is illustrated but the connection structure of the back gate is not illustrated; however, a point to which the back gate is electrically connected can be determined at the design stage. For example, in a transistor including a back gate, a gate and the back gate may be electrically connected to each other to increase the on-state current of the transistor. For example, the gate and the back gate of the transistor F1 may be electrically connected to each other, and the gate and the back gate of the transistor F1m may be electrically connected to each other. Furthermore, for example, in a transistor including a back gate, a wiring electrically connecting the back gate of the transistor to an external circuit or the like may be provided and a potential may be supplied to the back gate of the transistor with the external circuit or the like to change the threshold voltage of the transistor or to reduce the off-state current of the transistor.

The transistor F1 and the transistor F2 illustrated in FIG. 12 have back gates; however, the semiconductor device of one embodiment of the present invention is not limited thereto. For example, the transistor F1 and the transistor F2 illustrated in FIG. 12 may each be a transistor having a structure not including a back gate, i.e., a single-gate structure. It is also possible that some transistors have a structure including a back gate and the other transistors have a structure not including a back gate.

The transistor F1 and the transistor F2 illustrated in FIG. 12 are n-channel transistors; however, the semiconductor device of one embodiment of the present invention is not limited thereto. For example, some or all of the transistors F1 and the transistors F2 may be replaced with p-channel transistors. When some or all of the transistors F1 and the transistors F2 are replaced with p-channel transistors, a voltage applied by a wiring, a potential of a node NN, a potential of a node NNref, and the like, which are described in this specification and the like, can be changed as appropriate for the sake of desired operations of the transistor F1 and the transistor F2.

The above-described examples of changes in the structure and polarity of the transistor are not limited to the transistor F1 and the transistor F2. For example, the structures or polarities of the transistor F1m, the transistor F2m, a transistor F3[1] to a transistor F3[n] and a transistor F4[1] to a transistor F4[n], which are described later, a transistor described in other parts of the specification, and a transistor illustrated in other drawings may also be changed.

The wiring VE functions as a wiring for supplying a current between the first terminal and a second terminal of the transistor F2 of each of the cell IM[1,1], the cell IM[m,1], the cell IM[1,n], and the cell IM[m,n] and a wiring for supplying a current between the first terminal and a second terminal of the transistor F2m of each of the cell IMref[1] and the cell IMref[m]. The wiring VE functions as a wiring for supplying a constant voltage, for example. The constant voltage can be, for example, a low-level potential, a ground potential, or the like.

In the cell IM[1,1], a second terminal of the transistor F1 is electrically connected to the wiring WCL[1], and the gate of the transistor F1 is electrically connected to the wiring WSL[1]. The second terminal of the transistor F2 is electrically connected to the wiring WCL[1], and a second terminal of the capacitor C5 is electrically connected to the wiring XCL[1]. In the cell IM[1,1] in FIG. 12, a connection portion of the first terminal of the transistor F1, the gate of the transistor F2, and the first terminal of the capacitor C5 is a node NN[1,1].

In the cell IM[m,1], the second terminal of the transistor F1 is electrically connected to the wiring WCL[1], and the gate of the transistor F1 is electrically connected to the wiring WSL[m]. The second terminal of the transistor F2 is electrically connected to the wiring WCL[1], and the second terminal of the capacitor C5 is electrically connected to the wiring XCL[m]. In the cell IM[m,1] in FIG. 12, a connection portion of the first terminal of the transistor F1, the gate of the transistor F2, and the first terminal of the capacitor C5 is a node NN[m,1].

In the cell IM[1,n], the second terminal of the transistor F1 is electrically connected to the wiring WCL[n], and the gate of the transistor F1 is electrically connected to the wiring WSL[1]. The second terminal of the transistor F2 is electrically connected to the wiring WCL[n], and the second terminal of the capacitor C5 is electrically connected to the wiring XCL[1]. In the cell IM[1,n] in FIG. 12, a connection portion of the first terminal of the transistor F1, the gate of the transistor F2, and the first terminal of the capacitor C5 is a node NN[1,n].

In the cell IM[m,n], the second terminal of the transistor F1 is electrically connected to the wiring WCL[n], and the gate of the transistor F1 is electrically connected to the wiring WSL[m]. The second terminal of the transistor F2 is electrically connected to the wiring WCL[n], and the second terminal of the capacitor C5 is electrically connected to the wiring XCL[m]. In the cell IM[m,n] in FIG. 12, a connection portion of the first terminal of the transistor F1, the gate of the transistor F2, and the first terminal of the capacitor C5 is a node NN[m,n].

In the cell IMref[1], a second terminal of the transistor F1m is electrically connected to the wiring XCL[1], and the gate of the transistor F1m is electrically connected to the wiring WSL[1]. The second terminal of the transistor F2m is electrically connected to the wiring XCL[1], and the second terminal of the capacitor C5 is electrically connected to the wiring XCL[1]. In FIG. 12, in the cell IMref[1], a connection portion of the first terminal of the transistor F1m, the gate of the transistor F2m, and the first terminal of the capacitor C5 is a node NNref[1].

In the cell IMref[m], the second terminal of the transistor F1m is electrically connected to the wiring XCL[m], and the gate of the transistor F1m is electrically connected to the wiring WSL[m]. The second terminal of the transistor F2m is electrically connected to the wiring XCL[m], and the second terminal of the capacitor C5 is electrically connected to the wiring XCL[m]. In FIG. 12, in the cell IMref[m], a connection portion of the first terminal of the transistor F1m, the gate of the transistor F2m, and the first terminal of the capacitor C5 is a node NNref[m].

The node NN[1,1] to the node NN[m,n], and the node NNref[1] to the node NNref[m] function as retention nodes of the cells.

In the case where the transistor F1 is turned on in each of the cell IM[1,1] to the cell IM[m,n], for example, the transistor F2 is a diode-connected transistor. When a constant voltage supplied from the wiring VE is a ground potential (GND), the transistor F1 is turned on, and a current with a current amount I flows from the wiring WCL to the second terminal of the transistor F2, a potential of the gate of the transistor F2 (the node NN) is determined in accordance with the current amount I. Since the transistor F1 is in the on state, a potential of the second terminal of the transistor F2 is ideally equal to that of the gate of the transistor F2 (the node NN). Here, by turning off the transistor F1, the potential of the gate of the transistor F2 (the node NN) is retained. Accordingly, the transistor F2 can make the current with the current amount I corresponding to a ground potential of the first terminal of the transistor F2 and the potential of the gate of the transistor F2 (the node NN) flow between the source and the drain of the transistor F2. In this specification and the like, such operation is called “setting (programing) the amount of current flowing between the source and the drain of the transistor F2 in the cell IM to I”.

The circuit SWS1 includes the transistor F3[1] to the transistor F3[n], for example. A first terminal of the transistor F3[1] is electrically connected to the wiring WCL[1], a second terminal of the transistor F3[1] is electrically connected to the circuit WCS, and a gate of the transistor F3[1] is electrically connected to a wiring SWL1. A first terminal of the transistor F3[n] is electrically connected to the wiring WCL[n], a second terminal of the transistor F3[n] is electrically connected to the circuit WCS, and a gate of the transistor F3[n] is electrically connected to the wiring SWL1.

As each of the transistor F3[1] to the transistor F3[n], for example, a transistor that can be used as the transistor F1 and/or the transistor F2 can be used. It is particularly preferable to use an OS transistor as each of the transistor F3[1] to the transistor F3[n].

The circuit SWS1 functions as a circuit that establishes or breaks electrical continuity between the circuit WCS and each of the wiring WCL[1] to the wiring WCL[n].

The circuit SWS2 includes the transistor F4[1] to the transistor F4[n], for example. A first terminal of the transistor F4[1] is electrically connected to the wiring WCL[1], a second terminal of the transistor F4[1] is electrically connected to an input terminal of the circuit ITRZ[1], and a gate of the transistor F4[1] is electrically connected to a wiring SWL2. A first terminal of the transistor F4[n] is electrically connected to the wiring WCL[n], a second terminal of the transistor F4[n] is electrically connected to an input terminal of the circuit ITRZ[n], and a gate of the transistor F4[n] is electrically connected to the wiring SWL2.

As each of the transistor F4[1] to the transistor F4[n], for example, a transistor that can be used as the transistor F1 and/or the transistor F2 can be used. It is particularly preferable to use an OS transistor as each of the transistor F4[1] to the transistor F4[n].

The circuit SWS2 has a function of establishing or breaking electrical continuity between the wiring WCL[1] and the circuit ITRZ[1] and between the wiring WCL[n] and the circuit ITRZ[n].

The circuit WCS has a function of supplying data that is to be retained in each cell of the cell array CA.

The circuit XCS is electrically connected to the wiring XCL[1] to the wiring XCL[m]. The circuit XCS has a function of supplying a current with the amount corresponding to reference data described later or a current with the amount corresponding to the input data to each of the cell IMref[I] to the cell IMref[m] included in the cell array CA.

The circuit WSD is electrically connected to the wiring WSL[1] to the wiring WSL[m]. The circuit WSD has a function of selecting a row of the cell array CA to which the weight data is written, by supplying a predetermined signal to the wiring WSL[1] to the wiring WSL[m] at the time of writing the weight data to the cell IM[1,1] to the cell IM[m,n]. That is, the wiring WSL[1] to the wiring WSL[m] function as write word lines.

The circuit WSD is electrically connected to the wiring SWL1 and the wiring SWL2, for example. The circuit WSD has a function of establishing or breaking electrical continuity between the circuit WCS and the cell array CA by supplying a predetermined signal to the wiring SWL1, and a function of establishing or breaking electrical continuity between the circuit ITRZ[1] to the circuit ITRZ[n] and the cell array CA by supplying a predetermined signal to the wiring SWL2.

The circuit ITRZ[1] to the circuit ITRZ[n] each include an input terminal and an output terminal, for example. An output terminal of the circuit ITRZ[1] is electrically connected to a wiring OL[1], and an output terminal of the circuit ITRZ[n] is electrically connected to a wiring OL[n], for example.

The circuit ITRZ[1] to the circuit ITRZ[n] each have a function of converting a current input to input terminals into a voltage according to the amount of the current and outputting the voltage from output terminals. The voltage can be, for example, an analog voltage, a digital voltage, and the like. The circuit ITRZ[1] to the circuit ITRZ[n] may each include a semiconductor device performing an arithmetic operation of a function. In that case, for example, the semiconductor device may perform an arithmetic operation of a function with the use of the converted voltage and may output the arithmetic operation results to the wiring OL[1] to the wiring OL[n].

In particular, in the case of performing an arithmetic operation of the hierarchical neural network, a sigmoid function, a tanh function, a softmax function, a ReLU function, a threshold function, or the like can be used as the above-described nonlinear function.

### Structure Example of Circuit WCS and Circuit XCS

Structure examples of the circuit WCS and the circuit XCS will be described.

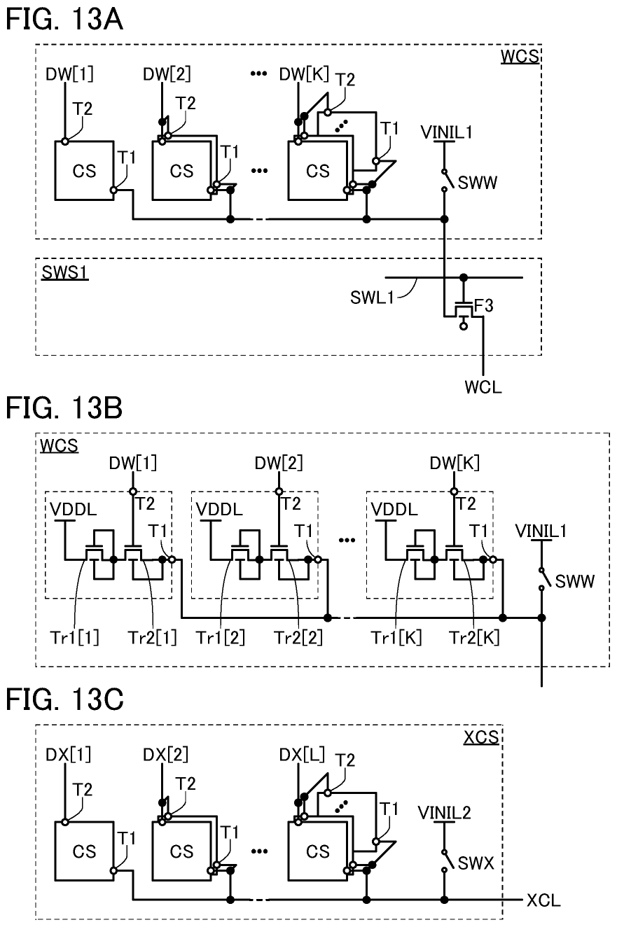

First, the circuit WCS is described. FIG. 13A is a block diagram illustrating an example of the circuit WCS. In FIG. 13A, to illustrate the electrical connection between the circuit WCS and its peripheral circuits, the circuit SWS1, the transistor F3, the wiring SWL1, and the wiring WCL are also illustrated. The transistor F3 is any one of the transistor F3[1] to the transistor F3[n] included in the semiconductor device MAC1 in FIG. 12, and the wiring WCL is any one of the wiring WCL[1] to the wiring WCL[n] included in the semiconductor device MAC1 in FIG. 12.

The circuit WCS illustrated in FIG. 13A includes a switch SWW, for example. A first terminal of the switch SWW is electrically connected to the second terminal of the transistor F3, and a second terminal of the switch SWW is electrically connected to a wiring VINIL1. The wiring VINIL1 functions as a wiring for supplying an initialization potential to the wiring WCL, and the initialization potential can be set to a ground potential (GND), a low-level potential, a high-level potential, or the like. Note that the switch SWW is in an on state only when the initialization potential is supplied to the wiring WCL; otherwise, the switch is in an off state.

As the switch SWW, an electrical switch such as an analog switch or a transistor can be used, for example. When a transistor is used as the switch SWW, for example, the transistor can be a transistor having a structure similar to that of the transistor F1 and the transistor F2. Other than the electrical switch, a mechanical switch may be used.

The circuit WCS in FIG. 13A includes a plurality of current sources CS, for example. Specifically, the circuit WCS has a function of outputting K-bit weight data (2^{K} values) (K is an integer greater than or equal to 1) as the current amount, and the circuit WCS includes 2^{K}−1 current sources CS at that time. Note that the circuit WCS includes one current source CS that outputs information corresponding to the first bit value as a current, two current sources CS that output information corresponding to the second bit value as a current, and the 2^{K-1} current sources CS that output information corresponding to the K-th bit value as a current.

Each of the current sources CS in FIG. 13A includes a terminal T1 and a terminal T2. The terminal T1 of each of the current sources CS is electrically connected to the second terminal of the transistor F3 included in the circuit SWS1. The terminal T2 of the one current source CS is electrically connected to a wiring DW[1], the terminals T2 of the two current sources CS are electrically connected to a wiring DW[2], and the terminals T2 of the 2^{K-1} current sources CS are electrically connected to a wiring DW[K].

The plurality of current sources CS included in the circuit WCS have a function of outputting the same constant current I_{Wut} from the terminals T1. In practice, at the manufacturing stage of the semiconductor device MAC1, transistors included in the current sources CS may have different electrical characteristics; this may yield an error. The error in the constant current I_{Wut} output from each of the terminals T1 of the plurality of current sources CS is thus preferably within 10%, further preferably within 5%, still further preferably within 1%. In this embodiment, the description is made on the assumption that there is no error in the constant current I_{Wut} output from each of the terminals T1 of the plurality of current sources CS included in the circuit WCS.

The wiring DW[1] to the wiring DW[K] function as wirings for transmitting control signals to allow the current sources CS, which are electrically connected to the wiring DW[1] to the wiring DW[K], to output the constant current I_{Wut}. Specifically, for example, when a high-level potential is supplied to the wiring DW[1], the current source CS electrically connected to the wiring DW[1] supplies I_{Wut} as a constant current to the second terminal of the transistor F3, and when a low-level potential is supplied to the wiring DW[1], the current source CS electrically connected to the wiring DW[1] does not output I_{Wut}. For example, when a high-level potential is supplied to the wiring DW[2], the two current sources CS electrically connected to the wiring DW[2] supply the sum of constant currents 2I_{Wut} to the second terminal of the transistor F3, and when a low-level potential is supplied to the wiring DW[2], the current sources CS electrically connected to the wiring DW[2] do not output the sum of constant currents 2I_{Wut}. For example, when a high-level potential is supplied to the wiring DW[K], the 2^{K-1} current sources CS electrically connected to the wiring DW[K] supply the sum of constant currents 2^{K-1}I_{Wut} to the second terminal of the transistor F3, and when a low-level potential is supplied to the wiring DW[K], the current sources CS electrically connected to the wiring DW[K] do not output the sum of constant currents 2^{K-1}I_{Wut}.

The current flowing from the one current source CS electrically connected to the wiring DW[1] corresponds to the value of the first bit, the current flowing from the two current sources CS electrically connected to the wiring DW[2] corresponds to the value of the second bit, and the amount of current flowing from the K current sources CS electrically connected to the wiring DW[K] corresponds to the value of the K-th bit. The circuit WCS with K of 2 is considered. For example, when the value of the first bit is “1” and the value of the second bit is “0”, a high-level potential is supplied to the wiring DW[1], and a low-level potential is supplied to the wiring DW[2]. In this case, the constant current I_{Wut} flows into the second terminal of the transistor F3 of the circuit SWS1 from the circuit WCS. For example, when the value of the first bit is “0” and the value of the second bit is “1”, a low-level potential is supplied to the wiring DW[1], and a high-level potential is supplied to the wiring DW[2]. In this case, the constant current 2I_{Wut} flows from the circuit WCS to the second terminal of the transistor F3 of the circuit SWS1. For example, when the value of the first bit is “1” and the value of the second bit is “1”, a high-level potential is supplied to the wiring DW[1] and the wiring DW[2]. In this case, the constant current 3I_{Wut} flows from the circuit WCS to the second terminal of the transistor F3 of the circuit SWS1. For example, when the value of the first bit is “0” and the value of the second bit is “0”, a low-level potential is supplied to the wiring DW[1] and the wiring DW[2]. In this case, the constant current does not flow from the circuit WCS into the second terminal of the transistor F3 of the circuit SWS1.

FIG. 13A illustrates the circuit WCS when K is an integer of 3 or more; when K is 1, the current sources CS electrically connected to the wiring DW[2] to the wiring DW[K] are not provided in the circuit WCS in FIG. 13A. When K is 2, the current sources CS electrically connected to the wiring DW[3] to the wiring DW[K] are not provided in the circuit WCS in FIG. 13A.

Next, a specific structure example of the current source CS is described.

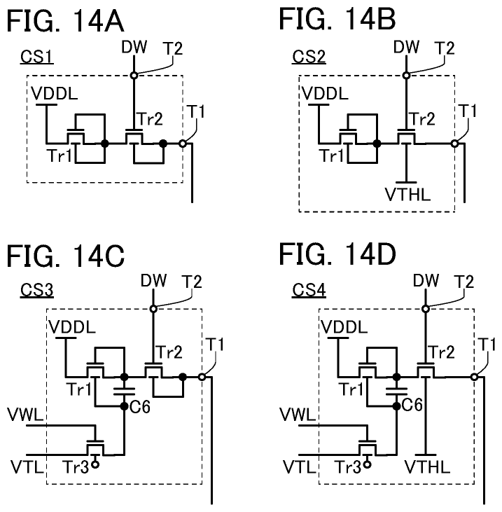

A current source CS1 illustrated in FIG. 14A is a circuit that can be used as the current source CS included in the circuit WCS in FIG. 13A, and the current source CS1 includes a transistor Tr1 and a transistor Tr2.

A first terminal of the transistor Tr1 is electrically connected to a wiring VDDL, and a second terminal of the transistor Tr1 is electrically connected to a gate of the transistor Tr1, a back gate of the transistor Tr1, and a first terminal of the transistor Tr2. A second terminal of the transistor Tr2 is electrically connected to the terminal T1, and a gate of the transistor Tr2 is electrically connected to the terminal T2. The terminal T2 is electrically connected to the wiring DW.

The wiring DW is any one of the wiring DW[1] to the wiring DW[K] in FIG. 13A.

The wiring VDDL functions as a wiring for supplying a constant voltage. The constant voltage can be a high-level potential, for example.

When a constant voltage supplied from the wiring VDDL is set at a high-level potential, a high-level potential is input to the first terminal of the transistor Tr1. A potential of the second terminal of the transistor Tr1 is lower than the high-level potential. At this time, the first terminal of the transistor Tr1 functions as a drain, and the second terminal of the transistor Tr1 functions as a source. Since the gate of the transistor Tr1 and the second terminal of the transistor Tr1 are electrically connected to each other, the gate-source voltage of the transistor Tr1 is 0 V. In the case where the threshold voltage of the transistor Tr1 is within an appropriate range, a current in the current range of the subthreshold region (drain current) flows between the first terminal and the second terminal of the transistor Tr1. The amount of the current is preferably smaller than or equal to 1.0×10⁻⁸ A, further preferably smaller than or equal to 1.0×10⁻¹² A, still further preferably smaller than or equal to 1.0×10⁻¹⁵ A, for example, in the case where the transistor Tr1 is an OS transistor. For example, the current is further preferably within a range where the current exponentially increases with respect to the gate-source voltage. That is, the transistor Tr1 functions as a current source for supplying a current within a current range of the transistor Tr1 operating in the subthreshold region. The current corresponds to I_{Wut} described above or I_{Xut} described later.

The transistor Tr2 functions as a switching element. In the case where a potential of the first terminal of the transistor Tr2 is higher than a potential of the second terminal of the transistor Tr2, the first terminal of the transistor Tr2 functions as a drain and the second terminal of the transistor Tr2 functions as a source. Since a back gate of the transistor Tr2 and the second terminal of the transistor Tr2 are electrically connected to each other, a back gate-source voltage becomes 0 V. Thus, when the threshold voltage of the transistor Tr2 is within an appropriate range and a high-level potential is input to the gate of the transistor Tr2, the transistor Tr2 is turned on; when a low-level potential is input to the gate of the transistor Tr2, the transistor Tr2 is turned off. Specifically, when the transistor Tr2 is in an on state, a current within the current range of the subthreshold region flows from the second terminal of the transistor Tr1 to the terminal T1, and when the transistor Tr2 is in an off state, the current does not flow from the second terminal of the transistor Tr1 to the terminal T1.

The circuit that can be used as the current source CS included in the circuit WCS in FIG. 13A is not limited to the current source CS1 in FIG. 14A. For example, the current source CS1 has a structure in which the back gate of the transistor Tr2 and the second terminal of the transistor Tr2 are electrically connected to each other; however, a structure in which the back gate of the transistor Tr2 is electrically connected to another wiring may be employed. Such a structure example is illustrated in FIG. 14B. In a current source CS2 illustrated in FIG. 14B, the back gate of the transistor Tr2 is electrically connected to a wiring VTHL. When the wiring VTHL of the current source CS2 is electrically connected to an external circuit or the like, the external circuit or the like supplies a predetermined potential to the wiring VTHL and the back gate of the transistor Tr2 can be supplied with the predetermined potential. This can change the threshold voltage of the transistor Tr2. In particular, the off-state current of the transistor Tr2 can be reduced by an increase in the threshold voltage of the transistor Tr2.

For example, the current source CS1 has a structure in which the back gate of the transistor Tr1 and the second terminal of the transistor Tr1 are electrically connected to each other; however, a structure in which the voltage between the back gate and the second terminal of the transistor Tr2 is retained with a capacitor may be employed. Such a structure example is illustrated in FIG. 14C. A current source CS3 illustrated in FIG. 14C includes a transistor Tr3 and a capacitor C6 in addition to the transistor Tr1 and the transistor Tr2. The current source CS3 is different from the current source CS1 in that the second terminal of the transistor Tr1 and the back gate of the transistor Tr1 are electrically connected to each other through the capacitor C6, and the back gate of the transistor Tr1 and a first terminal of the transistor Tr3 are electrically connected to each other. In the current source CS3, a second terminal of the transistor Tr3 is electrically connected to a wiring VTL, and a gate of the transistor Tr3 is electrically connected to a wiring VWL. In the current source CS3, the wiring VWL is supplied with a high-level potential to turn on the transistor Tr3, so that electrical continuity can be established between the wiring VTL and the back gate of the transistor Tr1. In this case, a predetermined potential can be input to the back gate of the transistor Tr1 from the wiring VTL. The wiring VWL is supplied with a low-level potential to turn off the transistor Tr3, so that a voltage between the second terminal of the transistor Tr1 and the back gate of the transistor Tr1 can be retained with the capacitor C6. That is, by setting the voltage supplied to the back gate of the transistor Tr1 from the wiring VTL, the threshold voltage of the transistor Tr1 can be changed and the threshold voltage of the transistor Tr1 can be fixed with the transistor Tr3 and the capacitor C6.

Alternatively, for example, as the circuit that can be used as the current source CS included in the circuit WCS in FIG. 13A, a current source CS4 illustrated in FIG. 14D may be used. The current source CS4 has a structure in which the back gate of the transistor Tr2 is electrically connected not to the second terminal of the transistor Tr2 but to the wiring VTHL in the current source CS3 in FIG. 14C. That is, the current source CS4 can change the threshold voltage of the transistor Tr2 with the potential supplied from the wiring VTHL, as in the current source CS2 in FIG. 14B.

When a high current flows between the first terminal and the second terminal of the transistor Tr1 in the current source CS4, the on-state current of the transistor Tr2 needs to be increased to supply the current from the terminal T1 to the outside of the current source CS4. In this case, in the current source CS4, a high-level potential is supplied to the wiring VTHL to decrease the threshold voltage of the transistor Tr2 and increase the on-state current of the transistor Tr2, whereby the high current flowing between the first terminal and the second terminal of the transistor Tr1 can be supplied from the terminal T1 to the outside of the current source CS4.

The use of the current source CS1 to the current source CS4 illustrated in FIG. 14A to FIG. 14D as the current sources CS included in the circuit WCS in FIG. 13A enables the circuit WCS to output a current corresponding to the K-bit weight data. The amount of the current can be the amount of current flowing between the first terminal and the second terminal of the transistor F1 in the range where the transistor F1 operates in the subthreshold region.

As the circuit WCS in FIG. 13A, the circuit WCS illustrated in FIG. 13B can be used. In the circuit WCS in FIG. 13B, one current source CS in FIG. 14A is connected to each of the wiring DW[1] to the wiring DW[K]. When the channel width of a transistor Tr1[1] is w[1], the channel width of a transistor Tr1[2] is w[2], and the channel width of a transistor Tr1[K] is w[K], the ratio of the channel widths is w[1]:w[2]:w[K]=1:2:2^{K-1}. Since a current flowing between a source and a drain of a transistor that operates in the subthreshold region is proportional to the channel width, the circuit WCS illustrated in FIG. 13B can output a current corresponding to the K-bit weight data like the circuit WCS in FIG. 13A.

As the transistor Tr1 (including the transistor Tr1 [1] to a transistor Tr2[K]), the transistor Tr2 (including a transistor Tr2[1] to the transistor Tr2[K]), and the transistor Tr3, a transistor that can be used as the transistor F1 and/or the transistor F2 can be used, for example. In particular, as the transistor Tr1 (including the transistor Tr1[1] to the transistor Tr2[K]), the transistor Tr2 (including the transistor Tr2[1] to the transistor Tr2[K]), and the transistor Tr3, OS transistors are preferably used.

Next, a specific example of the circuit XCS will be described.

FIG. 13C is a block diagram illustrating an example of the circuit XCS. FIG. 13C also illustrates the wiring XCL to show the electrical connection between the circuit WCS and its peripheral circuits. The wiring XCL is any one of the wiring XCL[1] to the wiring XCL[m] included in the semiconductor device MAC1 in FIG. 12.

The circuit XCS illustrated in FIG. 13C includes a switch SWX, for example. A first terminal of the switch SWX is electrically connected to the wiring XCL and a plurality of the current sources CS, and a second terminal of the switch SWX is electrically connected to a wiring VINIL2. The wiring VINIL2 functions as a wiring for supplying an initialization potential to the wiring XCL, and the initialization potential can be set to a ground potential (GND), a low-level potential, a high-level potential, or the like. The initialization potential supplied by the wiring VINIL2 can be the same as the potential supplied by the wiring VINIL1. Note that the switch SWX is in an on state only when the initialization potential is supplied to the wiring XCL; otherwise, the switch is in an off state.

The switch SWX can be, for example, a switch that can be used as the switch SWW.

The circuit XCS in FIG. 13C can have almost the same circuit structure as the circuit WCS in FIG. 14A. Specifically, the circuit XCS has a function of outputting reference data as the current amount, and a function of outputting L-bit input data (2^{L} values) (L is an integer of greater than or equal to 1) as the current amount, and the circuit XCS includes 2^{L-1} current sources CS at that time. The circuit XCS includes one current source CS that outputs information corresponding to the first bit value as a current, two current sources CS that output information corresponding to the second bit value as a current, and 2^{L-1} current sources CS that output information corresponding to the L-th bit value as a current.

The reference data output from the circuit XCS as a current can be information in which the first bit value is “1” and the second and subsequent bit values are “0”, for example.

In FIG. 13C, the terminal T2 of the one current source CS is electrically connected to a wiring DX[1], the terminals T2 of the two current sources CS are electrically connected to a wiring DX[2], and the terminals T2 of the 2^{L-1} current sources CS are electrically connected to a wiring DX[L].

The plurality of current sources CS included in the circuit XCS have a function of outputting the same constant currents I_{Xut} from the terminals T1. The wiring DX[1] to the wiring DX[L] electrically connected to the current sources CS function as wirings for transmitting control signals to make the current sources CS output I_{Xut}. In other words, the circuit XCS has a function of supplying the current amount corresponding to the L-bit information sent from the wiring DX[1] to the wiring DX[L] to the wiring XCL. Note that the control signals transmitted to the wiring DX[1] to the wiring DX[L] can be transmitted to respective rows by the shift register, the latch circuit, and the like described in Embodiment 1.

Specifically, the circuit XCS with L of 2 is considered. For example, when the value of the first bit is “1” and the value of the second bit is “0”, a high-level potential is supplied to the wiring DX[1], and a low-level potential is supplied to the wiring DX[2]. In this case, the constant current I_{Xut} flows from the circuit XCS to the wiring XCL. For example, when the value of the first bit is “0” and the value of the second bit is “1”, a low-level potential is supplied to the wiring DX[1], and a high-level potential is supplied to the wiring DX[2]. In this case, the constant current 2I_{Xut} flows from the circuit XCS to the wiring XCL. For example, when the value of the first bit is “1” and the value of the second bit is “1”, a high-level potential is supplied to the wiring DX[1] and the wiring DX[2]. In this case, the constant current 3I_{Xut} flows from the circuit XCS to the wiring XCL. For example, when the value of the first bit is “0” and the value of the second bit is “0”, a low-level potential is supplied to the wiring DX[1] and the wiring DX[2]. In this case, the constant current does not flow from the circuit XCS to the wiring XCL. In this case, in this specification and the like, it is also said that the current amount 0 flows from the circuit XCS to the wiring XCL, in some cases. The current amount 0, I_{Xut}, 2I_{Xut}, 3I_{Xut}, or the like output from the circuit XCS can be the input data output from the circuit XCS; particularly, the current amount I_{Xut} a output from the circuit XCS can be the reference data output from the circuit XCS.

When the transistors included in the current sources CS included in the circuit XCS have different electrical characteristics and this yields errors, the errors in the constant currents I_{Xut} output from the terminals T1 of the plurality of current sources CS are preferably within 10%, further preferably within 5%, still further preferably within 1%. In this embodiment, the description is made on the assumption that there is no error in the constant currents I_{Xut} a output from the terminals T1 of the plurality of current sources CS included in the circuit XCS.

As the current source CS of the circuit XCS, any of the current source CS1 to the current source CS4 in FIG. 14A to FIG. 14D can be used as in the case of the current source CS of the circuit WCS. In this case, the wiring DW illustrated in FIG. 14A to FIG. 14D is replaced with the wiring DX. This allows the circuit XCS to make a current within the current range of the subthreshold region flow through the wiring XCL as the reference data or the L-bit input data.

The circuit XCS in FIG. 13C can have a circuit structure similar to that of the circuit WCS illustrated in FIG. 13B. In this case, the circuit WCS illustrated in FIG. 13B is replaced with the circuit XCS, the wiring DW[1] is replaced with the wiring DX[1], the wiring DW[2] is replaced with the wiring DX[2], the wiring DW[K] is replaced with the wiring DX[L], the switch SWW is replaced with the switch SWX, and the wiring VINIL1 is replaced with the wiring VINIL2.

### Structure Example of Circuit ITRZ

Here, a structure example of a circuit that can be used as the circuit ITRZ[1] to the circuit ITRZ[n] included in the semiconductor device MAC1 in FIG. 12 is described.

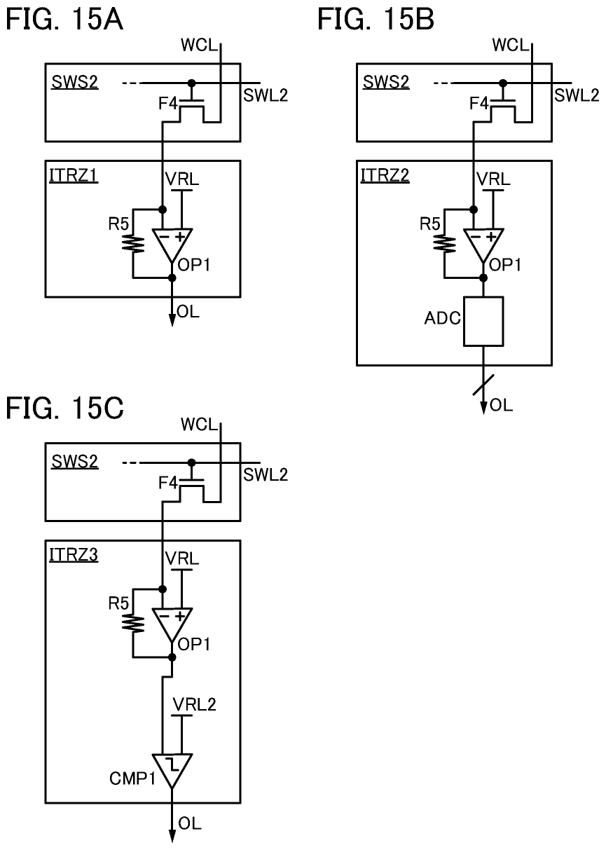

A circuit ITRZ1 illustrated in FIG. 15A is an example of a circuit that can be used as the circuit ITRZ[1] to the circuit ITRZ[n] in FIG. 12. FIG. 15A also illustrates the circuit SWS2, the wiring WCL, the wiring SWL2, and the transistor F4 to show the electrical connection between the circuit ITRZ1 and its peripheral circuits. The wiring WCL is any one of the wiring WCL[1] to the wiring WCL[n] included in the semiconductor device MAC1 in FIG. 12, and the transistor F4 is any one of the transistor F4[1] to the transistor F4[n] included in the semiconductor device MAC1 in FIG. 12.

The circuit ITRZ1 in FIG. 15A is electrically connected to the wiring WCL through the transistor F4. The circuit ITRZ1 is electrically connected to the wiring OL. The circuit ITRZ1 has a function of converting the amount of current flowing from the circuit ITRZ1 to the wiring WCL, or the amount of current flowing from the wiring WCL to the circuit ITRZ1 into an analog voltage and outputting the analog voltage to the wiring OL. That is, the circuit ITRZ1 includes a current-voltage converter circuit.

The circuit ITRZ1 in FIG. 15A includes a resistor R5 and an operational amplifier OP1, for example.

An inverting input terminal of the operational amplifier OP1 is electrically connected to a first terminal of the resistor R5 and a second terminal of the transistor F4. A non-inverting input terminal of the operational amplifier OP1 is electrically connected to a wiring VRL. An output terminal of the operational amplifier OP1 is electrically connected to a second terminal of the resistor R5 and the wiring OL.

The wiring VRL functions as a wiring for supplying a constant voltage. The constant voltage can be a ground potential (GND), a low-level potential, or the like, for example.

The circuit ITRZ1 with the structure in FIG. 15A can convert the amount of current flowing from the wiring WCL to the circuit ITRZ1 through the transistor F4 or the amount of current flowing from the circuit ITRZ1 to the wiring WCL through the transistor F4 into an analog voltage to output it to the wiring OL.

In particular, by setting the constant voltage applied from the wiring VRL to a ground potential (GND), the inverting input terminal of the operational amplifier OP1 is virtually grounded, and the analog voltage output to the wiring OL can be a voltage with reference to the ground potential (GND).

The circuit ITRZ1 in FIG. 15A outputs an analog voltage; however, a circuit structure that can be used for the circuit ITRZ[1] to the circuit ITRZ[n] in FIG. 12 is not limited thereto. For example, the circuit ITRZ1 may include an analog-digital converter circuit ADC as illustrated in FIG. 15B. Specifically, in a circuit ITRZ2 in FIG. 15B, an input terminal of the analog-digital converter circuit ADC is electrically connected to the output terminal of the operational amplifier OP1 and the second terminal of the resistor R5, and an output terminal of the analog-digital converter circuit ADC is electrically connected to the wiring OL. With such a structure, the circuit ITRZ2 in FIG. 15B can output a digital signal to the wiring OL. Note that the digital signal output to the wiring OL can be converted into a serial signal by the shift register, the latch circuit, the switch, and the like described in Embodiment 1 and output to the outside.

In the case where the digital signal output to the wiring OL is a 1-bit (binary) signal in the circuit ITRZ2, the circuit ITRZ2 may be replaced with a circuit ITRZ3 illustrated in FIG. 15C. The circuit ITRZ3 in FIG. 15C has a structure in which a comparator CMP1 is provided in the circuit ITRZ1 in FIG. 15A. Specifically, the circuit ITRZ3 has a structure in which a first input terminal of the comparator CMP1 is electrically connected to the output terminal of the operational amplifier OP1 and the second terminal of the resistor R5, a second input terminal of the comparator CMP1 is electrically connected to a wiring VRL2, and an output terminal of the comparator CMP1 is electrically connected to the wiring OL. The wiring VRL2 functions as a wiring supplying a potential to be compared with the potential of the first terminal of the comparator CMP1. With such a structure, the circuit ITRZ3 in FIG. 15C can output a low-level potential or a high-level potential (a binary digital signal) to the wiring OL in accordance with the magnitude relationship between the voltage converted with the current-voltage converter circuit from the amount of current flowing between the source and the drain of the transistor F4 and the voltage supplied from the wiring VRL2.

The circuit ITRZ[1] to the circuit ITRZ[n] that can be used for the semiconductor device MAC1 in FIG. 12 are not limited to the circuit ITRZ1 to the circuit ITRZ3 illustrated in FIG. 15A to FIG. 15C. In the case where the semiconductor device MAC1 is used for an arithmetic operation of a hierarchical neural network, for example, the circuit ITRZ1 to the circuit ITRZ3 preferably have semiconductor devices that perform an arithmetic operation of a function. As a semiconductor device that performs an arithmetic operation of a function, a semiconductor device with a sigmoid function, a tanh function, a softmax function, a ReLU function, a threshold function, or the like can be used.

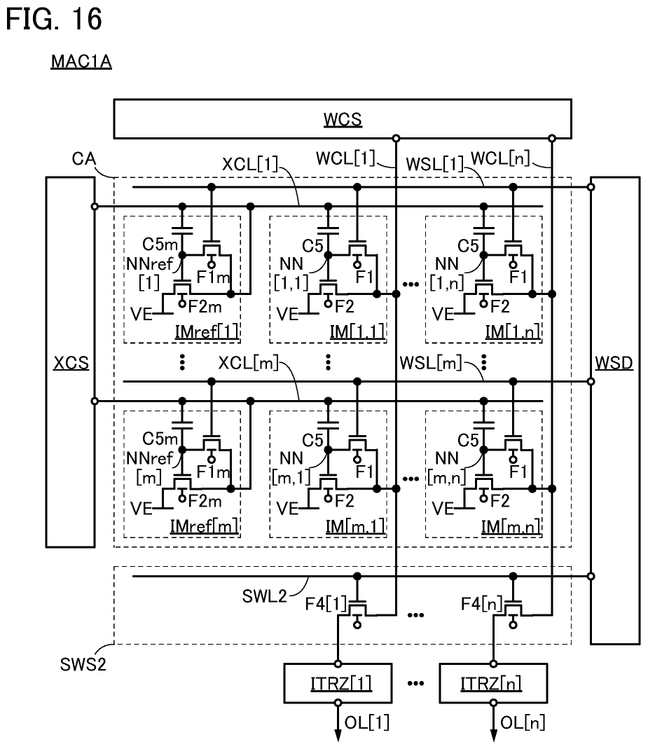

One embodiment of the present invention is not limited to the circuit structure of the semiconductor device MAC1 described in this embodiment. The circuit structure of the semiconductor device MAC1 can be changed depending on circumstances. For example, the semiconductor device MAC1 may be changed to a structure without the circuit SWS1 like a semiconductor device MAC1A illustrated in FIG. 16. The semiconductor device MAC1 can stop a current flowing from the circuit WCS to the wiring WCL[1] to the wiring WCL[n] with the circuit SWS1; the semiconductor device MAC1A stops a current flowing from the circuit WCS to the wiring WCL[1] to the wiring WCL[n] with the circuit WCS. Specifically, when the circuit WCS in FIG. 13A is used as the circuit WCS included in the semiconductor device MAC1A and the current source CS1 in FIG. 14A is used as the current source CS, a low-level potential is input to the wiring DW[1] to the wiring DW[K] and the switch SWW is turned off. By performing operations of the circuit WCS in this manner, a current flowing from the circuit WCS to the wiring WCL[1] to the wiring WCL[n] can be stopped. In this manner, a current flowing from the circuit WCS to the wiring WCL[1] to the wiring WCL[n] is stopped with the circuit WCS, whereby the semiconductor device MAC1A can be used instead of the semiconductor device MAC1 for an arithmetic operation.

### Operation Example of Semiconductor Device

Next, an operation example of the semiconductor device MAC1 will be described.

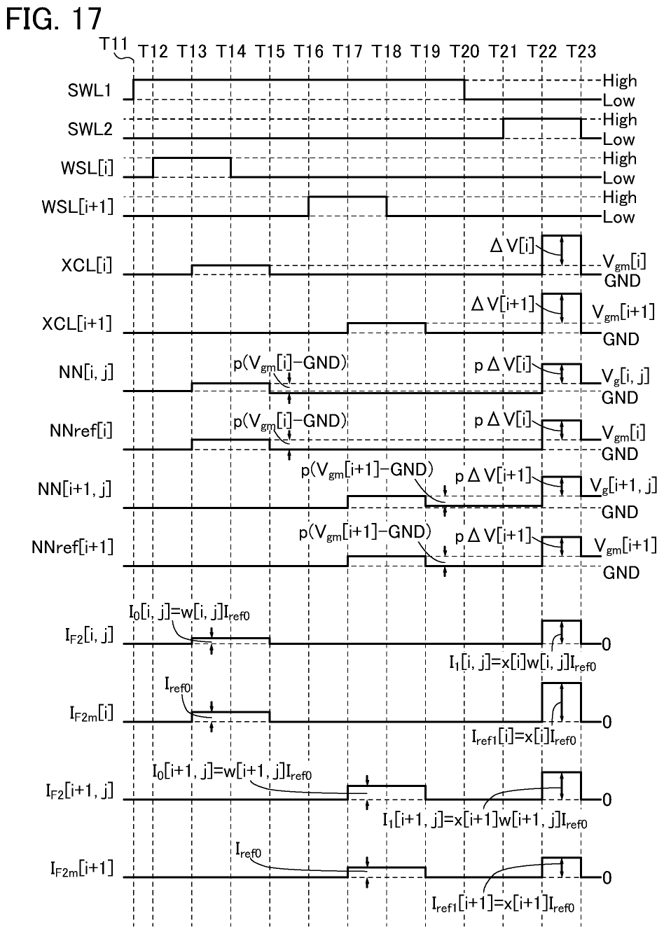

FIG. 17 shows a timing chart of the operation example of the semiconductor device MAC1. The timing chart in FIG. 17 shows changes in the potentials of the wiring SWL1, the wiring SWL2, the wiring WSL[i] (i is an integer greater than or equal to 1 and less than or equal to m−1), the wiring WSL[i+1], the wiring XCL[i], the wiring XCL[i+1], the node NN[i,j] (i in an integer greater than or equal to 1 and less than or equal to n−1), the node NN[i+1,j], the node NNref[i], and the node NNref[i+1] in the period from Time T11 to Time T23 and around the period. The timing chart in FIG. 17 also shows changes in the amount of current I_{F2}[i,j] flowing between the first terminal and the second terminal of the transistor F2 included in the cell IM[i,j]; the amount of current I_{F2m}[i] flowing between the first terminal and the second terminal of the transistor F2m included in the cell IMref[i]; the amount of current I_{F2}[i+1,j] flowing between the first terminal and the second terminal of the transistor F2 included in the cell IM[i+1,j]; and the amount of current I_{F2m}[i+1] flowing between the first terminal and the second terminal of the transistor F2m included in the cell IMref[i+1].

The circuit WCS in FIG. 13A is used as the circuit WCS of the semiconductor device MAC1, and the circuit XCS in FIG. 13C is used as the circuit XCS of the semiconductor device MAC1.

Note that in this operation example, the potential of the wiring VE is a ground potential GND. Before Time T11, each potential of the node NN[i,j], the node NN[i+1,j], the node NNref[i], and the node NNref[i+1] is the ground potential GND. Specifically, for example, the initialization potential of the wiring VINIL1 in FIG. 13A is set to the ground potential GND, and the switch SWW, the transistor F3, and the transistor F1 included in each of the cell IM[i,j] and the cell IM[i+1j] are turned on, whereby the potentials of the node NN[i,j] and the node NN[i+1,j] can be set to the ground potential GND. For example, the initialization potential of the wiring VINIL2 in FIG. 13C is set to the ground potential GND, and the switch SWX and the transistor F1m included in each of the cell IMref[i,j] and the cell IMref[i+1,j] are turned on, whereby the potentials of the node NNref[i,j] and the node NNref[i+1,j] can be set to the ground potential GND.

In the period from Time T11 to Time T12, a high-level potential (shown as High in FIG. 17) is applied to the wiring SWL1, and a low-level potential (shown as Low in FIG. 17) is applied to the wiring SWL2. Accordingly, the high-level potential is applied to each of the gates of the transistor F3[1] to the transistor F3[n] so that the transistor F3[1] to the transistor F3[n] are turned on, and the low-level potential is applied to each of the gates of the transistor F4[i] to the transistor F4[n] so that the transistor F4[I] to the transistor F4[n] are turned off.

In the period from Time T11 to Time T12, a low-level potential is applied to the wiring WSL[i] and the wiring WSL[i+1]. Accordingly, in the i-th row of the cell array CA, a low-level potential is applied to the gates of the transistors F1 included in the cell IM[i,1] to the cell IM[i,n] and the gate of the transistor F1m included in the cell IMref[i] so that the transistors F1 and the transistor F1m are turned off. In addition, in the i+1-th row of the cell array CA, a low-level potential is applied to the gates of the transistors F1 included in the cell IM[i+1,1] to the cell IM[i+1,n] and the gate of the transistor F1m included in the cell IMref[i+1] so that the transistors F1 and the transistor F1m are turned off.

In the period from Time T11 to Time T12, the ground potential GND is applied to the wiring XCL[i] and the wiring XCL[i+1]. Specifically, for example, when the wiring XCL illustrated in FIG. 13C is the wiring XCL[i] and the wiring XCL[i+1], the initialization potential of the wiring VINIL2 is set to the ground potential GND, and the switch SWX is turned on, the potentials of the wiring XCL[i] and the wiring XCL[i+1] can be set to the ground potential GND.

In the period from Time T11 to Time T12, when the wiring WCL illustrated in FIG. 13A is the wiring WCL[1] to the wiring WCL[K], the weight data is not input to the wiring DW[1] to the wiring DW[K]. When the wiring XCL in FIG. 13C is the wiring XCL[i] to the wiring XCL[K], the input data is not input to the wiring DX[i] to the wiring DX[L]. Here, it is assumed that a low-level potential is input to the wiring DW[1] to the wiring DW[K] in the circuit WCS in FIG. 13A, and a low-level potential is input to the wiring DX[i] to the wiring DX[L] in the circuit XCS in FIG. 13C.

In the period from Time T11 to Time T12, a current does not flow through the wiring WCL[j], the wiring XCL[i], and the wiring XCL[i+i]. Therefore, I_{F2}[i,j], I_{F2m}[i], I_{F2}[i+1,j], and I_{F2m}[i+1] are each 0.

In the period from Time T12 to Time T13, a high-level potential is applied to the wiring WSL[i]. Accordingly, in the i-th row of the cell array CA, a high-level potential is applied to the gates of the transistors F1 included in the cell IM[i,1] to the cell IM[i,n] and the gate of the transistor F1m included in the cell IMref[i] so that the transistors F1 and the transistor F1m are turned on. Furthermore, in the period from Time T12 to Time T13, a low-level potential is applied to the wiring WSL[i] to the wiring WSL[m] except the wiring WSL[i], and in the cell array CA, the transistors F1 included in the cell IM[1,1] to the cell IM[m,n] in the rows other than the i-th row and the transistors F1m included in the cell IMref[1] to the cell IMref[m] in the rows other than the i-th row are in the off state.

The ground potentials GND have been continuously applied to the wiring XCL[1] to the wiring XCL[m] since before Time T12.

In the period from Time T13 to Time T14, a current with a current amount I₀[i,j] flows as the weight data from the circuit WCS to the cell array CA through the transistor F3[j]. Specifically, when the wiring WCL illustrated in FIG. 13A is the wiring WCL[j], signals corresponding to the weight data are input to the wiring DW[1] to the wiring DW[K], whereby the current I₀[i,j] flows from the circuit WCS to the second terminal of the transistor F3[j]. That is, when the value of the K-bit signal input as the weight data is α[i,j](α[i,j] is an integer greater than or equal to 0 and less than or equal to 2^{K-1}), I₀[i,j] is equal to α[i,j]×I_{Wut}.

When α[i,j] is 0, I₀[i,j] is equal to 0; in a strict sense, a current does not flow from the circuit WCS to the cell array CA through the transistor F3[j], but in this specification and the like, it may be referred to as “the current with I₀[i,j]=0 flows” or the like.

In the period from Time T13 to Time T14, electrical continuity is established between the wiring WCL[j] and the first terminal of the transistor F1 included in the cell IM[i,j] in the i-th row of the cell array CA, and electrical continuity is not established between the wiring WCL[j] and the first terminals of the transistors F1 included in the cell IM[1,j] to the cell IM[m,j] in the rows other than the i-th row of the cell array CA; accordingly, a current with the current amount I₀[i,j] flows from the wiring WCL[j] to the cell IM[i,j].

When the transistor F1 included in the cell IM[i,j] is turned on, the transistor F2 included in the cell IM[i,j] has a diode-connected structure. Therefore, when a current flows from the wiring WCL[j] to the cell IM[i,j], the potentials of the gate of the transistor F2 and the second terminal of the transistor F2 are substantially equal to each other. The potentials are determined by the amount of current flowing from the wiring WCL[j] to the cell IM[i,j], the potential of the first terminal of the transistor F2 (here, GND), and the like. In this operation example, the current with the current amount I₀[i,j] flows from the wiring WCL[j] to the cell IM[i,j], whereby the potential of the gate of the transistor F2 (the node NN[i,j]) becomes V_{g}[i,j]. That is, the gate-source voltage of the transistor F2 is V_{g}[i,j]−GND, and the current with the amount I₀[i,j] is set as a current flowing between the first terminal and the second terminal of the transistor F2.

Here, when the threshold voltage of the transistor F2 is Vₜₕ[i,j], the current amount I₀[i,j] in the case where the transistor F2 operates in the subthreshold region can be expressed by the following Formula (1.1).

I₀[i,j]=I_{α}exp{J(V_{g}[i,j]−Vₜₕ[i,j])} [Formula 1](1.1)

Note that Iₐ is a drain current for the case where V_{g}[i,j] is Vₜₕ[i,j], and J is a correction coefficient determined by the temperature, the device structure, and the like.

In the period from Time T13 to Time T14, a current with the current amount I_{ref0} flows as the reference data from the circuit XCS to the wiring XCL[i]. Specifically, when the wiring XCL illustrated in FIG. 13C is the wiring XCL[i], a high-level potential is input to the wiring DX[1], a low-level potential is input to the wiring DX[2] to the wiring DX[K], and the current Iwo flows from the circuit XCS to the wiring XCL[i]. In other words, I_{ref0}=I_{Xut} is satisfied.

In the period from Time T13 to Time T14, since electrical continuity is established between the first terminal of the transistor F1m included in the cell IMref[i] and the wiring XCL[i], the current with the current amount Iwo flows from the wiring XCL[i] to the cell IMref[i].

As in the cell IM[i,j], when the transistor F1m included in the cell IMref[i] is turned on, the transistor F2m included in the cell IMref[i] has a diode-connected structure. Therefore, when a current flows from the wiring XCL[i] to the cell IMref[i], the potentials of the gate of the transistor F2m and the second terminal of the transistor F2m are substantially equal to each other. The potentials are determined by the amount of current flowing from the wiring XCL[i] to the cell IMref[i], the potential of the first terminal of the transistor F2m (here, GND), and the like. In this operation example, the current with the current amount I_{ref0} flows from the wiring XCL[i] to the cell IMref[i], whereby the potential of the gate of the transistor F2 (the node NNref[i]) becomes V_{gm}[i]; at this time, the potential of the wiring XCL[i] is also V_{gm}[i]. That is, the gate-source voltage of the transistor F2m is V_{gm}[i]−GND, and the current with the current amount I_{ref0} is set as a current flowing between the first terminal and the second terminal of the transistor F2m.

Here, when the threshold voltage of the transistor F2m is Vₜₕₘ[i], the current amount I_{ref0} in the case where the transistor F2m operates in the subthreshold region can be expressed by the following Formula (1.2). Note that the correction coefficient J is the same as that of the transistor F2 included in the cell IM[i,j]. For example, the same device structure and the same size (channel length and channel width) are used for the transistors. Furthermore, although variations in manufacturing cause variations in the correction coefficient J among the transistors, the variations are inhibited to the extent that the argument described later can be made with sufficient precision for practical purposes.

### [Formula 2]

I_{ref0}=I_{α}exp{J(V_{gm}[i]−Vₜₕₘ[i])} 1.2)

Here, a weight coefficient w[i,j] that is the weight data is defined as the following Formula (1.3).

w[i,j]=exp{J(V_{g}[i,j]−Vₜₕ[i,j]−V_{gm}[i]+Vₜₕₘ[i])} [Formula 3](1.3)

Therefore, Formula (1.1) can be rewritten to the following Formula (1.4).

I₀[i,j]=w[i,j]I_{ref0 →α[}i,j]I_{Wut}=w[i,j]I_{Xut} [Formula 4](1.4)

When the current I_{Wut} output from the current source CS of the circuit WCS in FIG. 13A and the current I_{Xut} output from the current source CS of the circuit XCS in FIG. 13C are equal, w[i,j] is equal to α[i,j]. That is, when I_{Wut} is equal to I_{Xut}, α[i,j] corresponds to the value of the weight data; thus, I_{Wut} and I_{Xut} are preferably equal to each other.

In the period from Time T14 to Time T15, a low-level potential is applied to the wiring WSL[i]. Accordingly, in the i-th row of the cell array CA, a low-level potential is applied to the gates of the transistors F1 included in the cell IM[i,1] to the cell IM[i,n] and the gate of the transistor F1m included in the cell IMref[i] so that the transistors F1 and the transistor F1m are turned off.

When the transistor F1 included in the cell IM[i,j] is turned off, V_{g}[i,j]−V_{gm}[i], which is a difference between the potential of the gate of the transistor F2 (the node NN[i,j]) and the potential of the wiring XCL[i], is retained in the capacitor C5. When the transistor F1 included in the cell IMref[i] is turned off, 0, which is a difference between the potential of the gate of the transistor F2m (the node NNref[i]) and the potential of the wiring XCL[i], is retained in the capacitor C5m. In the operation from Time T13 to Time T14, a voltage that is not 0 (e.g., V_{ds}) might be retained in the capacitor C5m depending on transistor characteristics of the transistor F1m, the transistor F2m, or the like. In this case, the potential of the node NNref[i] is regarded as a potential obtained by adding Vs to the potential of the wiring XCL[i].

In the period from Time T15 to Time T16, GND is applied to the wiring XCL[i]. Specifically, for example, when the wiring XCL illustrated in FIG. 13C is the wiring XCL[i], the initialization potential of the wiring VINIL2 is set to the ground potential GND, and the switch SWX is turned on, the potential of the wiring XCL[i] can be set to the ground potential GND.

Thus, the potentials of the node NN[i,1] to the node NN[i,n] change because of capacitive coupling of the capacitors C5 included in the cell IM[i,1] to the cell IM[i,n] in the i-th row, and the potential of the node NNref[i] changes because of capacitive coupling of the capacitor C5m included in the cell IMref[i].

The amount of change in the potentials of the node NN[i,1] to the node NN[i,n] is a potential obtained by multiplying the amount of change in the potential of the wiring XCL[i] by a capacitive coupling coefficient determined by the structures of the cell IM[i,1] to the cell IM[i,n] included in the cell array CA. The capacitive coupling coefficient is calculated using the capacitance of the capacitor C5, the gate capacitance of the transistor F2, the parasitic capacitance, and the like. When the capacitive coupling coefficient due to the capacitor C5 is p in each of the cell IM[i,1] to the cell IM[i,n], the potential of the node NN[i,j] in the cell IM[i,j] decreases by p(V_{gm}[i]−GND) from the potential of the period from Time T14 to Time T15.

Similarly, when the potential of the wiring XCL[i] changes, the potential of the node NNref[i] also changes because of capacitive coupling of the capacitor C5m included in the cell IMref[i]. In the case where the capacitive coupling coefficient due to the capacitor C5m is p as with the capacitor C5, the potential of the node NNref[i] in the cell IMref[i] decreases by p(V_{gm}[i]−GND) from the potential of the period from Time T14 to Time T15. In the timing chart in FIG. 17, p=1, for example. Thus, the potential of the node NNref[i] is GND in the period from Time T15 to Time T16.

Accordingly, the potential of the node NN[i,j] of the cell IM[i,j] decreases, so that the transistor F2 is turned off; similarly, the potential of the node NNref[i] of the cell IMref[i] decreases, so that the transistor F2m is also turned off. Therefore, I_{F2}[i,j] and I_{F2m}[i] are each 0 in the period from Time T15 to Time T16.

In the period from Time T16 to Time T17, a high-level potential is applied to the wiring WSL[i+1]. Accordingly, in the i+1-th row of the cell array CA, a high-level potential is applied to the gates of the transistors F1 included in the cell IM[i+1,1] to the cell IM[i+1,n] and the gate of the transistor F1m included in the cell IMref[i+1] so that the transistors F1 and the transistor F1m are turned on. Furthermore, in the period from Time T16 to Time T17, a low-level potential is applied to the wiring WSL[1] to the wiring WSL[m] except the wiring WSL[i+1], and in the cell array CA, the transistors F1 included in the cell IM[1,1] to the cell IM[m,n] in the rows other than the i+1-th row and the transistors F1m included in the cell IMref[1] to the cell IMref[m] in the rows other than the i+1-th row are in an off state.

The ground potential GND has been continuously applied to the wiring XCL[1] to the wiring XCL[m] since before Time T16.

In the period from Time T17 to Time T18, a current with a current amount I₀[i+1,j] flows as the weight data from the circuit WCS to the cell array CA through the transistor F3[j]. Specifically, when the wiring WCL illustrated in FIG. 13A is the wiring WCL[j+1], signals corresponding to the weight data are input to the wiring DW[1] to the wiring DW[K], whereby the current I₀[i+1,j] flows from the wiring WCS to the second terminal of the transistor F3[j]. That is, when the value of the K-bit signal input as the weight data is α[i+1,j](α[i+1,j] is an integer greater than or equal to 0 and less than or equal to 2^{K-1}), I₀[i+1,j] is equal to α[i+1,j]×I_{Wut}.

When α[i+1,j] is 0, I₀[i+1,j] is 0; in a strict sense, a current does not flow from the circuit WCS to the cell array CA through the transistor F3[j] but in this specification and the like, it may be referred to as “the current with I₀[i+1,j]=0 flows” or the like as in the case of I₀[i,j]=0.

At this time, electrical continuity is established between the wiring WCL[j] and the first terminal of the transistor F1 included in the cell IM[i+1,j] in the i+1-th row of the cell array CA, and electrical continuity is not established between the wiring WCL[j] and the first terminals of the transistors F1 included in the cell IM[1,j] to the cell IM[m,j] in the rows other than the i+1-th row of the cell array CA; accordingly, the current with the current amount I₀[i+1,j] flows from the wiring WCL[j] to the cell IM[i+1,j].

When the transistor F1 included in the cell IM[i+1,j] is turned on, the transistor F2 included in the cell IM[i+1,j] has a diode-connected structure. Therefore, when a current flows from the wiring WCL[j] to the cell IM[i+1,j], the potentials of the gate of the transistor F2 and the second terminal of the transistor F2 are substantially equal to each other. The potentials are determined by the amount of current flowing from the wiring WCL[j] to the cell IM[i+1,j], the potential of the first terminal of the transistor F2 (here, GND), and the like. In this operation example, the current with the current amount I₀[i+1,j] flows from the wiring WCL[j] to the cell IM[i+1,j], whereby the potential of the gate of the transistor F2 (the node NN[i+1,j]) becomes V_{g}[i+1,j]. That is, the gate-source voltage of the transistor F2 is V_{g}[i+1,j]−GND, and the current amount I₀[i+1,j] is set as a current flowing between the first terminal and the second terminal of the transistor F2.

Here, when the threshold voltage of the transistor F2 is Vₜₕ[i+1,j], the current amount I₀[i+1,j] in the case where the transistor F2 operates in the subthreshold region can be expressed by the following Formula (1.5). Note that the correction coefficient is J, which is the same as those of the transistor F2 included in the cell IM[i,j] and the transistor F2m included in the cell IMref[i].

I₀[i+1,j]=I_{α}exp{J(V_{g}[i+1,j]−Vₜₕ[i+1,j])} [Formula 5](1.5)

In the period from Time T17 to Time T18, the current with the current amount Iwo flows as the reference data from the circuit XCS to the wiring XCL[i+1]. Specifically, as in the period from Time T13 to Time T14, when the wiring XCL illustrated in FIG. 13C is the wiring XCL[i+1], a high-level potential is input to the wiring DX[1], a low-level potential is input to the wiring DX[2] to the wiring DX[K], and the current I_{ref0}=I_{Xut} flows from the circuit XCS to the wiring XCL[i+1].

In the period from Time T17 to Time T18, since electrical continuity is established between the first terminal of the transistor F1m included in the cell IMref[i+1] and the wiring XCL[i+1], the current with the current amount I_{ref0} flows from the wiring XCL[i+1] to the cell IMref[i+1].

As in the cell IM[i+1,j], when the transistor F1m included in the cell IMref[i+1] is turned on, the transistor F2m included in the cell IMref[i+1,j] has a diode-connected structure. Therefore, when a current flows from the wiring XCL[i+1] to the cell IMref[i+1], the potentials of the gate of the transistor F2m and the second terminal of the transistor F2m are substantially equal to each other. The potentials are determined by the amount of current flowing from the wiring XCL[i+1] to the cell IMref[i+1], the potential of the first terminal of the transistor F2m (here, GND), and the like. In this operation example, the current with the current amount Iwo flows from the wiring XCL[i+1] to the cell IMref[i+1], whereby the potential of the gate of the transistor F2 (the node NNref[i+1]) becomes V_{gm}[i+1]; at this time, the potential of the wiring XCL[i+1] is also V_{gm}[i+1]. That is, the gate-source voltage of the transistor F2m is V_{gm}[i+1]−GND, and the current amount I_{ref0} is set as a current flowing between the first terminal and the second terminal of the transistor F2m.

Here, when the threshold voltage of the transistor F2m is Vₜₕ[i+1,j], the current amount Iwo in the case where the transistor F2m operates in the subthreshold region can be expressed by the following Formula (1.6). Note that the correction coefficient J is the same as that of the transistor F2 included in the cell IM[i+1,j].

I_{ref0}=I_{α}exp{J(V_{gm}[i+1]−Vₜₕₘ[i+1])} [Formula 6](1.6)

Here, a weight coefficient w[i+1,j] that is the weight data is defined as follows.

w[i+1,j]=exp{J(V_{g}[i+1,j]−Vₜₕ[i+1,j]−V_{gm}[i+1]+Vₜₕₘ[i+1])} [Formula 7](1.7)

Therefore, Formula (1.5) can be rewritten to the following Formula (1.6).

I₀[i+1,j]=w[i+1,j]I_{ref0}→α[i+1,j]I_{Wut}=w[i+1,j]I_{Xut} [Formula 8](1.8)

When the current I_{Wut} output from the current source CS of the circuit WCS in FIG. 13A and the current I_{Xut} output from the current source CS of the circuit XCS in FIG. 13C are equal, w[i+1,j] is equal to α[i+1,j]. That is, when I_{Wut} is equal to I_{Xut}, α[i+1,j] corresponds to the value of the weight data; accordingly, I_{Wut} and I_{Xut} a are preferably equal to each other.

In the period from Time T18 to Time T19, a low-level potential is applied to the wiring WSL[i+1]. Accordingly, in the i+1-th row of the cell array CA, a low-level potential is applied to the gates of the transistors F1 included in the cell IM[i+1,1] to the cell IM[i+1,n] and the gate of the transistor F1m included in the cell IMref[i+1] so that the transistors F1 and the transistor F1m are turned off.

When the transistor F1 included in the cell IM[i+1,j] is turned off, V_{g}[i+1,j]−V_{gm}[i+1], which is a difference between the potential of the gate of the transistor F2 (the node NN[i+1,j]) and the potential of the wiring XCL[i+1], is retained in the capacitor C5. When the transistor F1 included in the cell IMref[i+1] is turned off, 0, which is a difference between the potential of the gate of the transistor F2m (the node NNref[i+1]) and the potential of the wiring XCL[i+1], is retained in the capacitor C5m. In the operation from Time T18 to Time T19, the voltage retained in the capacitor C5m might be a voltage that is not 0 (e.g., V_{ds}) depending on transistor characteristics of the transistor F1m, the transistor F2m, or the like. In this case, the potential of the node NNref[i+1] is regarded as a potential obtained by adding Vs to the potential of the wiring XCL[i+1].

In the period from Time T19 to Time T20, the ground potential GND is applied to the wiring XCL[i+1]. Specifically, for example, when the wiring XCL illustrated in FIG. 13C is the wiring XCL[i+1], the potential of the wiring XCL[i+1] can be set to the ground potential GND by setting the initialization potential of the wiring VINIL2 to the ground potential GND and turning on the switch SWX.

Thus, the potentials of the node NN[i,1] to the node NN[i+1,n] change because of capacitive coupling of the capacitors C5 included in the cell IM[i+1,1] to the cell IM[i+1,n] in the i+1-th row, and the potential of the node NNref[i+1] changes because of capacitive coupling of the capacitor C5m included in the cell IMref[i+1].

The amount of change in the potentials of the node NN[i+1,1] to the node NN[i+1,n] is a potential obtained by multiplying the amount of change in the potential of the wiring XCL[i+1] by a capacitive coupling coefficient determined by the structures of the cell IM[i+1,1] to the cell IM[i+1,n] included in the cell array CA. The capacitive coupling coefficient is calculated using the capacitance of the capacitor C5, the gate capacitance of the transistor F2, the parasitic capacitance, and the like. In the case where the capacitive coupling coefficient due to the capacitor C5 in each of the cell IM[i+1,1] to the cell IM[i+1,n] is p, which is the same as the capacitive coupling coefficient due to the capacitor C5 in each of the cell IM[i,1] to the cell IM[i,n], the potential of the node NN[i+1,j] in the cell IM[i+1,j] decreases by p(V_{gm}[i+1]−GND) from the potential of the period from Time T18 to Time T19.

Similarly, when the potential of the wiring XCL[i+1] changes, the potential of the node NNref[i+1] also changes because of capacitive coupling of the capacitor C5m included in the cell IMref[i+1]. The potential of the node NNref[i+1] of the cell IMref[i+1] in the case where the capacitive coupling coefficient due to the capacitor C5m is p like that due to the capacitor C5 decreases from the potential in the period from Time T18 to Time T19 by p(V_{gm}[i+1]−GND). In the timing chart in FIG. 17, p=1, for example. Thus, the potential of the node NNref[i+1] is GND in the period from Time T20 to Time T21.

Accordingly, the potential of the node NN[i+1,j] of the cell IM[i+1,j] decreases, so that the transistor F2 is turned off; similarly, the potential of the node NNref[i+1] of the cell IMref[i+1] decreases, so that the transistor F2m is also turned off. Therefore, I_{F2}[i+1,j] and I_{F2m}[i+1] are each 0 in the period from Time T19 to Time T20.

In the period from Time T20 to Time T21, a low-level potential is applied to the wiring SWL1. Accordingly, a low-level potential is applied to each of the gates of the transistor F3[1] to the transistor F3[n], whereby the transistor F3[1] to the transistor F3[n] are turned off.

In the period from Time T21 to Time T22, a high-level potential is applied to the wiring SWL2. Accordingly, a high-level potential is applied to each of the gates of the transistor F4[1] to the transistor F4[n], whereby the transistor F4[1] to the transistor F4[n] are turned on.

In the period from Time T22 to Time T23, a current x[i]I_{ref0}, which is x[i] times as high as the current with the amount I_{ref0}, flows as the input data from the circuit XCS to the wiring XCL[i]. Specifically, for example, when the wiring XCL illustrated in FIG. 13C is the wiring XCL[i], a high-level potential or a low-level potential is input to the wiring DX[1] to the wiring DX[K] in accordance with the value of x[i], and the current with the amount x[i]I_{ref0}=x[i]I_{Xut} flows from the circuit XCS to the wiring XCL[i]. In this operation example, x[i] corresponds to the value of the input data. At this time, the potential of the wiring XCL[i] changes from 0 to V_{gm}[i]+ΔV[i].

When the potential of the wiring XCL[i] changes, the potentials of the node NN[i,1] to the node NN[i,n] also change because of the capacitive coupling of the capacitors C5 included in the cell IM[i,1] to the cell IM[i,n] in the i-th row of the cell array CA. Thus, the potential of the node NN[i,j] in the cell IM[i,j] becomes V_{g}[i,j]+pΔV[i].

Similarly, when the potential of the wiring XCL[i] changes, the potential of the node NNref[i] also changes because of capacitive coupling of the capacitor C5m included in the cell IMref[i]. Thus, the potential of the node NNref[i] in the cell IMref[i] becomes V_{gm}[i]+pΔV[i].

Accordingly, the current amount I₁[i,j] of a current flowing between the first terminal and the second terminal of the transistor F2 and the current amount I_{ref1}[i,j] of a current flowing between the first terminal and the second terminal of the transistor F2m in the period from Time T22 to Time T23 can be expressed as follows.

$$\begin{matrix}[ Formula 9 ] & \\ \begin{matrix}{I}_{1} [ i , j ] = {I}_{a} exp \{ J ( {V}_{g} [ i , j ] + p Δ V [ i ] - {V}_{t h} [ i , j ] ) \} \\ = {I}_{0} [ i , j ] exp ( Jp Δ V [ i ] )\end{matrix} & ( 1.9 )\end{matrix}$$

$$\begin{matrix}[ Formula 10 ] & \\ \begin{matrix}{I}_{ref 1} [ i ] = {I}_{a} exp \{ J ( {V}_{g m} [ i ] + p Δ V [ i ] — {V}_{t h m} [ i ] ) \} \\ = x [ i ] {I}_{ref 0}\end{matrix} & ( 1.1 )\end{matrix}$$

According to Formula (1.9) and Formula (1.10), x[i] can be expressed by the following Formula (1.11).

x[i]=exp(JpΔV[i]) [Formula 11](1.11)

Therefore, Formula (1.9) can be rewritten to the following Formula (1.12).

I₁[i,j]=x[i]w[i,j]I_{ref0} [Formula 12](1.12)

That is, the amount of current flowing between the first terminal and the second terminal of the transistor F2 included in the cell IM[i,j] is proportional to the product of the weight coefficient w[i,j] that is the weight data and input data x[i].

In the period from Time T22 to Time T23, a current x[i+1]I_{ref0}, which is x[i+1] times as high as the current with the amount I_{ref0}, flows as the input data from the circuit XCS to the wiring XCL[i+1]. Specifically, for example, when the wiring XCL illustrated in FIG. 13C is the wiring XCL[i+1], a high-level potential or a low-level potential is input to the wiring DX[1] to the wiring DX[K] in accordance with the value of x[i+1], and the current amount x[i+1]I_{ref0}=x[i+1]I_{Xut} flows from the circuit XCS to the wiring XCL[i+1]. In this operation example, x[i+1] corresponds to the value of the input data. At this time, the potential of the wiring XCL[i+1] changes from 0 to V_{gm}[i+1]+ΔV[i+1].

When the potential of the wiring XCL[i+1] changes, the potentials of the node NN[i+1,1] to the node NN[i+1,n] also change because of the capacitive coupling of the capacitors C5 included in the cell IM[i+1,1] to the cell IM[i+1,n] in the i+1-th row of the cell array CA. Thus, the potential of the node NN[i+1,j] in the cell IM[i+1,j] becomes V_{g}[i+1,j]+pΔV[i+1].

Similarly, when the potential of the wiring XCL[i+1] changes, the potential of the node NNref[i+1] also changes because of capacitive coupling of the capacitor C5m included in the cell IMref[i+1]. Thus, the potential of the node NNref[i+1] in the cell IMref[i+1] becomes V_{gm}[i+1]+pΔV[i+1].

Accordingly, a current with the amount I₁[i+1,j] flowing between the first terminal and the second terminal of the transistor F2 and a current with the amount I_{ref1}[i+1,j] flowing between the first terminal and the second terminal of the transistor F2m in the period from Time T22 to Time T23 can be expressed as follows.

$$\begin{matrix}[ Formula 13 ] & \\ \begin{matrix}{I}_{1} [ i + 1 , j ] = {I}_{a} exp \{ J ( {V}_{g} [ i + 1 , j ] + p Δ V [ i + 1 ] - {V}_{t h} [ i + 1 , j ] ) \} \\ = {I}_{0} [ i + 1 , j ] exp ( Jp Δ V [ i + 1 ] )\end{matrix} & ( 1.13 )\end{matrix}$$

$$\begin{matrix}[ Formula 14 ] & \\ \begin{matrix}{I}_{ref 1} [ i + 1 ] = {I}_{a} exp \{ J ( {V}_{g m} [ i + 1 ] + p Δ V [ i + 1 ] - {V}_{t h m} [ i + 1 ] ) \} \\ = x [ i + 1 ] {I}_{ref 0}\end{matrix} & ( 1.14 )\end{matrix}$$

According to Formula (1.13) and Formula (1.14), x[i+1] can be expressed by the following Formula (1.15).

x[i+1]=exp(JpΔV[i+1]) [Formula 15](1.15)

Therefore, Formula (1.13) can be rewritten to the following Formula (1.16).

I₁[i+1,j]=x[i+1]w[i+1,]I_{ref0} [Formula 16](1.16)

That is, the amount of current flowing between the first terminal and the second terminal of the transistor F2 included in the cell IM[i+1,j] is proportional to the product of the weight data w[i+1,j] and the input data x[i+1].

Here, the sum of the amounts of current flowing from the circuit ITRZ[i] to the cell IM[i,j] and the cell IM[i+1,j] through the transistor F4[j] and the wiring WCL[j] is considered. According to Formula (1.12) and Formula (1.16), when the sum of the amounts of current is Iₛ[j], Iₛ[j] can be expressed by the following Formula (1.17).

### [Formula 17]

$$\begin{matrix}[ Formula 17 ] & \\ \begin{matrix}{I}_{S} [ j ] = {I}_{1} [ i , j ] + {I}_{1} [ i + 1 , j ] \\ = {I}_{ref 0} ( x [ i ] w [ i , j ] + x [ i + 1 ] w [ i + 1 , j ] )\end{matrix} & ( 1.17 )\end{matrix}$$

Thus, the amount of current output from the circuit ITRZ[j] is the amount of current proportional to the sum of products of the weight coefficients w[i,j] and w[i+1,j] that are the weight data and the input data x[i] and x[i+1].

Although the sum of the amounts of current flowing to the cell IM[i,j] and the cell IM[i+1j] is described in the above-described operation example, the sum of the amounts of current flowing to a plurality of cells, the cell IM[1,j] to the cell IM[m,j], may be described. In this case, Formula (1.17) can be rewritten to the following Formula (1.18).

$$\begin{matrix}[ Formula 18 ] & \\ {I}_{S} [ j ] = {I}_{ref 0} {\sum }_{i = 1}^{m} x [ i ] w [ i , j ] & ( 1.18 )\end{matrix}$$

Thus, even in the case of the semiconductor device MAC1 including the cell array CA with three or more rows and two or more columns, a product-sum operation can be performed in the above-described manner. In the semiconductor device MAC1 of such a case, cells in one of the plurality of columns are used for retaining I_{ref0} and xI_{ref0} as the amount of current, whereby product-sum operations, the number of which corresponds to the number of rest of the columns among the plurality of columns, can be performed concurrently. That is, when the number of columns in a cell array increases, a semiconductor device that achieves high-speed product-sum operation can be provided.

The above operation example of the semiconductor device MAC1 is suitable when a product-sum operation of the positive weight data and the positive input data is performed.

Although this embodiment describes the case where the transistors included in the semiconductor device MAC1 are OS transistors or Si transistors, one embodiment of the present invention is not limited thereto. The transistor included in the semiconductor device MAC1 can be, for example, a transistor including Ge or the like in a channel formation region, a transistor including a compound semiconductor such as gallium nitride in a channel formation region, a transistor including a carbon nanotube in a channel formation region, or a transistor including an organic semiconductor in a channel formation region.

Note that this embodiment can be combined with any of the other embodiments described in this specification as appropriate.

### Embodiment 4

In this embodiment, a display device provided with the above-described semiconductor device will be described. The display device can be a display device capable of performing an arithmetic operation with excellent arithmetic efficiency by providing a semiconductor device that can perform an arithmetic operation of an artificial neural network. In this embodiment, a schematic top view of a light-emitting element and its cross-sectional schematic view, a structure example of a light-emitting element, a structure example of a light-emitting element and a light-receiving element, and a structure example of a schematic view of a display device are described.

### Structure Example of Display Device

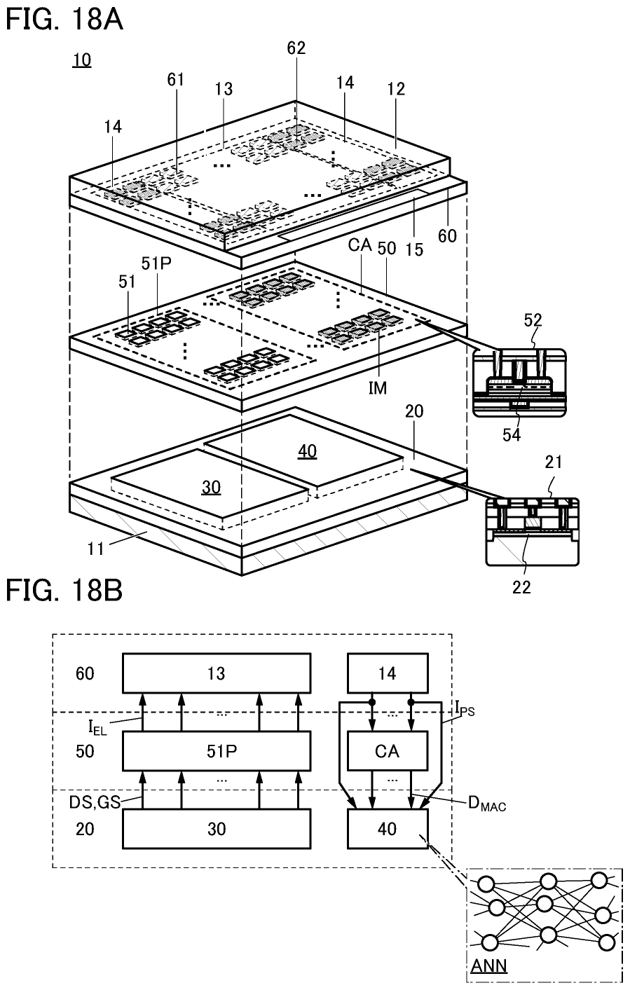

FIG. 18A is a diagram illustrating a perspective view of a display device 10. The display device 10 illustrated in FIG. 18A schematically illustrates a structure of a layer 20, a layer 50, and a layer 60 which are provided between a substrate 11 and a substrate 12. In FIG. 18A, a display portion 13, a light-receiving portion 14, and an input/output terminal 15 are illustrated in the layer 60.

The layer 20 is provided over the substrate 11. In the layer 20, a driver circuit 30 and an arithmetic circuit 40 are provided, for example. The layer 20 includes a transistor 21 containing silicon (also referred to as a Si transistor) in a channel formation region 22. The substrate 11 is a silicon substrate, for example. A silicon substrate is preferable because of having higher thermal conductivity than a glass substrate.

The transistor 21 can be a transistor containing single crystal silicon in a channel formation region, for example. In particular, the use of a transistor containing single crystal silicon in a channel formation region as the transistor provided in the layer 20 can increase the on-state current of the transistor. This is preferable because circuits included in the layer 20 can be driven at high speed. Furthermore, a transistor containing single crystal silicon in a channel formation region can be formed by microfabrication to have a channel length of 3 nm to 10 nm, for example; thus, an accelerator such as CPU or GPU, an application processor, or the like can be provided as well as the arithmetic circuit 40 dedicated to, for example, an artificial neural network (hereinafter referred to as a neural network in some cases) and/or the driver circuit 30. As the arithmetic circuit 40, the above-described semiconductor device described in Embodiments 1 to 3 can be used.

The driver circuit 30 includes a gate driver circuit, a source driver circuit, or the like, for example. The gate driver circuit, the source driver circuit, or the like can be placed to overlap with the display portion 13 and/or the light-receiving portion 14. Therefore, compared with the case where the driver circuit 30 and the display portion 13 are arranged side by side, the width of a non-display region (also referred to as a bezel) in the outer periphery of the display portion 13 of the display device 10 can be significantly reduced, enabling the display device 10 to have a small size. In the case where the driver circuit 30 is placed in the outer periphery of the display portion 13 of the display device 10, the gate driver circuit and the source driver circuit are placed collectively in the outer periphery of the display portion 13. In contrast, the driver circuit 30 can be divided into a plurality of parts and they can be placed in a region overlapping with the display portion 13.

The arithmetic circuit 40 includes the above-described semiconductor device described in Embodiments 1 to 3. Thus, product-sum operation processing in an artificial neural network can be performed, and for example, inference processing based on a hierarchical neural network such as a deep neural network (DNN) or a convolutional neural network (CNN) can be performed. The arithmetic circuit 40 can perform a product-sum operation using an ultralow current according to an analog voltage; thus, it can perform arithmetic processing using ultralow currents flowing through light-receiving elements 62 as input data. Therefore, use of the arithmetic circuit 40 is effective in a reduction in the circuit area, low power consumption, an improvement of arithmetic efficiency, and the like. The light-receiving element 62 is an element that converts a light signal into an electric signal and is also referred to as a photoelectric conversion element.

The layer 50 is provided over the layer 20. The layer 50 includes a pixel circuit portion 51P including a plurality of pixel circuits 51 and the cell array CA including the plurality of cells IM. The layer 50 includes a transistor 52 (also referred to as an OS transistor) including a metal oxide (also referred to as an oxide semiconductor) in a channel formation region 54. Note that the layer 50 can be stacked over the layer 20. The layer 50 may be formed over another substrate and bonded to the layer 20.

It is preferable to use, as the transistor 52, which is an OS transistor, a transistor including an oxide containing at least one of indium, an element M (the element M is aluminum, gallium, yttrium, or tin), and zinc in a channel formation region. Such an OS transistor has a characteristic of an extremely low off-state current. Thus, it is particularly preferable to use the OS transistor as a transistor provided in the pixel circuit 51 and the cell IM, in which case analog data written to the pixel circuit 51 and the cell IM can be retained for a long period.

The layer 60 is provided over the layer 50. Over the layer 60, the substrate 12 is provided. The substrate 12 is preferably a substrate having a light-transmitting property or a layer formed with a material having a light-transmitting property. The layer 60 includes the display portion 13 provided with a plurality of light-emitting elements 61 and the light-receiving portion 14 provided with the plurality of light-receiving elements 62. The layer 60 can be stacked over the layer 50. As the light-emitting element 61, an organic electroluminescent element (also referred to as an organic EL element) or the like can be used, for example. Note that the light-emitting element 61 is not limited thereto; an inorganic EL element formed with an inorganic material may be used, for example. Note that an “organic EL element” and an “inorganic EL element” are collectively referred to as “EL element” in some cases. The light-emitting element 61 may contain an inorganic compound such as quantum dots. For example, when used for the light-emitting layer, the quantum dots can function as a light-emitting material. Some of steps for forming the light-receiving element 62 can be the same as steps for forming an organic electroluminescent element when an organic photodiode or the like is used for the light-receiving element 62, for example.

As illustrated in FIG. 18A, the display device 10 of one embodiment of the present invention can have a structure in which the light-emitting element 61, the pixel circuit 51, and the driver circuit 30 are stacked, whereby the pixel circuit 51 can be arranged with extremely high density and thus the resolution of a pixel can be extremely high. Such a display device 10 has extremely high resolution, and thus can be suitably used for a device for VR such as a head-mounted display or a glasses-type device for AR. For example, even in the case of a structure in which the display portion of the display device 10 is seen through an optical member such as a lens, pixels of the extremely-high-resolution display portion included in the display device 10 are not seen when the display portion is enlarged by the lens, so that display providing a high sense of immersion can be performed.

Furthermore, the display device 10 of one embodiment of the present invention can have a structure in which the light-receiving element 62, the cell array CA, and the arithmetic circuit 40 are stacked as illustrated in FIG. 18A; thus, arithmetic processing excellent in the arithmetic efficiency can be performed using ultralow currents output from the light-receiving elements 62 as input data. In the display device 10, the light-receiving portion 14 can be placed close to the display portion 13; therefore, an image can be viewed by the user's eyes and an image of the user's eyes and/or their surroundings can be captured. Analog data written according to ultralow currents can be retained for along time in the cells IM of the cell array CA. The arithmetic circuit that performs product-sum operation processing using ultralow currents can perform an arithmetic operation with excellent arithmetic efficiency.

FIG. 18B is a block diagram illustrating components included in each of the layer 20, the layer 50, and the layer 60 in FIG. 18A. The driver circuit 30 in the layer 20 outputs signals GS and DS for controlling the pixel circuit portion 51P in the layer 50 (for example, GS is a signal for driving a gate line, and DS is a signal according to image data). The pixel circuit portion 51P in the layer 50 outputs a current I_{EL} according to image data to the light-emitting elements 61 (not illustrated) provided in the display portion 13 in the layer 60. The light-emitting elements 61 (not illustrated) in the display portion 13 in the layer 60 can emit light in accordance with the current I_{EL}, so that the user can view an image.

In the block diagram illustrated in FIG. 18B, the light-receiving element 62 (not illustrated) provided in the light-receiving portion 14 in the layer 60 outputs a current I_{PS} that flows when an image around the display device 10 is captured. The current I_{PS} is output to the cell array CA in the layer 50 and the arithmetic circuit 40 in the layer 20. The cell array CA in the layer 50 outputs signals D_{MAC} according to a product-sum operation to the arithmetic circuit 40 in the layer 20, in accordance with the currents I_{PS} from the light-receiving portions 14 in the layer 60 and a control signal for the arithmetic circuit 40 in the layer 20. The arithmetic circuit 40 in the layer 20 can perform inference processing based on a neural network ANN.

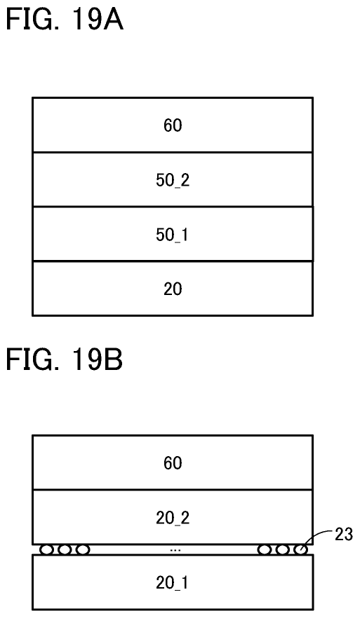

The layer 50 provided over the layer 20 can have a structure of two or more layers. For example, the layer 50 can be composed of layers 501 and 50_2 including the transistors, which are OS transistors, as illustrated in FIG. 19A. The layer 20 can have a structure formed of two or more layers with a bonding step or the like. As illustrated in FIG. 19B, layers 20_1 and 20_2 including Si transistors can be used instead of the layer 50 and the layer 20 as illustrated in FIG. 19B. The layers 20_1 and 20_2 including Si transistors can be bonded together by connecting electrodes (not illustrated) provided with a TSV (Through Silicon Via) with a micro-bump 23 or the like.

### Three-Dimensional Structure of Sensor and Semiconductor Device

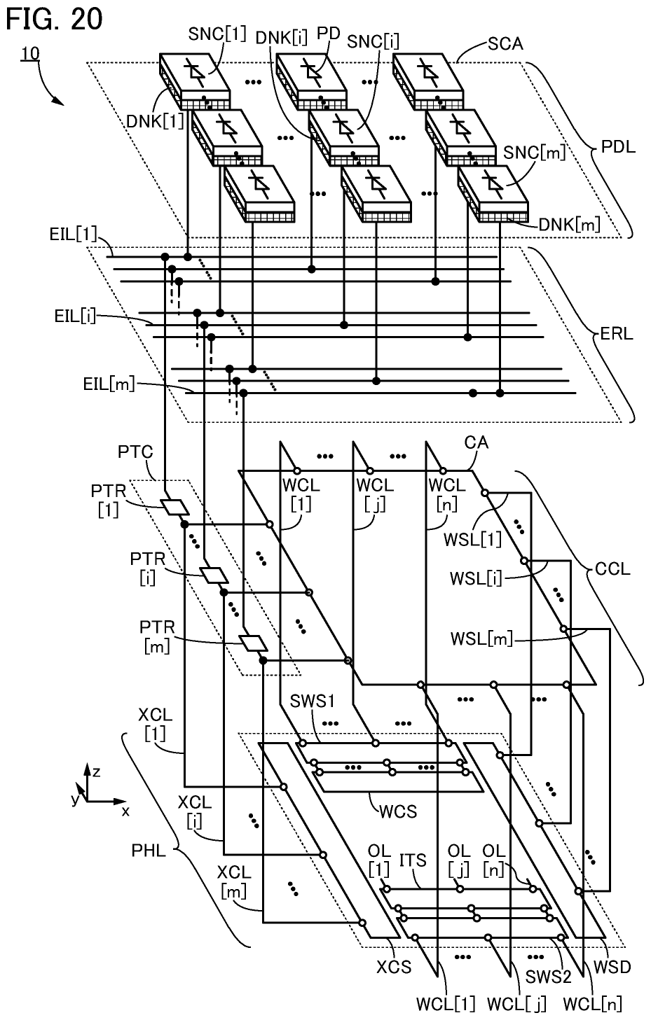

Next, a three-dimensional structure of the case where the semiconductor device that can perform an arithmetic operation using an output of a sensor such as a light-receiving element provided in part of the display device is provided in the display device 10 will be described. The display device 10 illustrated in FIG. 20 includes a layer PDL, a layer ERL, a layer CCL, and a layer PHL. The layer CCL and the layer PHL each have the above-described structure in the semiconductor device MAC1 or the semiconductor device MAC1A. A circuit PTC provided in the layer CCL includes a circuit PTR[1] to a circuit PTR[m].

The circuit PTR[1] has a function of establishing or breaking electrical continuity between a wiring EIL[1] and the wiring XCL[1]. Similarly, the circuit PTR[i] has a function of establishing or breaking electrical continuity between a wiring EIL[i] and the wiring XCL[i], and the circuit PTR[m] has a function of establishing or breaking electrical continuity between a wiring EIL[m] and the wiring XCL[m]. That is, the circuit PTR[1] to the circuit PTR[m] each function as a switching element.

Note that the display device 10 illustrated in FIG. 20 has a three-dimensional structure; thus, the x direction, the y direction, and the z direction are shown by arrows in FIG. 20. Here, the x direction, the y direction, and the z direction are shown as directions orthogonal to each other. In this specification and the like, one of the x direction, the y direction, and the z direction is referred to as a “first direction” in some cases. Another one of the directions is referred to as a “second direction” in some cases. The remaining one of the directions is referred to as a “third direction” in some cases.

The layer CCL is positioned above the layer PHL, the layer ERL is positioned above the layer CCL, and the layer PDL is positioned above the layer ERL. In other words, the layer PHL, the layer CCL, the layer ERL, and the layer PDL are sequentially stacked in the z direction.

The layer PDL includes a sensor array SCA, for example. The sensor array SCA includes a plurality of electrodes and a plurality of sensors; FIG. 20 illustrates an electrode DNK[1] to an electrode DNK[m] (here, m is an integer greater than or equal to 1) as the plurality of electrodes and a sensor SNC[1] to a sensor SNC[m] as the plurality of sensors. In the layer PDL, m electrodes DNK are arranged in a matrix, and the sensor SNC[1] to the sensor SNC[m] are provided over the electrode DNK[1] to the electrode DNK[m], respectively.

In the layer PDL illustrated in FIG. 20, the reference numerals of the electrode DNK[1], the electrode DNK[i] (here, i is an integer greater than or equal to 1 and less than or equal to m), and the electrode DNK[m] among the electrode DNK[1] to the electrode DNK[m] are selectively illustrated. In the layer PDL illustrated in FIG. 20, the reference numerals of the sensor SNC[1], the sensor SNC[i], and the sensor SNC[m] among the sensor SNC[1] to the sensor SNC[m] are selectively illustrated.

The sensor SNC[1] to the sensor SNC[m] each have a function of converting sensed information into a current amount and outputting the current amount. The electrode DNK[1] to the electrode DNK[m] each function as a terminal for outputting the current amount in the sensor SNC[1] to the sensor SNC[m]. As the sensors SNC, light-receiving elements can be used, for example. With the use of light-receiving elements as the sensor SNC[1] to the sensor SNC[m], the layer PDL can be part of an image sensor. In that case, it is preferable that the range of the intensity of light that can be sensed by the light-receiving elements include the intensity of light emitted in an environment where the light-receiving elements are used. FIG. 20 illustrates the display device 10 in which the sensors SNC each including a photodiode PD are used as light-receiving elements. As the photodiode PD, an organic light-emitting diode that can be provided in the same layer as a light-emitting element is preferably used.

As the circuit structure of the sensor SNC[i], a structure may be used in which one of an input terminal and an output terminal of the photodiode PD included in the sensor SNC[i] is electrically connected to the wiring EIL[i] through the electrode DNK[i]. As the circuit structure of the sensor SNC[i], a structure may be used in which a switch or the like for shutting off the supply of power to temporarily halt the sensor SNC[i] is provided. A light-emitting element (not illustrated) for performing display can be provided in the same layer as the sensor SNC[i].

The layer ERL includes the wiring EIL[1] to the wiring EIL[m]. Note that in the layer ERL illustrated in FIG. 20, the reference numerals of the wiring EIL[1], the wiring EIL[i], and the wiring EIL[m] among the wiring EIL[1] to the wiring EIL[m] are selectively illustrated.

The wiring EIL[1] is electrically connected to the electrode DNK[1] in the layer PDL. The wiring EIL[i] is electrically connected to the electrode DNK[i] in the layer PDL. The wiring EIL[m] is electrically connected to the electrode DNK[m] in the layer PDL.

Specifically, for example, plugs (referred to as contact holes or the like in some cases) or the like are provided at portions where the electrode DNK[1] to the electrode DNK[m] intersect with the wiring EIL[1] to the wiring EIL[m], respectively, in a top view of the display device 10 (when seen in the direction opposite to the arrows of the z axis illustrated in FIG. 20), and the electrode DNK[1] to the electrode DNK[m] are electrically connected to the wiring EIL[1] to the wiring EIL[m], respectively.

Thus, when information is sensed in the sensor SNC[1] to the sensor SNC[m], the wiring EIL[1] to the wiring EIL[m] function as paths through which currents flow in accordance with the information that has been output from the sensor SNC[1] to the sensor SNC[m].

The layer PDL preferably has a structure in which the sensor SNC[1] to the sensor SNC[m] perform sequential sensing and sequentially supply currents to the wiring EIL[1] to the wiring EIL[m]. In this case, for example, signal lines for selecting the sensor SNC[1] to the sensor SNC[m] are provided in the layer PDL to sequentially transmit signals or the like to the signal lines so that the sensor SNC[1] to the sensor SNC[m] sequentially operate.

In the case where the sensor SNC[1] to the sensor SNC[m] are each a light-receiving element including a photodiode or the like, the layer PDL in the display device 10 can have a structure in which an output terminal (cathode) of the photodiode is electrically connected to the electrode DNK, for example. For another structure example of the layer PDL in the display device 10, an input terminal (anode) of the photodiode may be electrically connected to the electrode DNK.

For example, in the case where the sensor SNC[1] to the sensor SNC[m] are each a light-receiving element including a photodiode or the like, a filter is provided such that only one of the sensor SNC[1] to the sensor SNC[m] is irradiated with light, whereby the sensor SNC[1] to the sensor SNC[m] can sequentially operate. Since the number of sensors SNC is m, the number of kinds of filters that allow only one of the sensors SNC to be irradiated with light ism. In addition, in the case where a filter that allows none of the sensor SNC[1] to the sensor SNC[m] to be irradiated with light is prepared, the number of kinds of filters is m+1. The filters are sequentially changed while the layer PDL is being irradiated with light, whereby the sensor SNC[1] to the sensor SNC[m] can perform sequential sensing.

In the case where the sensor SNC[1] to the sensor SNC[m] are each a light-receiving element including a photodiode or the like, the display device 10 may have a structure in which the sensor SNC[1] to the sensor SNC[m] are irradiated with light individually, for example. With the structure in which the sensor SNC[1] to the sensor SNC[m] are irradiated with light independently of each other, the sensor SNC[1] to the sensor SNC[m] can be sequentially irradiated with light to perform sequential sensing.

The layer CCL includes the circuit PTC and the cell array CA, for example. The layer PHL includes, for example, the circuit XCS, the circuit WCS, the circuit WSD, a circuit ITS, the circuit SWS1, and the circuit SWS2. As illustrated in FIG. 20, the cell array CA can have a structure positioned above the circuit XCS, the circuit WCS, the circuit WSD, the circuit ITS, the circuit SWS1, and the circuit SWS2, which correspond to peripheral circuits of the cell array CA.

The cell array CA includes a plurality of cells. The plurality of cells included in the cell array CA each have a function of retaining the weight data for performing a product-sum operation and a function of performing multiplication of the weight data and the input data.

The cell array CA is electrically connected to a plurality of wirings. Specifically, for example, FIG. 20 illustrates a structure in which the cell array CA is electrically connected to the wiring WCL[1] to the wiring WCL[n] (here, n is an integer greater than or equal to 1), the wiring WSL[1] to the wiring WSL[m], and the wiring XCL[1] to the wiring XCL[m]. In particular, the wiring WCL[1] to the wiring WCL[n] are wirings electrically connecting the circuit SWS1 and the circuit SWS2. That is, the circuit SWS1 is electrically connected to the circuit SWS2 through the cell array CA by the wiring WCL[1] to the wiring WCL[n]. Note that in FIG. 20, the wiring WSL[1] to the wiring WSL[m], the wiring XCL[1] to the wiring XCL[m], and the wiring WCL[1] to the wiring WCL[n] extend in the z direction.

One of the plurality of cells of the cell array CA is electrically connected to any one of the wiring WCL[1] to the wiring WCL[n], any one of the wiring WSL[1] to the wiring WSL[m], and any one of the wiring XCL[1] to the wiring XCL[m]. Thus, the plurality of cells included in the cell array CA are arranged in a matrix of at least m rows and n columns.

The circuit WCS has a function of supplying, to the wiring WCL[1] to the wiring WCL[n], a current in an amount corresponding to the weight data. Thus, the circuit WCS is electrically connected to the wiring WCL[1] to the wiring WCL[n] through the circuit SWS1.

The circuit SWS1 has a function of establishing or breaking electrical continuity between the circuit WCS and each of the wiring WCL[1] to the wiring WCL[n].

The circuit WSD is electrically connected to the wiring WSL[1] to the wiring WSL[m]. The circuit WSD has a function of selecting a row of the cell array CA to which the weight data is written, by supplying a predetermined signal to the wiring WSL[1] to the wiring WSL[m] at the time of writing the weight data to the cell included in the cell array CA. That is, the wiring WSL[1] to the wiring WSL[m] function as write word lines.

The circuit XCS is electrically connected to the wiring XCL[1] to the wiring XCL[m]. The circuit XCS has a function of supplying a current in an amount corresponding to reference data to be described later or a current in an amount corresponding to the input data to the wiring XCL[1] to the wiring XCL[m].

The circuit PTC includes the circuit PTR[1] to the circuit PTR[m]. A first terminal of the circuit PTR[1] is electrically connected to the wiring XCL[1], a first terminal of the circuit PTR[i] is electrically connected to the wiring XCL[i], and a first terminal of the circuit PTR[m] is electrically connected to the wiring XCL[m].

A second terminal of the circuit PTR[1] is electrically connected to the wiring EIL[1] in the layer ERL, a second terminal of the circuit PTR[i] is electrically connected to the wiring EIL[i] in the layer ERL, and a second terminal of the circuit PTR[m] is electrically connected to the wiring EIL[m] in the layer ERL.

Specifically, for example, plugs or the like are provided at portions where the second terminals of the circuit PTR[1] to the circuit PTR[m] intersect with the wiring EIL[1] to the wiring EIL[m], respectively, in a top view of the display device 10, and the second terminals of the circuit PTR[1] to the circuit PTR[m] are electrically connected to the wiring EIL[1] to the wiring EIL[m], respectively.

The circuit PTR[1] has a function of establishing or breaking electrical continuity between the wiring EIL[1] and the wiring XCL[1]. Similarly, the circuit PTR[i] has a function of establishing or breaking electrical continuity between the wiring EIL[i] and the wiring XCL[i], and the circuit PTR[m] has a function of establishing or breaking electrical continuity between the wiring EIL[m] and the wiring XCL[m]. That is, the circuit PTR[1] to the circuit PTR[m] each function as a switching element.

The circuit ITS has functions of acquiring the amount of current flowing through the wiring WCL[1] to the wiring WCL[n] and outputting the result depending on the amount of current to the wiring OL[1] to the wiring OL[n]. Thus, the circuit ITS is electrically connected to the wiring WCL[1] to the wiring WCL[n] through the circuit SWS2. The circuit ITS is electrically connected to the wiring OL[1] to the wiring OL[n].

The circuit SWS2 has a function of establishing or breaking electrical continuity between the circuit ITS and each of the wiring WCL[1] to the wiring WCL[n].

In the layer ERL in FIG. 20, the wiring EIL[1] to the wiring EIL[m] preferably extend along the x direction, for example. That is, for example, the direction in which the wiring EIL[1] to the wiring EIL[m] extend is preferably substantially parallel to, further preferably, parallel to the wiring XCL[1] to the wiring XCL[m] when seen in the y direction. For example, the wiring EIL[1] to the wiring EIL[m] are preferably substantially parallel to, further preferably, parallel to the wiring XCL[1] to the wiring XCL[m] included in the layer CCL when seen from above.

As described above, the use of the display device 10 illustrated in FIG. 20 allows substantially free determination of the placement position of the sensor array SCA on a display device including the arithmetic circuit (the layer CCL). Thus, the sensor array SCA can be placed in the center of or the vicinity of the center of the display device in the top view, for example. The layout of the arithmetic circuit included in the layer CCL does not depend on the placement position of the sensor array SCA; thus, flexibility in the layout of the arithmetic circuit and the peripheral wirings and the like can be increased.

### Three-Dimensional Structure of Driver Circuit, Pixel Circuit, and Light-Emitting Element

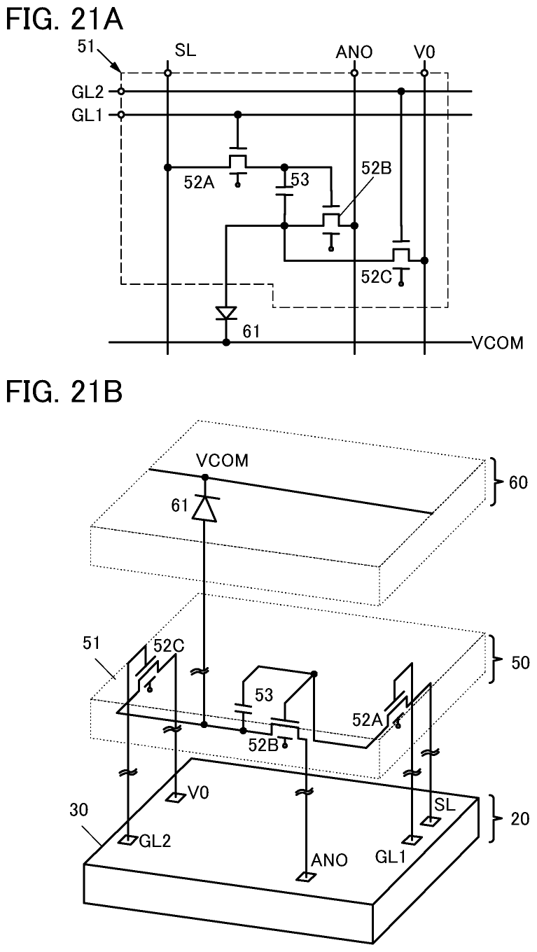

FIG. 21A and FIG. 21B each illustrate a structure example of the pixel circuit 51 and the light-emitting element 61 connected to the pixel circuit 51 which are illustrated in FIG. 18A. FIG. 21A illustrates the connection of the elements, and FIG. 21B schematically illustrates the vertical position relation of the layer 20 including the driver circuit 30, the layer 50 including a plurality of transistors of the pixel circuit 51, and the layer 60 including the light-emitting element 61.

The pixel circuit 51 illustrated as an example in FIG. 21A and FIG. 21B includes a transistor 52A, a transistor 52B, a transistor 52C, and a capacitor 53. Note that the number of transistors included in the pixel circuit 51, the number of capacitors, and electrical connection between elements are not limited to those shown in the structure illustrated in FIG. 21A and FIG. 21B, and another structure may be employed. The transistor 52A, the transistor 52B, and the transistor 52C can be OS transistors. Each of the OS transistors of the transistor 52A, the transistor 52B, and the transistor 52C preferably includes a back gate electrode, in which case the structure in which the back gate electrode is supplied with the same signals as those supplied to the gate electrode or the structure in which the back gate electrode is supplied with signals different from those supplied to the gate electrode can be used.

The transistor 52B includes a gate electrode electrically connected to the transistor 52A, a first electrode electrically connected to the light-emitting element 61, and a second electrode electrically connected to a wiring ANO. The wiring ANO supplies a potential for supplying a current to the light-emitting element 61.

The transistor 52A includes a first terminal electrically connected to the gate electrode of the transistor 52B, a second terminal electrically connected to a wiring SL functioning as a source line, and a gate electrode. The transistor 52A has a function of controlling its conduction state or non-conduction state based on the potential of a wiring GL1 functioning as a gate line.

The transistor 52C includes a first terminal electrically connected to a wiring VO, a second terminal electrically connected to the light-emitting element 61, and agate electrode. The transistor 52C has a function of controlling its conduction state or non-conduction state based on the potential of a wiring GL2 serving as a gate line. The wiring VO is a wiring for supplying a reference potential and a wiring for outputting a current flowing through the pixel circuit 51 to the driver circuit 30 or the arithmetic circuit 40.

The capacitor 53 includes a conductive film electrically connected to the gate electrode of the transistor 52B and a conductive film electrically connected to a second electrode of the transistor 52C.

The light-emitting element 61 includes a first electrode electrically connected to a first electrode of the transistor 52B and a second electrode electrically connected to a wiring VCOM. The wiring VCOM is a wiring for supplying a potential for supplying a current to the light-emitting element 61.

Accordingly, the intensity of light emitted by the light-emitting element 61 can be controlled in accordance with an image signal supplied to the gate electrode of the transistor 52B. Furthermore, variations in the gate-source voltage of the transistor 52B can be inhibited by the reference potential of the wiring VO supplied through the transistor 52C.

A current value that can be used for setting pixel parameters can be output from the wiring VO. Specifically, the wiring VO can function as a monitor line for outputting a current flowing through the transistor 52B or a current flowing through the light-emitting element 61 to the outside. A current output to the wiring VO is converted into a voltage by a source follower circuit or the like and output to the outside. Alternatively, the current output to the wiring VO can be converted into a digital signal by an A-D converter or the like and output to the arithmetic circuit 40 or the like.

A light-emitting element described in one embodiment of the present invention refers to a self-luminous light-emitting element such as an organic EL element (also referred to as an organic light-emitting diode (OLED)). The light-emitting element electrically connected to the pixel circuit can be a self-luminous light-emitting element such as a light-emitting diode (LED), a micro LED, a quantum-dot light-emitting diode (QLED), or a semiconductor laser.

In the structure illustrated as an example in FIG. 21B, the wirings electrically connecting the pixel circuit 51 and the driver circuit 30 can be made short, so that the wiring resistance of the wirings can be reduced. Thus, data writing can be performed at high speed, leading to high-speed operation of the display device 10. Therefore, even when the number of pixel circuits 51 included in the display device 10 is large, a sufficiently long frame period can be ensured and thus the pixel density of the display device 10 can be increased. In addition, the increased pixel density of the display device 10 can increase the resolution of an image displayed by the display device 10. For example, the pixel density of the display device 10 can be 1000 ppi or higher, 5000 ppi or higher, or 7000 ppi or higher. Thus, the display device 10 can be, for example, a display device for VR or AR and can be suitably used in an electronic device with a short distance between the display portion and the user, such as a head-mounted display.

The arithmetic circuit 40, the cell array CA, and the photodiodes PD serving as light-receiving elements, which are described in Embodiment 3, can be provided in the layer 20, the layer 50, and the layer 60 illustrated in FIG. 21A and FIG. 21B. Thus, the display device 10 can be provided with an arithmetic circuit and a driver circuit, pixel circuits and a cell array, and light-emitting elements and light-receiving elements.

As illustrated above, the display device 10 of one embodiment of the present invention can have a structure in which the light-emitting element 61, the pixel circuit 51, and the driver circuit 30 are stacked; thus, the aperture ratio (effective display area ratio) of the pixels can be significantly increased. Furthermore, the pixel circuit 51 can be arranged extremely densely, and thus the resolution of the pixels can be extremely high. Such a display device 10 has extremely high resolution, and thus can be suitably used for a device for VR such as a head-mounted display or a glasses-type device for AR. For example, even in the case of a structure in which the display portion of the display device 10 is seen through an optical member such as a lens, pixels of the extremely-high-resolution display portion included in the display device 10 are not seen when the display portion is enlarged by the lens, so that display providing a high sense of immersion can be performed.

Furthermore, the display device 10 of one embodiment of the present invention can have a structure in which the light-receiving element 62, the cell array CA, and the arithmetic circuit 40 are stacked; thus, arithmetic processing excellent in the arithmetic efficiency can be performed using ultralow currents output from the light-receiving elements 62 as input data. In the display device 10, the light-receiving portion 14 can be placed close to the display portion 13; therefore, an image can be viewed by the user's eyes and an image of the user's eyes and/or their surroundings can be captured. Analog data written according to ultralow currents can be retained for a long time in the cells IM of the cell array CA. The arithmetic circuit 40 that performs product-sum operation processing using ultralow currents can perform an arithmetic operation with excellent arithmetic efficiency.

### Schematic Top Views and Schematic Cross-Sectional Views of Light-Emitting Element

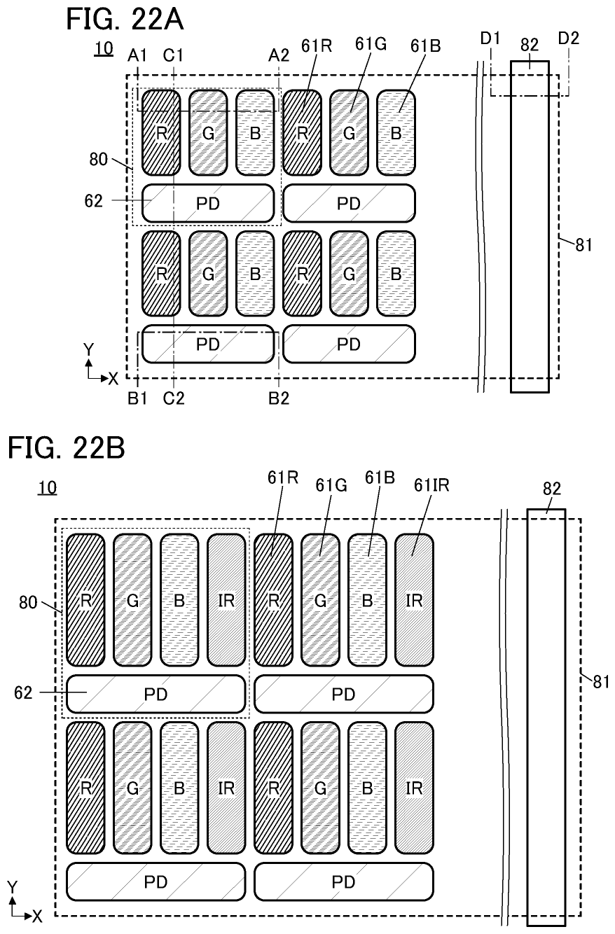

FIG. 22A is a schematic top view illustrating a structure example of the case where light-emitting elements and a light-receiving element are arranged in one pixel in the display device 10 of one embodiment of the present invention. The display device 10 includes light-emitting elements 61R that emit red light, light-emitting elements 61G that emit green light, light-emitting elements 61B that emit blue light, and the light-receiving elements 62. In FIG. 22A, light-emitting regions of the light-emitting elements 61 are denoted by R, G, and B to easily differentiate the light-emitting elements 61. In addition, light-receiving regions of the light-emitting elements 62 are denoted by PD.

The light-emitting elements 61R, the light-emitting elements 61G, the light-emitting elements 61B, and the light-receiving elements 62 are arranged in a matrix. FIG. 22A illustrates an example where the light-emitting elements 61R, the light-emitting elements 61G, and the light-emitting elements 61B are arranged in the X direction and the light-receiving elements 62 are arranged thereunder. FIG. 22A illustrates a structure example where the light-emitting elements 61 that emit light of the same color are arranged in the Y direction intersecting the X direction. In the display device 10 in FIG. 22A, a pixel 80 can be composed of a subpixel including the light-emitting element 61R, a subpixel including the light-emitting element 61G, and a subpixel including the light-emitting element 61B, which are arranged in the X direction, and a subpixel including the light-receiving element 62 provided under the subpixels, for example.

As each of the light-emitting elements 61R, the light-emitting elements 61G, and the light-emitting elements 61B, an EL element such as an organic light-emitting diode (OLED) or a quantum-dot light-emitting diode (QLED) is preferably used. Examples of a light-emitting substance included in the EL elements include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescent (TADF) material). Note that as a TADF material, a material that is in a thermal equilibrium state between a singlet excited state and a triplet excited state may be used. Since such a TADF material enables a short emission lifetime (excitation lifetime), an efficiency decrease of a light-emitting element in a high-luminance region can be inhibited.

As the light-receiving element 62, a PN photodiode or a PIN photodiode can be used, for example. The light-receiving element 62 functions as a photoelectric conversion element that senses light incident on the light-receiving element 62 and generates electric charge. The amount of generated electric charge depends on the amount of incident light.

It is particularly preferable to use an organic photodiode including a layer containing an organic compound as the light-receiving element 62. An organic photodiode, which is easily made thin, lightweight, and large in area and has a high degree of freedom for shape and design, can be used in a variety of display devices.

In one embodiment of the present invention, organic EL elements are used as the light-emitting elements 61, and organic photodiodes are used as the light-receiving elements 62. The organic EL elements and the organic photodiodes can be formed over one substrate. Thus, the organic photodiodes can be incorporated in a display device including the organic EL elements. A photolithography method is preferably employed to separate the organic EL elements and the organic photodiodes from each other. This can reduce the distance between the light-emitting elements and the organic photodiodes, achieving a display device having a higher aperture ratio than that formed using, for example, a shadow mask such as a metal mask.

FIG. 22A illustrates a common electrode 81 and a connection electrode 82. Here, the connection electrode 82 is electrically connected to the common electrode 81. The connection electrode 82 is provided outside a display portion where the light-emitting elements 61 and the light-receiving elements 62 are arranged. In FIG. 22A, the common electrode 81 having a region overlapping with the light-emitting elements 61, the light-receiving elements 62, and the connection electrode 82 is shown by dashed lines.

The connection electrode 82 can be provided along the outer periphery of the display portion. For example, the connection electrode 82 may be provided along one side of the outer periphery of the display portion or two or more sides of the outer periphery of the display portion. That is, the top surface shape of the connection electrode 82 can be a band shape, an L shape, a square bracket shape, a quadrangle, or the like in the case where the top surface shape of the display portion is a rectangle.

FIG. 22B is a schematic top view illustrating a structure example of the display device 10, which is a modification example of the display device 10 illustrated in FIG. 22A. The display device 10 illustrated in FIG. 22B is different from the display device 10 illustrated in FIG. 22A in that light-emitting elements 61IR that emit infrared light are included. The light-emitting elements 61IR can emit near-infrared light (light with a wavelength of greater than or equal to 750 nm and less than or equal to 1300 nm), for example.

In the example illustrated in FIG. 22B, the light-emitting elements 61IR as well as the light-emitting elements 61R, the light-emitting elements 61G, and the light-emitting elements 61B are arranged in the X direction, and the light-receiving elements 62 are arranged thereunder. The light-receiving elements 62 have a function of sensing infrared light.

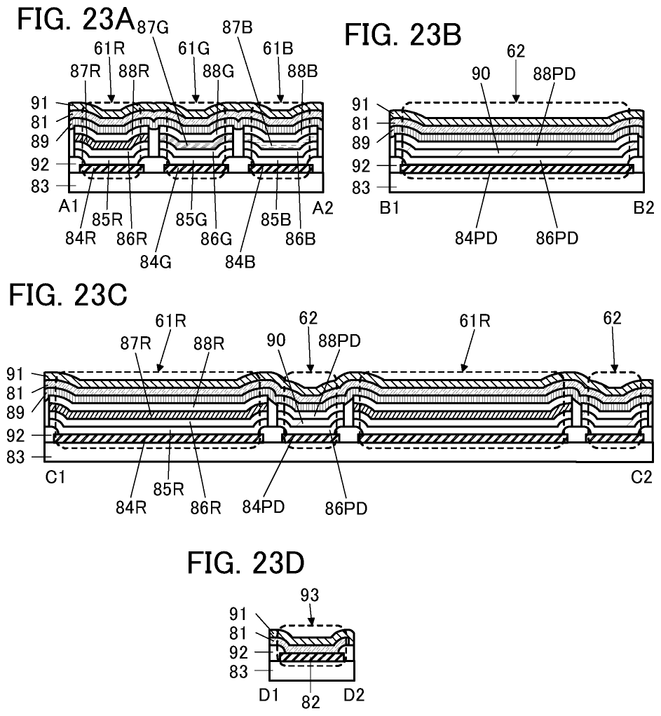

FIG. 23A is a cross-sectional view taken along dashed-dotted line A1-A2 in FIG. 22A, and FIG. 23B is a cross-sectional view taken along dashed-dotted line B1-B2 in FIG. 22A. FIG. 23C is a cross-sectional view taken along dashed-dotted line C1-C2 in FIG. 22A, and FIG. 23D is a cross-sectional view taken along dashed-dotted line D1-D2 in FIG. 22A. The light-emitting elements 61R, the light-emitting elements 61G, the light-emitting elements 61B, and the light-receiving elements 62 are provided over a substrate 83. In the case where the display device 10 includes the light-emitting elements 61IR, the light-emitting elements 61IR are provided over the substrate 83.

In the case where the expression “B over A” or “B under A” is used in this specification and the like, for example, A and B do not always need to include a region where they are in contact with each other.

FIG. 23A illustrates a cross-sectional structure example of the light-emitting element 61R, the light-emitting element 61G, and the light-emitting element 61B. FIG. 23B illustrates a cross-sectional structure example of the light-receiving element 62.

The light-emitting element 61R includes a pixel electrode 84R, a hole-injection layer 85R, a hole-transport layer 86R, a light-emitting layer 87R, an electron-transport layer 88R, a common layer 89, and the common electrode 81. The light-emitting element 61G includes a pixel electrode 84G, a hole-injection layer 85G, a hole-transport layer 86G, a light-emitting layer 87G, an electron-transport layer 88G, the common layer 89, and the common electrode 81. The light-emitting element 61B includes a pixel electrode 84B, a hole-injection layer 85B, a hole-transport layer 86B, a light-emitting layer 87B, an electron-transport layer 88B, the common layer 89, and the common electrode 81. The light-receiving element 62 includes a pixel electrode 84PD, a hole-transport layer 86PD, a light-receiving layer 90, an electron-transport layer 88PD, the common layer 89, and the common electrode 81.

In the following description, the term “hole-injection layer 85” is sometimes used to describe a common part of the hole-injection layer 85R, the hole-injection layer 85G, the hole-injection layer 85B, and the like. The term “hole-transport layer 86” is sometimes used to describe a common part of the hole-transport layer 86R, the hole-transport layer 86G, the hole-transport layer 86B, the hole-transport layer 86PD, and the like. The term “light-emitting layer 87” is sometimes used to describe a common part of the light-emitting layer 87R, the light-emitting layer 87G, the light-emitting layer 87B, and the like. The term “electron-transport layer 88” is sometimes used to describe a common part of the electron-transport layer 88R, the electron-transport layer 88G, the electron-transport layer 88B, the electron-transport layer 88PD, and the like.

The common layer 89 has a function of an electron-injection layer in the light-emitting element 61. Meanwhile, the common layer 89 has a function of an electron-transport layer in the light-receiving element 62. Therefore, the light-receiving element 62 does not necessarily have to include the electron-transport layer 88PD.

The hole-injection layer 85, the hole-transport layer 86, the electron-transport layer 88, and the common layer 89 can also be referred to as functional layers.

The pixel electrode 84, the hole-injection layer 85, the hole-transport layer 86, the light-emitting layer 87, and the electron-transport layer 88 can each be separately provided for each element. The light-emitting elements 61R, the light-emitting elements 61G, the light-emitting elements 61B, and the light-receiving elements 62 include the common layer 89 and the common electrode 81 in common.

The light-emitting elements 61 and the light-receiving elements 62 may each include a hole-blocking layer and an electron-blocking layer other than the layers illustrated in FIG. 23A. The light-emitting elements 61 and the light-receiving elements 62 may each include a layer containing a bipolar substance (a substance with a high electron-transport property and a high hole-transport property).

A gap is provided between the common layer 89 and an insulating layer 92 described later. This can inhibit contact between the common layer 89 and each of a side surface of the light-emitting layer 87, a side surface of the light-receiving layer 90, a side surface of the hole-transport layer 86, and a side surface of the hole-injection layer 85. Thus, a short circuit in the light-emitting elements 61 and a short circuit in the light-receiving elements 62 can be inhibited.

The shorter the distance between the light-emitting layers 87 is, the more easily the gap is formed, for example. For example, when the distance is less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm, the gap can be favorably formed.

A structure in which the light-emitting element 61 includes the pixel electrode 84, the hole-injection layer 85, the hole-transport layer 86, the light-emitting layer 87, the electron-transport layer 88, the common layer 89 (electron-injection layer), and the common electrode 81 in this order from the bottom is illustrated in FIG. 23A. In FIG. 23B, a structure in which the light-receiving element 62 includes the pixel electrode 84PD, the hole-transport layer 86PD, the light-receiving layer 90, the electron-transport layer 88PD, the common layer 89, and the common electrode 81 in this order from the bottom is illustrated; however, one embodiment of the present invention is not limited thereto. For example, the light-emitting element 61 may include a pixel electrode, an electron-injection layer, an electron-transport layer, a light-emitting layer, a hole-transport layer, a hole-injection layer, and a common electrode in this order from the bottom, and the light-receiving element 62 may include a pixel electrode, an electron-transport layer, a light-receiving layer, a hole-transport layer, and a common electrode in this order from the bottom. In that case, the hole-injection layer included in the light-emitting element 61 can be a common layer, and the common layer can be provided between the hole-transport layer included in the light-receiving element 62 and the common electrode. In addition, the electron-injection layers can be separated between the light-emitting elements 61.

Although the electron-transport layer is considered as being provided over the hole-transport layer in the description below, the following description can also be applied to the case where the electron-transport layer is provided under the hole-transport layer, when “electron” is replaced with “hole” and “hole” is replaced with “electron”, for example.

The hole-injection layer injects holes from an anode to the hole-transport layer and contains a material with a high hole-injection property. As the material with a high hole-injection property, an aromatic amine compound and a composite material containing a hole-transport material and an acceptor material (electron-accepting material) can be used, for example.

The hole-transport layer transports holes injected from the anode by the hole-injection layer, to the light-emitting layer. The hole-transport layer contains a hole-transport material. As the hole-transport material, a substance having a hole mobility greater than or equal to 10⁻⁶ cm²/Vs is preferable. Note that other substances can also be used as long as the substances have a hole-transport property higher than an electron-transport property. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferred.

The electron-transport layer transports electrons injected from the cathode by the electron-injection layer, to the light-emitting layer. The electron-transport layer contains an electron-transport material. As the electron-transport material, a substance having an electron mobility greater than or equal to 1×10⁻⁶ cm²/Vs is preferable. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The electron-injection layer can be formed using an alkali metal, an alkaline earth metal, or a compound thereof, such as lithium, cesium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolato lithium (abbreviation: LiPPP), lithium oxide (LiOₓ), or cesium carbonate.

Alternatively, an electron-transport material may be used for the electron-injection layer. For example, a compound having an unshared electron pair and an electron deficient heteroaromatic ring can be used as the electron-transport material. Specifically, a compound with at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound including an unshared electron pair is preferably greater than or equal to −3.6 eV and less than or equal to −2.3 eV. In general, the highest occupied molecular orbital (HOMO) level and the LUMO level of the organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound including an unshared electron pair. Note that NBPhen has a higher glass transition temperature (Tg) than BPhen and thus has high heat resistance.

The light-emitting layer contains a light-emitting substance. The light-emitting layer can contain one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton, an organometallic complex (particularly an iridium complex) having a phenylpyridine derivative including an electron-withdrawing group as a ligand, a platinum complex, and a rare earth metal complex.

The light-emitting layer may contain one or more kinds of organic compounds (e.g., a host material or an assist material) in addition to the light-emitting substance (guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a combination of a hole-transport material and an electron-transport material that easily forms an exciplex and a phosphorescent material, for example. With such a structure, light emission can be efficiently obtained by exciplex-triplet energy transfer (ExTET), which is energy transfer from an exciplex to a light-emitting substance (phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting element can be achieved at the same time.

The light-emitting layer 87R of the light-emitting element 61R includes at least a light-emitting organic compound that emits light with an intensity in a red wavelength range. The light-emitting layer 87G of the light-emitting element 61G includes at least a light-emitting organic compound that emits light with an intensity in a green wavelength range. The light-emitting layer 87B of the light-emitting element 61B includes at least a light-emitting organic compound that emits light with an intensity in a blue wavelength range. The light-receiving layer 90 of the light-receiving element 62 includes an organic compound having detection sensitivity in a wavelength range of visible light, for example.

A conductive film that transmits visible light is used for either the pixel electrode 84 or the common electrode 81, and a reflective conductive film is used for the other. When the pixel electrode 84 has a light-transmitting property and the common electrode 81 has a light-reflecting property, the display device 10 can have a bottom emission structure. When the pixel electrode 84 has a light-reflecting property and the common electrode 81 has a light-transmitting property, the display device 10 can have a top emission structure. When both the pixel electrode 84 and the common electrode 81 transmit light, the display device 10 can have a dual-emission structure.

The light-emitting element 61 preferably has a micro-optical resonator (microcavity) structure. In that case, light emitted from the light-emitting layer 87 can be resonated between the pixel electrode 84 and the common electrode 81, so that light emitted from the light-emitting element 61 can be intensified.

In the case where the light-emitting element 61 has a microcavity structure, one of the common electrode 81 and the pixel electrode 84 is preferably an electrode having both a light-transmitting property and a light-reflecting property (transflective electrode), and the other of the common electrode 81 and the pixel electrode 84 is preferably a reflective electrode. Here, the transflective electrode can have a stacked-layer structure of a reflective electrode and an electrode having a property of transmitting visible light (also referred to as a transparent electrode). The transparent electrode can be referred to as an optical adjustment layer.

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting elements 61. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity of 1×10⁻² Ωcm or lower. Note that in the case where a light-emitting element that emits near-infrared light is used in the display device, the near-infrared light (light with a wavelength greater than or equal to 750 nm and less than or equal to 1300 nm) transmittance and reflectivity of these electrodes are preferably in the above numerical ranges.

The insulating layer 92 is provided so as to cover end portions of the pixel electrode 84R, end portions of the pixel electrode 84G, end portions of the pixel electrode 84B, and end portions of the pixel electrode 84PD. End portions of the insulating layer 92 are preferably tapered. The insulating layer 92 is not necessarily provided.

For example, the hole-injection layer 85R, the hole-injection layer 85G, the hole-injection layer 85B, and the hole-transport layer 86PD each include a region in contact with the top surface of the pixel electrode 84 and a region in contact with a surface of the insulating layer 92. In addition, end portions of the hole-injection layer 85R, end portions of the hole-injection layer 85G, end portions of the hole-injection layer 85B, and end portions of the hole-transport layer 86PD are positioned over the insulating layer 92.

As illustrated in FIG. 23A, a gap is provided between the light-emitting elements 61 that emit light of different colors, for example, between two light-emitting layers 87. In this manner, it is preferable that the light-emitting layer 87R, the light-emitting layer 87G, and the light-emitting layer 87B be provided such that they are not in contact with each other, for example. This favorably prevents unintentional light emission from being caused by a current flowing through adjacent two light-emitting layers 87. Thus, the contrast of the display device 10 can be increased, so that the display quality of the display device 10 can be improved.

A protective layer 91 is provided over the common electrode 81. The protective layer 91 has a function of preventing diffusion of impurities such as water into each light-emitting element from the above.

The protective layer 91 can have, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as an indium gallium oxide or an indium gallium zinc oxide may be used for the protective layer 91.

In this specification and the like, a silicon oxynitride film refers to a film that contains more oxygen than nitrogen. A silicon nitride oxide film refers to a film that contains more nitrogen than oxygen.

A stack of an inorganic insulating film and an organic insulating film can be used as the protective layer 91. For example, a structure where an organic insulating film is provided between a pair of inorganic insulating films is preferably employed. Furthermore, an organic insulating film preferably functions as a planarization film. This planarizes the top surface of the organic insulating film, resulting in improved coverage with an inorganic insulating film thereover and an enhanced barrier property. The top surface of the protective layer 91 is flat, which is preferable because the influence of an uneven shape due to a structure below the protective layer 91 can be reduced in the case where a structure (e.g., a color filter, an electrode of a touch sensor, or a lens array) is provided above the protective layer 91.

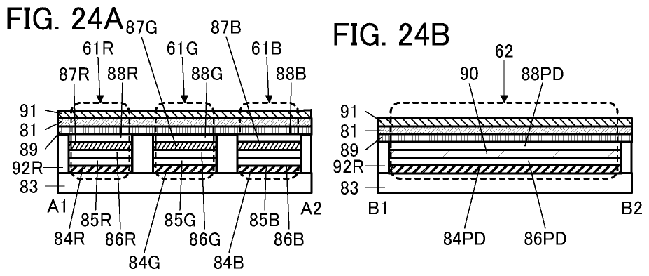

In FIG. 23A and FIG. 23B, the distance between the light-emitting elements can be shortened in the case where the insulating layer 92 is not provided. For example, a diagram in which the insulating layer 92 is omitted is illustrated in FIG. 24A and FIG. 24B. Note that a region 92R between light-emitting elements in FIG. 24A and FIG. 24B may include an insulating layer containing an organic material or the like. The region 92R may be filled with, for example, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The region 92R may be filled with a photosensitive resin. A photoresist may be used for the photosensitive resin. As the photosensitive resin, a positive photosensitive material or a negative photosensitive material can be used.

FIG. 23C illustrates a cross-sectional structure example of the display device 10 in the Y direction, specifically, a cross-sectional structure example of the light-emitting element 61R and the light-receiving element 62. The light-emitting element 61G and the light-emitting element 61B can be arranged in the Y direction like the light-emitting element 61R.

FIG. 23D illustrates a connection portion 93 where the connection electrode 82 and the common electrode 81 are electrically connected to each other. In the connection portion 93, the common electrode 81 is provided over and in contact with the connection electrode 82, and the protective layer 91 is provided so as to cover the common electrode 81. The insulating layer 92 is provided so as to cover end portions of the connection electrode 82.

### Structure Example of Light-Emitting Element

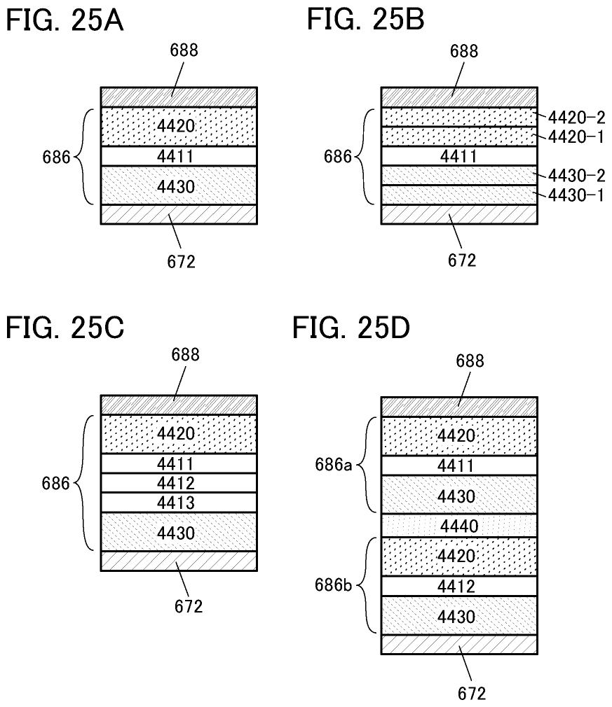

As illustrated in FIG. 25A, a light-emitting element includes an EL layer 686 between a pair of electrodes (an electrode 672 and an electrode 688). The EL layer 686 can be formed of a plurality of layers such as a layer 4420, a light-emitting layer 4411, and a layer 4430. The layer 4420 can include, for example, a layer containing a substance with a high electron-injection property (electron-injection layer) and a layer containing a substance with a high electron-transport property (electron-transport layer). The light-emitting layer 4411 contains a light-emitting compound, for example. The layer 4430 can include, for example, a layer containing a substance with a high hole-injection property (hole-injection layer) and a layer containing a substance with a high hole-transport property (hole-transport layer).

The structure including the layer 4420, the light-emitting layer 4411, and the layer 4430, which is provided between a pair of electrodes, can function as a single light-emitting unit, and the structure in FIG. 25A is referred to as a single structure in this specification.

FIG. 25B is a modification example of the EL layer 686 included in the light-emitting element illustrated in FIG. 25A. Specifically, a light-emitting element illustrated in FIG. 25B includes a layer 4430-1 over the electrode 672, a layer 4430-2 over the layer 4430-1, the light-emitting layer 4411 over the layer 4430-2, a layer 4420-1 over the light-emitting layer 4411, a layer 4420-2 over the layer 4420-1, and the electrode 688 over the layer 4420-2. For example, in the case where the electrode 672 is an anode and the electrode 688 is a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the electrode 672 is as a cathode and the electrode 688 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With the layered structure in FIG. 25B, carriers can be efficiently injected into the light-emitting layer 4411, so that the efficiency of carrier recombination in the light-emitting layer 4411 can be increased.

The structure in which a plurality of light-emitting layers (the light-emitting layer 4411, a light-emitting layer 4412, and a light-emitting layer 4413) are provided between the layer 4420 and the layer 4430 as illustrated in FIG. 25C is another variation of the single structure.

The structure in which a plurality of light-emitting units (an EL layer 686a and an EL layer 686b) are connected in series with an intermediate layer (charge-generation layer) 4440 therebetween as illustrated in FIG. 25D is referred to as a tandem structure in this specification. The structure illustrated in FIG. 25D is referred to as a tandem structure in this specification and the like; however, the name of the structure is not limited thereto. A tandem structure may be referred to as a stack structure, for example. The tandem structure enables a light-emitting element capable of high luminance light emission.

In FIG. 25C and FIG. 25D, the layer 4420 and the layer 4430 may each have a stacked-layer structure of two or more layers as illustrated in FIG. 25B.

A structure in which light-emitting elements that emit light of different colors (here, blue (B), green (G), and red (R)) are separately formed is referred to as a side-by-side (SBS) structure in some cases.

In the case where the single structure and the tandem structure described above and the SBS structure are compared with each other, the SBS structure, the tandem structure, and the single structure have lower consumption in this order. To reduce power consumption, the SBS structure is preferably employed. Meanwhile, the single structure and the tandem structure are preferable in terms of lower manufacturing cost or higher manufacturing yield because the manufacturing processes for the single structure and the tandem structure are simpler than that for the SBS structure.

The emission colors of the light-emitting elements can be changed to red, green, blue, cyan, magenta, yellow, white, or the like depending on a material of the EL layer 686. When the light-emitting elements have a microcavity structure, the color purity can be further increased.

In a light-emitting element that emits white light, a light-emitting layer preferably contains two or more kinds of light-emitting substances. To obtain white light emission, the two or more kinds of light-emitting substances are selected so as to emit light of complementary colors. For example, when the emission color of a first light-emitting layer and the emission color of a second light-emitting layer are complementary colors, so that a light-emitting element can emit white light as a whole. This can be applied to a light-emitting element including three or more light-emitting layers.

A light-emitting layer preferably contains two or more of light-emitting substances that emit light of R (red), G (green), B (blue), Y (yellow), O (orange), and the like. Alternatively, a light-emitting layer preferably contains two or more light-emitting substances each of which emits light containing two or more of spectral components of R, G, and B.

### Structure Example of Light-Emitting Element and Light-Receiving Element

The display device of one embodiment of the present invention is a top-emission display device where light is emitted in the direction opposite to a substrate over which light-emitting elements are formed. In this embodiment, a top-emission display device provided with light-emitting elements and a light-receiving element will be described as an example.

In this specification and the like, unless otherwise specified, in describing a structure including a plurality of elements (e.g., light-emitting elements and light-emitting layers), alphabets are not added when a common part of the elements is described. For example, when a common part of a light-emitting layer 383R, a light-emitting layer 383G, and the like is described, the term “light-emitting layer 383” is used in some cases.

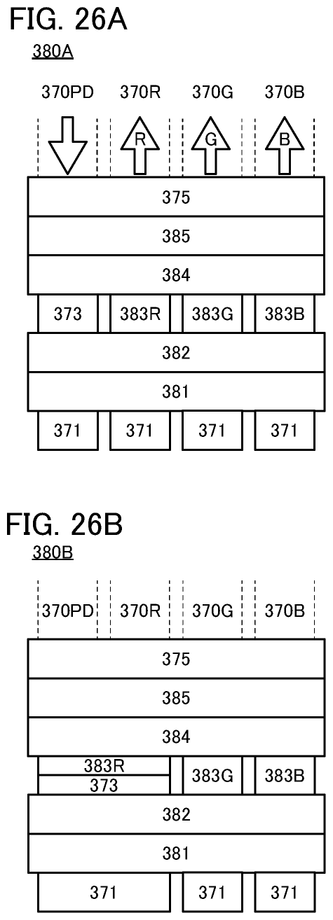

A display device 380A illustrated in FIG. 26A includes a light-receiving element 370PD, a light-emitting element 370R which emits red (R) light, a light-emitting element 370G which emits green (G) light, and a light-emitting element 370B which emits blue (B) light.

Each of the light-emitting elements includes a pixel electrode 371, a hole-injection layer 381, a hole-transport layer 382, a light-emitting layer, an electron-transport layer 384, an electron-injection layer 385, and a common electrode 375 which are stacked in this order. The light-emitting element 370R includes the light-emitting layer 383R, the light-emitting element 370G includes the light-emitting layer 383G, and the light-emitting element 370B includes a light-emitting layer 383B. The light-emitting layer 383R includes a light-emitting substance which emits red light, the light-emitting layer 383G includes a light-emitting substance which emits green light, and the light-emitting layer 383B includes a light-emitting substance which emits blue light.

The light-emitting elements are electroluminescent elements which emit light to the common electrode 375 side on voltage application between the pixel electrode 371 and the common electrode 375.

The light-receiving element 370PD includes the pixel electrode 371, the hole-injection layer 381, the hole-transport layer 382, an active layer 373, the electron-transport layer 384, the electron-injection layer 385, and the common electrode 375 which are stacked in this order.

The light-receiving element 370PD is a photoelectric conversion element that receives light incident from the outside of the display device 380A and converts the light into an electric signal.

This embodiment is described assuming that the pixel electrode 371 functions as an anode and the common electrode 375 functions as a cathode in the light-emitting elements and the light-receiving element. In other words, the light-receiving element is driven by application of reverse bias between the pixel electrode 371 and the common electrode 375, whereby light incident on the light-receiving element can be sensed and electric charge can be generated and extracted as a current.

In the display device of this embodiment, an organic compound is used for the active layer 373 of the light-receiving element 370PD. The light-receiving element 370PD can share the layers other than the active layer 373 with the light-emitting elements. Therefore, the light-receiving element 370PD can be formed concurrently with the formation of the light-emitting elements only by adding a step of forming the active layer 373 in the manufacturing process of the light-emitting elements. The light-emitting elements and the light-receiving element 370PD can be formed over one substrate. Accordingly, the light-receiving element 370PD can be incorporated into the display device without a significant increase in the number of manufacturing steps.

In the display device 380A, for example, the light-receiving element 370PD and the light-emitting elements have a common structure except that the active layer 373 of the light-receiving element 370PD and the light-emitting layers 383 of the light-emitting elements are separately formed. The structures of the light-receiving element 370PD and the light-emitting elements are not limited thereto. The light-receiving element 370PD and the light-emitting elements may have separately formed layers in addition to the active layer 373 and the light-emitting layer 383. The light-receiving element 370PD and the light-emitting elements preferably include at least one layer used in common (common layer). Thus, the light-receiving element 370PD can be incorporated into the display device without a significant increase in the number of manufacturing steps.

A conductive film that transmits visible light is used as the electrode through which light is extracted, which is either the pixel electrode 371 or the common electrode 375. A conductive film that reflects visible light is preferably used as the electrode through which light is not extracted.

The light-emitting elements included in the display device of this embodiment preferably employ a micro-optical resonator (microcavity) structure. Therefore, one of the pair of electrodes of the light-emitting elements is preferably an electrode having properties of transmitting and reflecting visible light (transflective electrode), and the other is preferably an electrode having a property of reflecting visible light (reflective electrode). When the light-emitting elements have a microcavity structure, light obtained from the light-emitting layers can be resonated between the electrodes, whereby light emitted from the light-emitting elements can be intensified.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting elements. The visible light reflectivity of the transflective electrode is higher than or equal to 10% and less than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity of 1×10⁻² Ωcm or lower. Note that in the case where any of the light-emitting elements emits near-infrared light (light with a wavelength greater than or equal to 750 nm and less than or equal to 1300 nm), the near-infrared light transmittance and reflectivity of these electrodes preferably satisfy the above-described numerical ranges of the visible light transmittance and reflectivity.

The light-emitting element includes at least the light-emitting layer 383. In addition to the light-emitting layer 383, the light-emitting element may further include a layer containing any of a substance with a high hole-injection property, a substance with a high hole-transport property, a hole-blocking material, a substance with a high electron-transport property, a substance with a high electron-injection property, an electron-blocking material, a substance with a bipolar property (a substance with a high electron- and hole-transport property), and the like.

For example, the light-emitting elements and the light-receiving element can share at least one of the hole-injection layer, the hole-transport layer, the electron-transport layer, and the electron-injection layer. At least one of the hole-injection layer, the hole-transport layer, the electron-transport layer, and the electron-injection layer can each be separately formed for the light-emitting elements and the light-receiving element.

The hole-injection layer injects holes from an anode to the hole-transport layer and contains a material with a high hole-injection property. As the material with a high hole-injection property, an aromatic amine compound and a composite material containing a hole-transport material and an acceptor material (electron-accepting material) can be used.

In the light-emitting element, the hole-transport layer transports holes injected from the anode by the hole-injection layer, to the light-emitting layer. In the light-receiving element, the hole-transport layer transports holes generated in the active layer on the basis of incident light, to the anode. The hole-transport layer contains a hole-transport material. The hole-transport material preferably has a hole mobility of 1×10⁻⁶ cm²/Vs or higher. Note that other substances can also be used as long as the substances have a hole-transport property higher than an electron-transport property. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferred.

In the light-emitting element, the electron-transport layer transports electrons injected from the cathode by the electron-injection layer, to the light-emitting layer. In the light-receiving element, the electron-transport layer transports electrons generated in the active layer on the basis of incident light, to the cathode. The electron-transport layer contains an electron-transport material. The electron-transport material preferably has an electron mobility of 1×10⁻² cm²/VNs or higher. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The light-emitting layer 383 contains a light-emitting substance. The light-emitting layer 383 can contain one kind or two or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer 383 may contain one kind or two or more kinds of organic compounds (e.g., a host material or an assist material) in addition to the light-emitting substance (guest material). As one kind or two or kinds of organic compounds, one or both of the hole-transport material and the electron-transport material can be used. Alternatively, as one kind or two or kinds of organic compounds, a bipolar material or a TADF material may be used.

The light-emitting layer 383 preferably includes a phosphorescent material and a combination of a hole-transport material and an electron-transport material that easily forms an exciplex. With such a structure, light emission can be efficiently obtained by exciplex-triplet energy transfer (ExTET), which is energy transfer from an exciplex to a light-emitting substance (phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting element can be achieved at the same time.

In a combination of materials for forming an exciplex, the highest occupied molecular orbital level (HOMO level) of the hole-transport material is preferably higher than or equal to that of the electron-transport material. The lowest unoccupied molecular orbital level (LUMO level) of the hole-transport material is preferably higher than or equal to that of the electron-transport material. The LUMO levels and the HOMO levels of the materials can be derived from the electrochemical characteristics (the reduction potentials and the oxidation potentials) of the materials that are measured by cyclic voltammetry (CV).

The formation of an exciplex can be confirmed, for example, by a phenomenon in which the emission spectrum of a mixed film in which the hole-transport material and the electron-transport material are mixed is shifted to the longer wavelength side than the emission spectra of each of the hole-transport material and the electron-transport material (or has another peak on the longer wavelength side) observed by comparison of the emission spectra of the hole-transport material, the electron-transport material, and the mixed film of these materials. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the hole-transport material and the electron-transport material, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of the materials.

The active layer 373 includes a semiconductor. Examples of the semiconductor include an inorganic semiconductor such as silicon and an organic semiconductor including an organic compound. This embodiment shows an example in which an organic semiconductor is used as the semiconductor included in the active layer 373. The use of an organic semiconductor is preferable because the light-emitting layer 383 and the active layer 373 can be formed by the same method (e.g., a vacuum evaporation method) and thus the same manufacturing apparatus can be used.

Examples of an n-type semiconductor material included in the active layer 373 are electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, the electron-donating property (donor property) usually increases. Although π-electrons widely spread in fullerene having a spherical shape, its electron-accepting property is high. The high electron-accepting property efficiently causes rapid charge separation and is useful for the light-receiving element. Both C₆₀ and C₇₀ have a wide absorption band in the visible light region, and C₇₀ is especially preferable because of having a larger π-electron conjugation system and a wider absorption band in the long wavelength region than C₆₀. Other examples of fullerene derivatives include [6,6]-phenyl-C₇₁-butyric acid methyl ester (abbreviation: PC₇₀BM), [6,6]-phenyl-C₆₁-butyric acid methyl ester (abbreviation: PC₆₀BM), and 1′,1″,4′,4″-tetrahydro-di[1,4]methanonaphthaleno[1,2:2′, 3′, 56,60:2″, 3″][5,6] fullerene-C₆₀ (abbreviation: ICBA).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer 373 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the active layer 373 is preferably formed by co-evaporation of an n-type semiconductor and a p-type semiconductor. Alternatively, the active layer 373 may be formed by stacking an n-type semiconductor and a p-type semiconductor.

Either a low molecular compound or a high molecular compound can be used for the light-emitting elements and the light-receiving element, and an inorganic compound may also be included. Each of the layers included in the light-emitting elements and the light-receiving element can be formed by any of the following methods: an evaporation method (including a vacuum evaporation method), a transfer method, a printing method, an inkjet method, a coating method, and the like.

As the hole-transport material, a high molecular compound such as poly(3,4-ethylenedioxythiophene)/poly(styrenesulfonic acid) (PEDOT/PSS), or an inorganic compound such as a molybdenum oxide or copper iodide (CuI) can be used, for example. As the electron-transport material, an inorganic compound such as a zinc oxide (ZnO) can be used.

For the active layer 373, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBTB-T or a PBDB-T derivative can be used.

The active layer 373 may contain a mixture of three or more kinds of materials. For example, a third material may be mixed with an n-type semiconductor material and a p-type semiconductor material in order to extend the wavelength range. The third material may be a low molecular compound or a high molecular compound.

A display device 380B illustrated in FIG. 26B is different from the display device 380A in that the light-receiving element 370PD and the light-emitting element 370R have the same structure.

The light-receiving element 370PD and the light-emitting element 370R share the active layer 373 and the light-emitting layer 383R.

Here, the light-receiving element 370PD preferably has the same structure as the light-emitting element which emits light with a wavelength that is longer than the sensing-target light wavelength. For example, the light-receiving element 370PD with a structure for sensing blue light can have a structure similar to that of either or both of the light-emitting element 370R and the light-emitting element 370G. For example, the light-receiving element 370PD with a structure for sensing green light can have a structure similar to that of the light-emitting element 370R.

When the light-receiving element 370PD and the light-emitting element 370R have a common structure, the number of film formation steps and the number of masks can be reduced from those used in the structure where the light-receiving element 370PD and the light-emitting element 370R include separately formed layers. Consequently, the manufacturing steps and the manufacturing costs of the display device can be reduced.

When the light-receiving element 370PD and the light-emitting element 370R have the common structure, a margin for misalignment can be reduced compared with the structure in which the light-receiving element 370PD and the light-emitting element 370R include separately formed layers. Accordingly, the aperture ratio of pixels can be increased and the light extraction efficiency of the display device can be increased. This can extend the life of the light-emitting element. Furthermore, the display device can exhibit a high luminance. Moreover, the resolution of the display device can be increased.

The light-emitting layer 383R includes a light-emitting material that emits red light. The active layer 373 contains an organic compound that absorbs light with a wavelength shorter than that of red light (e.g., either or both of green light and blue light). The active layer 373 preferably contains an organic compound that does not easily absorb red light and that absorbs light with a wavelength shorter than that of red light. In this way, red light can be efficiently extracted from the light-emitting element 370R, and the light-receiving element 370PD can sense light with a wavelength shorter than that of red light with high accuracy.

Although the display device 380B is an example where the light-emitting element 370R and the light-receiving element 370PD have the same structure, the optical adjustment layer of the light-emitting element 370R may have a thickness different from that of the optical adjustment layer of the light-receiving element 370PD.

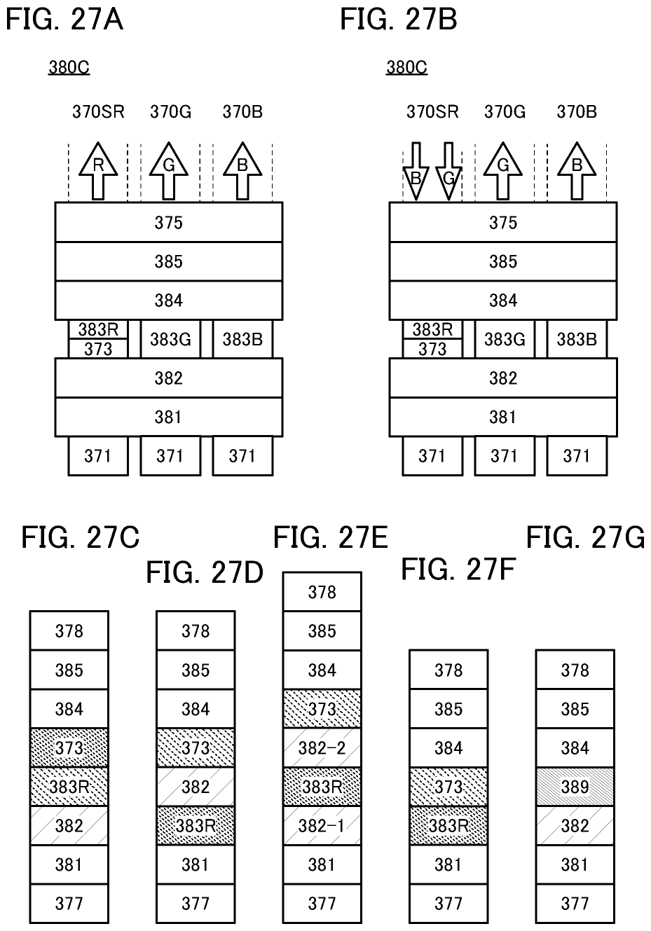

A display device 380C illustrated in FIG. 27A and FIG. 27B includes a light-emitting and light-receiving element 370SR that emits red (R) light and has a light-receiving function, the light-emitting element 370G, and the light-emitting element 370B. The above description of the display device 380A and the like can be referred to for the structures of the light-emitting element 370G and the light-emitting element 370B.

The light-emitting and light-receiving element 370SR includes the pixel electrode 371, the hole-injection layer 381, the hole-transport layer 382, the active layer 373, the light-emitting layer 383R, the electron-transport layer 384, the electron-injection layer 385, and the common electrode 375 which are stacked in this order. The light-emitting and light-receiving element 370SR has the same structure as the light-emitting element 370R and the light-receiving element 370PD illustrated in the display device 380B.

FIG. 27A illustrates a case where the light-emitting and light-receiving element 370SR functions as a light-emitting element. FIG. 27A illustrates an example in which the light-emitting element 370B emits blue light, the light-emitting element 370G emits green light, and the light-emitting and light-receiving element 370SR emits red light.

FIG. 27B illustrates a case where the light-emitting and light-receiving element 370SR functions as a light-receiving element. FIG. 27B illustrates an example in which the light-emitting and light-receiving element 370SR receives blue light emitted by the light-emitting element 370B and green light emitted by the light-emitting element 370G.

The light-emitting element 370B, the light-emitting element 370G, and the light-emitting and light-receiving element 370SR each include the pixel electrode 371 and the common electrode 375. In this embodiment, the case where the pixel electrode 371 functions as an anode and the common electrode 375 functions as a cathode is described as an example. The light-emitting and light-receiving element 370SR is driven by application of reverse bias between the pixel electrode 371 and the common electrode 375, whereby light incident on the light-emitting and light-receiving element 370SR can be sensed and electric charge can be generated and extracted as a current.

It can be said that the light-emitting and light-receiving element 370SR has a structure in which the active layer 373 is added to the light-emitting element. That is, the light-emitting and light-receiving element 370SR can be formed concurrently with the light-emitting element only by adding a step of forming the active layer 373 in the manufacturing process of the light-emitting element. The light-emitting elements and the light-emitting and light-receiving element can be formed over one substrate. Thus, one or both of an image capturing function and a sensing function can be provided to the display portion without a significant increase in the number of manufacturing steps.

The stacking order of the light-emitting layer 383R and the active layer 373 is not limited. In FIG. 27A and FIG. 27B, the active layer 373 is provided over the hole-transport layer 382, and the light-emitting layer 383R is provided over the active layer 373. The stacking order of the light-emitting layer 383R and the active layer 373 may be reversed.

The light-emitting and light-receiving element may exclude at least one of the hole-injection layer 381, the hole-transport layer 382, the electron-transport layer 384, and the electron-injection layer 385. The light-emitting and light-receiving element may include another functional layer such as a hole-blocking layer or an electron-blocking layer.

In the light-emitting and light-receiving element, a conductive film that transmits visible light is used as the electrode through which light is extracted. A conductive film that reflects visible light is preferably used as the electrode through which light is not extracted.

The functions and materials of the layers constituting the light-emitting and light-receiving element are similar to those of the layers constituting the light-emitting elements and the light-receiving element and not described in detail here.

FIG. 27C to FIG. 27G illustrate examples of stacked-layer structures of light-emitting and light-receiving elements.

A light-emitting and light-receiving element illustrated in FIG. 27C includes a first electrode 377, the hole-injection layer 381, the hole-transport layer 382, the light-emitting layer 383R, the active layer 373, the electron-transport layer 384, the electron-injection layer 385, and a second electrode 378.

FIG. 27C illustrates an example in which the light-emitting layer 383R is provided over the hole-transport layer 382, and the active layer 373 is stacked over the light-emitting layer 383R.

As illustrated in FIG. 27A to FIG. 27C, the active layer 373 and the light-emitting layer 383R may be in contact with each other.

A buffer layer is preferably provided between the active layer 373 and the light-emitting layer 383R. In that case, the buffer layer preferably has a hole-transport property and an electron-transport property. For example, a bipolar substance is preferably used for the buffer layer. Alternatively, as the buffer layer, at least one of a hole-injection layer, a hole-transport layer, an electron-transport layer, an electron-injection layer, a hole-blocking layer, an electron-blocking layer, and the like can be used. FIG. 27D illustrates an example where the hole-transport layer 382 is used as the buffer layer.

The buffer layer provided between the active layer 373 and the light-emitting layer 383R can inhibit transfer of excitation energy from the light-emitting layer 383R to the active layer 373. Furthermore, the optical path length (cavity length) of the microcavity structure can be adjusted with the buffer layer. Thus, high emission efficiency can be obtained from the light-emitting and light-receiving element including the buffer layer between the active layer 373 and the light-emitting layer 383R.

FIG. 27E illustrates an example in which a hole-transport layer 382-1, the active layer 373, a hole-transport layer 382-2, and the light-emitting layer 383R are stacked in this order over the hole-injection layer 381. The hole-transport layer 382-2 functions as a buffer layer. The hole-transport layer 382-1 and the hole-transport layer 382-2 may contain the same material or different materials. Instead of the hole-transport layer 382-2, a layer that can be used as the buffer layer may be used. The positions of the active layer 373 and the light-emitting layer 383R may be interchanged.

The light-emitting and light-receiving element illustrated in FIG. 27F is different from the light-emitting and light-receiving element illustrated in FIG. 27A in that the hole-transport layer 382 is not included. Thus, the light-emitting and light-receiving element may exclude at least one of the hole-injection layer 381, the hole-transport layer 382, the electron-transport layer 384, and the electron-injection layer 385. The light-emitting and light-receiving element may include another functional layer such as a hole-blocking layer or an electron-blocking layer.

The light-emitting and light-receiving element illustrated in FIG. 27G is different from the light-emitting and light-receiving element illustrated in FIG. 27A in including a layer 389 serving as both a light-emitting layer and an active layer instead of including the active layer 373 and the light-emitting layer 383R.

As the layer serving as both a light-emitting layer and an active layer, a layer containing three materials which are an n-type semiconductor that can be used for the active layer 373, a p-type semiconductor that can be used for the active layer 373, and a light-emitting substance that can be used for the light-emitting layer 383R can be used, for example.

An absorption band on the lowest energy side of an absorption spectrum of a mixed material of the n-type semiconductor and the p-type semiconductor and a maximum peak of an emission spectrum (PL spectrum) of the light-emitting substance preferably do not overlap with each other and are further preferably positioned fully apart from each other.

At least part of this embodiment can be implemented in combination with any of the other embodiments described in this specification, as appropriate.

### Structure Example of Cross-Sectional View

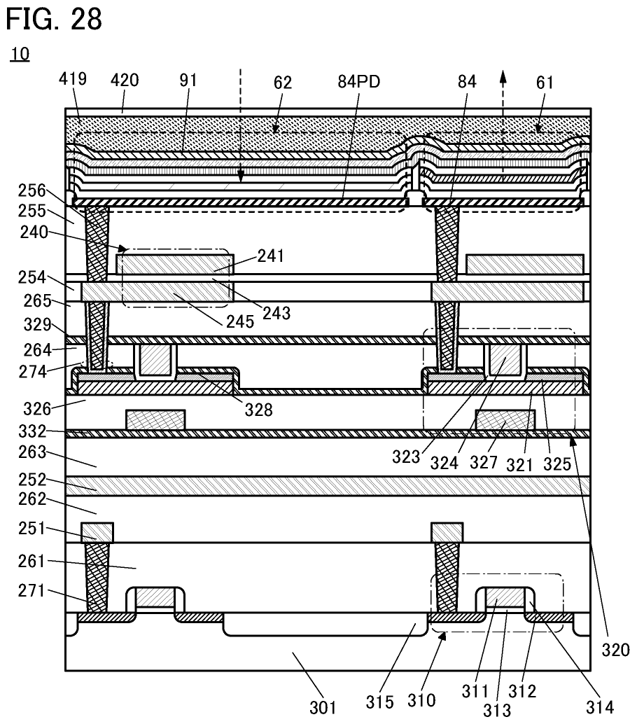

FIG. 28 is a cross-sectional view illustrating a structure example of the display device 10. The display device 10 has a structure in which a transistor 310 whose channel is formed in a substrate 301 and a transistor 320 including a metal oxide in a semiconductor layer where a channel is formed are stacked.

An insulating layer 261 is provided so as to cover the transistor 310, and a conductive layer 251 is provided over the insulating layer 261. An insulating layer 262 is provided so as to cover the conductive layer 251, and a conductive layer 252 is provided over the insulating layer 262. The conductive layer 251 and the conductive layer 252 each function as a wiring. An insulating layer 263 and an insulating layer 332 are provided so as to cover the conductive layer 252, and the transistor 320 is provided over the insulating layer 332. An insulating layer 265 is provided so as to cover the transistor 320, and a capacitor 240 is provided over the insulating layer 265. The capacitor 240 and the transistor 320 are electrically connected to each other through a plug 274.

The transistor 320 can be used as a transistor included in a pixel circuit or a transistor included in a memory cell. The transistor 310 can be used as a transistor included in a memory cell, a transistor included in a driver circuit for driving the pixel circuit, or a transistor included in an arithmetic circuit. The transistor 310 and the transistor 320 can also be used as transistors included in a variety of circuits such as an arithmetic circuit and a memory circuit.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided so as to cover a side surface of the conductive layer 311 and functions as an insulating layer.

An element isolation layer 315 is provided between two adjacent transistors 310 so as to be embedded in the substrate 301.

The transistor 320 contains a metal oxide (also referred to as an oxide semiconductor) in a semiconductor layer where a channel is formed.

The transistor 320 includes a semiconductor layer 321, an insulating layer 323, a conductive layer 324, a pair of conductive layers 325, an insulating layer 326, and a conductive layer 327.

The insulating layer 332 functions as a barrier layer that prevents diffusion of impurities such as water and hydrogen from the substrate 301 into the transistor 320 and release of oxygen from the semiconductor layer 321 to the insulating layer 332 side. As the insulating layer 332, for example, a film in which hydrogen or oxygen is less likely to diffuse than in a silicon oxide film such as an aluminum oxide film, a hafnium oxide film, and a silicon nitride film.

The conductive layer 327 is provided over the insulating layer 332, and the insulating layer 326 is provided so as to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. For the semiconductor layer 321, a metal oxide containing at least one of indium, zinc, and the element M (the element Mis aluminum, gallium, yttrium, or tin) is preferably used. An OS transistor including such a metal oxide in a channel formation region has a characteristic of an extremely low off-state current. Thus, it is preferable that such an OS transistor be used as a transistor provided in a pixel circuit, in which case analog data written to the pixel circuit can be retained for a long time. Similarly, it is preferable that such an OS transistor be used as a transistor provided in a memory cell, in which case analog data written to the memory cell can be retained for a long time.

The pair of conductive layers 325 is provided on and in contact with the semiconductor layer 321, and functions as a source electrode and a drain electrode.

An insulating layer 328 is provided so as to cover top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with side surfaces of the insulating layer 264, the insulating layer 328, and the conductive layer 325, and the top surface of the semiconductor layer 321 and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and the insulating layer 265 are provided so as to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like to the transistor 320. For the insulating layer 329, an insulating film similar to those used for the insulating layer 328 and the insulating layer 332 can be used.

The plug 274 electrically connected to one of the pair of conductive layers 325 is provided so as to be embedded in the insulating layer 265, the insulating layer 329, and the insulating layer 264.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in the insulating layer 254. The conductive layer 241 is electrically connected to one of a source and a drain of the transistor 310 through the plug 271 embedded in the insulating layer 261. The insulating layer 243 is provided so as to cover the conductive layer 241. The conductive layer 245 is provided in a region overlapping with the conductive layer 241 with the insulating layer 243 therebetween.

An insulating layer 255 is provided so as to cover the capacitor 240, and the light-emitting element 61, the light-receiving element 62, and the like are provided over the insulating layer 255. The protective layer 91 is provided over the light-emitting element 61 and the light-receiving element 62, and a substrate 420 is bonded to the top surface of the protective layer 91 with a resin layer 419. A light-transmitting substrate can be used as the substrate 420.

The pixel electrode 84 of the light-emitting element 61 and the pixel electrode 84PD of the light-receiving element 62 are electrically connected to one of the source and the drain of the transistor 310 through a plug 256 embedded in the insulating layer 255, the conductive layer 241 embedded in the insulating layer 254, and the plug 271 embedded in the insulating layer 261.

With such a structure, OS transistors included in a pixel circuit and a cell as well as the driver circuit, an arithmetic circuit, and the like can be provided directly under the light-receiving element and the light-emitting element; thus, the size of a display device with higher performance can be reduced.

At least part of this embodiment can be implemented in combination with any of the other embodiments described in this specification, as appropriate.

### Embodiment 5

In one embodiment of the present invention, an electronic device to which the display device of one embodiment of the present invention can be applied will be described. The electronic device of one embodiment of the present invention can be suitably used also as a wearable electronic device for VR and/or AR application(s).

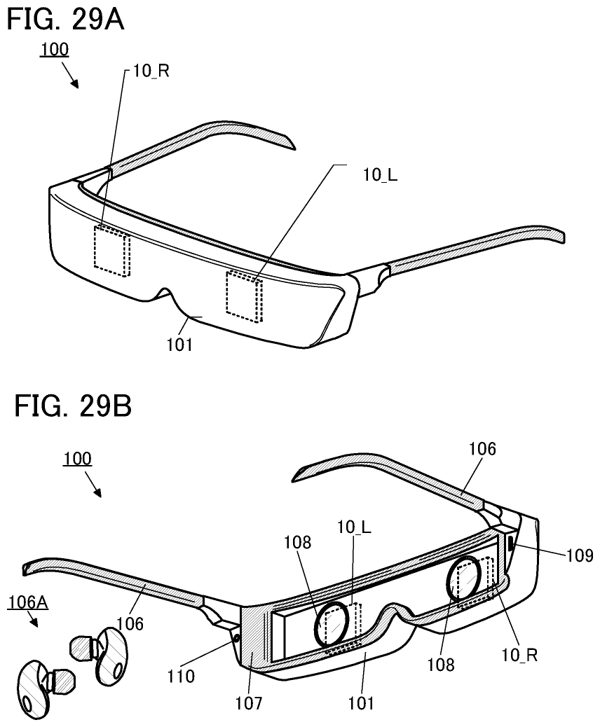

FIG. 29A is a perspective view of a goggle-type electronic device 100 as an example of a wearable electronic device. The electronic device 100 illustrated in FIG. 29A includes a pair of display devices 10_L and 10_R in a housing 101. Note that when the housing 101 is provided with an acceleration sensor such as a gyroscope sensor, the orientation of the user's head can be detected and an image corresponding to the orientation can be displayed.

In this specification and the like, in the case where a common matter between the display devices 10_L and 10_R is described or in the case where it is not necessary to differentiate between these, for example, the display devices 10_L and 10_R may be simply referred to as “display device 10”. The display device 10 described in the above embodiment can apply to the display devices 10_L and 10_R illustrated in FIG. 29A.

As described in the above-described Embodiment 4, the display device 10 of one embodiment of the present invention can have a structure in which the light-emitting element, the pixel circuit, and the driver circuit are stacked; thus, the aperture ratio (effective display area ratio) of the pixels can be significantly increased. Furthermore, the pixel circuits can be arranged extremely densely, resulting in a significant increase in the resolution of the pixels. The display device 10 has an extremely high resolution and thus can be suitably used for a device for VR such as a head-mounted display or a glasses-type device for AR. For example, even in the case of a structure in which the display portion of the display device 10 is viewed through an optical component such as a lens, pixels of the extremely-high-resolution display portion included in the display device 10 are not seen when the display portion is enlarged by the lens, so that display providing a high sense of immersion can be performed.

As described in the above-described Embodiment 4, the display device 10 of one embodiment of the present invention can have a structure in which the light-receiving element, the cell array, and the arithmetic circuit are stacked; thus, arithmetic processing excellent in the arithmetic efficiency can be performed using ultralow currents output from the light-receiving elements as input data. In the display device 10, the light-receiving portion can be placed close to the display portion; therefore, an image can be viewed by the user's eyes and an image of the user's eyes and/or their surroundings can be captured. Therefore, a structure in which inference processing based on a neural network using imaging data as input data is performed can be employed. Analog data written according to ultralow currents can be retained for a long time in the cells of the cell array. The arithmetic circuit that performs product-sum operation processing using ultralow currents can perform an arithmetic operation with excellent arithmetic efficiency.

FIG. 29B is a perspective view illustrating the back surface, the bottom surface, and the right side surface of the electronic device 100 illustrated in FIG. 29A.

In FIG. 29B, the housing 101 of the electronic device 100 includes, for example, a mounting portion 106, a cushion 107, a pair of lenses 108, and the like, as well as the pair of display devices 10_L and 10_R. The display portion 13 in each of the pair of display devices 10_L and 10_R is provided at a position where the display portion 13 can be viewed through the lens 108 inside the housing 101.

The light-receiving portion 14 in each of the pair of display devices 10_L and 10_R is provided at a position where data on the eyes of the user and their surroundings can be acquired. The acquirement of data on the eyes of the user and their surroundings in the light-receiving portion 14 can be performed either through the lenses 108 inside the housing 101 or without the lenses 108.

In addition, an input terminal 109 and an output terminal 110 are provided in the housing 101 illustrated in FIG. 29B. To the input terminal 109, a cable for supplying an image signal (image data) from a video output device or the like, power for charging a battery provided in the housing 101, or the like can be connected. The output terminal 110 can function as, for example, an audio output terminal to which earphones, headphones, or the like can be connected.

In addition, the housing 101 preferably includes a mechanism by which the right and left positions of the lenses 108 and the display devices 10_L and 10_R can be adjusted to the optimal positions in accordance with the positions of the user's eyes. The housing 101 preferably includes a mechanism for adjusting focus by changing the distance between the lenses 108 and the display devices 10_L and 10_R.

The cushion 107 is in contact with the user's face (forehead, cheek, or the like). This can prevent light leakage, which increases the sense of immersion. A soft material is preferably used for the cushion 107 so that the cushion 107 is in close contact with the user's face when the user wears the electronic device 100. Using such a material is preferable because it provides a soft texture and the user does not feel cold when wearing the electronic device in a cold season, for example. A member in contact with user's skin, such as the cushion 107 or the mounting portion 106, is preferably detachable because cleaning or replacement can be easily performed.

The electronic device of one embodiment of the present invention may further include earphones 106A. The earphones 106A include a communication portion (not illustrated) and has a wireless communication function. The earphones 106A can output audio data with the wireless communication function. The earphones 106A may include a vibration mechanism to function as bone-conduction earphones. The earphones 106A can be directly connected to or connected with wire to the mounting portion 106.

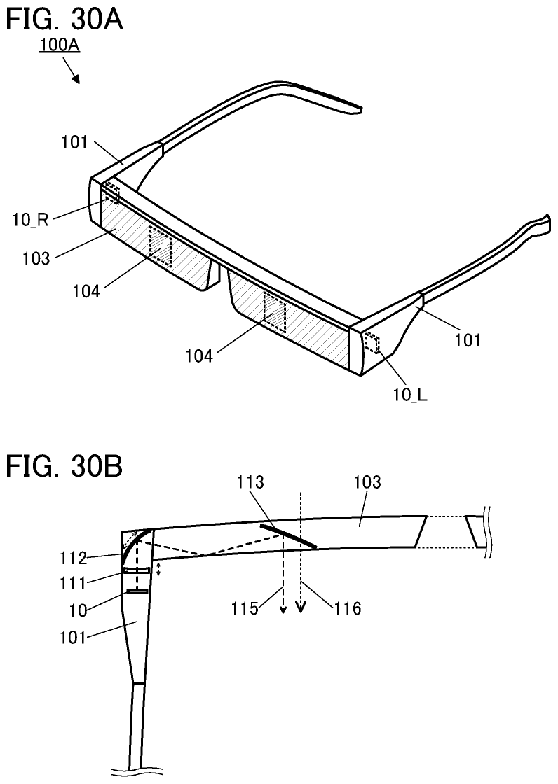

FIG. 30A is a perspective view of a glasses-type electronic device 100A as another example of a wearable electronic device. In the electronic device 100A illustrated in FIG. 30A, the pair of display devices 10_L and 10_R is provided in the housing 101.

The electronic device 100A can project images displayed on the display portions 13 of the display devices 10_L and 10_R in display regions 104 of optical components 103. Since the optical components 103 have a light-transmitting property, a user can see images displayed on the display regions 104, which are superimposed on transmission images seen through the optical components 103. Thus, the electronic device 100A is an electronic appliance capable of AR display.

Although not illustrated, the housing 101 is provided with a wireless receiver or a connector to which a cable can be connected, whereby a video signal or the like can be supplied to the housing 101. Furthermore, when the housing 101 is provided with an acceleration sensor such as a gyroscope sensor, the orientation of the user's head can be detected and an image according to the orientation can be displayed on the display region 104.

Next, a method for projecting an image on the display region 104 of the electronic device 100A will be described with reference to FIG. 30B. The display device 10, a lens 111, and a reflective plate 112 are provided inside the housing 101. A reflective surface 113 functioning as a half mirror is provided as a portion corresponding to the display region 104 of the optical component 103.

Light 115 emitted from the display device 10 passes through the lens 111 and is reflected by the reflective plate 112 toward the optical component 103 side. In the optical component 103, the light 115 is fully reflected repeatedly by end surfaces of the optical component 103 and reaches the reflective surface 113, whereby an image is projected on the reflective surface 113. Accordingly, the user can see both the light 115 reflected by the reflective surface 113 and transmitted light 116 transmitted through the optical component 103 (including the reflective surface 113).

FIG. 30B illustrates an example in which the reflective plate 112 and the reflective surface 113 each have a curved surface. This can increase optical design flexibility and reduce the thickness of the optical component 103, compared to the case where they have flat surfaces. Note that the reflective plate 112 and the reflective surface 113 may be flat.

For the reflective plate 112, a component having a mirror surface can be used, and the reflective plate 112 preferably has high reflectivity. As the reflective surface 113, a half mirror utilizing reflection of a metal film may be used, but the use of prism or the like utilizing total reflection can increase the transmittance of the transmitted light 116.

Here, the housing 101 preferably includes a mechanism for adjusting the distance or angle between the lens 111 and the display device 10. This enables focus adjustment and zooming in/out of images, for example. One or both of the lens 111 and the display device 10 are preferably movable in the optical-axis direction, for example.

The housing 101 preferably includes a mechanism capable of adjusting the angle of the reflective plate 112. The position of the display region 104 where images are displayed can be changed by changing the angle of the reflective plate 112. Thus, the display region 104 can be placed at the most appropriate position in accordance with the position of the user's eye.

At least part of any of the structure examples, the drawings corresponding thereto, and the like described in this embodiment can be combined with the other structure examples, the other drawings, and the like as appropriate.

### Supplementary Notes on Description in this Specification and the Like

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that a content (or part thereof) described in one embodiment can be applied to, combined with, or replaced with another content (or part thereof) described in the embodiment and/or a content (or part thereof) described in another embodiment or other embodiments, for example.

Note that in each embodiment, a content described in the embodiment is a content described using a variety of diagrams or a content described with text disclosed in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there are such a case where one circuit is associated with a plurality of functions or a case where a plurality of circuits are associated with one function, for example. Therefore, blocks in the block diagrams are not limited by the components described in this specification, and the description can be changed appropriately depending on the situation.

In drawings, the size, the layer thickness, or the region is shown arbitrarily for description convenience. Therefore, they are not limited to the illustrated scale. Note that the drawings are schematically shown for clarity, and embodiments of the present invention are not limited to shapes, values, or the like shown in the drawings. For example, variations in a signal, a voltage, or a current due to noise, variations in a signal, a voltage, or a current due to difference in timing, or the like can be included.

In this specification and the like, the terms “one of a source and a drain” (or a first electrode or a first terminal) and “the other of the source and the drain” (or a second electrode or a second terminal) are used to describe the connection relationship of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In this specification and the like, the term “electrode”, “wiring”, or the like does not functionally limit these components. For example, an “electrode” is used as part of a “wiring” in some cases, and vice versa. Furthermore, the term “electrode”, “wiring”, or the like also includes the case where a plurality of“electrodes”, “wirings”, or the like are formed in an integrated manner, for example.

In this specification and the like, voltage and potential can be replaced with each other as appropriate. The term voltage refers to a potential difference from a reference potential, and when the reference potential is a ground potential, for example, voltage can be replaced with potential. The ground potential does not necessarily mean 0 V. Note that potentials are relative, and the potential supplied to a wiring or the like is changed depending on the reference potential, in some cases.

Note that in this specification and the like, the terms “film”, “layer”, and the like can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether a current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where a current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where a current flows in a semiconductor when a transistor is in an on state) and a gate electrode overlap with each other or a region where a channel is formed.

In this specification and the like, the expression “A and B are connected” includes the case where A and B are electrically connected as well as the case where A and B are directly connected. Here, the expression “A and B are electrically connected” means the case where electric signals can be transmitted and received between A and B when an object having any electric action exists between A and B.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting elements of different colors (here, blue (B), green (G), and red (R)) are separately formed or separately patterned may be referred to as a SBS (Side By Side) structure. In this specification and the like, a light-emitting element capable of emitting white light may be referred to as a white-light-emitting element. Note that a white-light-emitting element that is combined with coloring layers (e.g., color filters) can be a light-emitting element for full-color display.

The light-emitting elements can be roughly classified into a single structure and a tandem structure. An element having a single structure includes one light-emitting unit between a pair of electrodes, and the light-emitting unit preferably includes one or more light-emitting layers. To obtain white light emission, two or more of light-emitting layers are selected such that their emission colors are complementary to each other. For example, when emission color of a first light-emitting layer and emission color of a second light-emitting layer are complementary colors, the light-emitting element can be configured to emit white light as a whole. The same can be applied to a light-emitting element including three or more light-emitting layers.

An element having a tandem structure includes two or more light-emitting units between a pair of electrode, and each light-emitting unit preferably includes one or more light-emitting layers. To obtain white light emission, the structure is made so that light from light-emitting layers of the light-emitting units can be combined to be white light. Note that a structure for obtaining white light emission is similar to that in the case of a single structure. In the element having a tandem structure, it is preferable that an intermediate layer such as a charge-generation layer is provided between a plurality of light-emitting units.

When the above-described white-light-emitting element (the single structure or the tandem structure) and a light-emitting element having a SBS structure are compared, the light-emitting element having a SBS structure consumes lower power than the white-light-emitting element. To reduce power consumption, the light-emitting element having a SBS structure is preferably used. In contrast, the white light-emitting element is preferable in that the manufacturing cost is low or the manufacturing yield is high because a process for manufacturing the white light-emitting element is easier than that for the light-emitting element having a SBS structure.

### REFERENCE NUMERALS

CA: cell array, IM: cell, ITRZ: circuit, MAC: semiconductor device, WCS: circuit, WSD: circuit, XCLK: clock signal, XCS: circuit, XDATA: input data, XLAT: latch signal, XSP: start pulse, YCLK: clock signal, YDATA: output data, YLAT: latch signal, YSP: start pulse

1. A semiconductor device comprising:
a cell array configured to perform a product-sum operation of a first layer and a product-sum operation of a second layer in an artificial neural network;
a first circuit and;
a second circuit,
wherein the cell array comprises a first region and a second region,
wherein in a first period, the first region is configured to be supplied with a t-th first data from the first circuit,
wherein in the first period, the first region is configured to output a t-th second data according to the product-sum operation of the first layer to the second circuit,
wherein in the first period, the second region is configured to be supplied with a (t−1)-th first data from the first circuit,
wherein in the first period, the first region is configured to output a (t−1)-th second data according to the product-sum operation of the second layer to the second circuit, and
wherein t is a natural number greater than or equal to 2.

2. The semiconductor device according to claim 1,
wherein in a second period, the first region is configured to be supplied with a (t+1)-th first data from the first circuit,
wherein in the second period, the first region is configured to output a (t+1)-th second data according to the product-sum operation of the first layer to the second circuit,
wherein in the second period, the second region is configured to be supplied with the t-th first data from the first circuit, and
wherein in the second period, the first region is configured to output the t-th second data according to the product-sum operation of the second layer to the second circuit.

3. The semiconductor device according to claim 1,
wherein the first data input to the second region is data obtained by performing a nonlinear operation on the second data output from the first region.

4. The semiconductor device according to claim 1, further comprising a third circuit,
wherein the third circuit is configured to perform arithmetic operation based on a nonlinear function on the second data.

5. The semiconductor device according to claim 1,
wherein the cell array comprises a cell,
wherein the cell comprises a first transistor, a second transistor, and a capacitor,
wherein the first transistor is configured to retain u a first potential corresponding to weight data supplied to a gate of the second transistor through the first transistor,
wherein the capacitor is configured to change the first potential retained in the gate of the second transistor into a second potential in accordance with a change of a potential corresponding to the first data, and
wherein the second transistor is configured to output the second data based on the first data, as an analog current, to one of a source and a drain of the second transistor.

6. The semiconductor device according to claim 5,
wherein the analog current flows when the second transistor operates in a subthreshold region.

7. The semiconductor device according to claim 1,
wherein the cell array comprises a cell,
wherein the cell comprises a transistor, and
wherein the transistor comprises a semiconductor layer containing a metal oxide in a channel formation region.

8. The semiconductor device according to claim 7,
wherein the metal oxide comprises In, Ga, and Zn.

9. The semiconductor device according to claim 1,
wherein the cell array comprises a cell,
wherein the cell comprises a transistor, and
wherein the transistor comprises a semiconductor layer containing silicon in a channel formation region.

10. An electronic device comprising:
the semiconductor device according to claim 1; and a light-receiving element,
wherein the semiconductor device is configured to perform arithmetic processing using a current output from the light-receiving element as the first data.

11. The electronic device according to claim 10, further comprising a light-emitting element,
wherein the light-emitting element comprises an organic EL element.

12. The electronic device according to claim 11,
wherein the light-emitting element and the light-receiving element are separated by a photolithography method.
